(19) United States
(12) Patent Application Publication
(10) Pub. No.: US 2023/0019681 A1
(43) Pub. Date: Jan. 19, 2023

(54) POSITIVE RESIST MATERIAL AND PATTERNING PROCESS

(71) Applicant: SHIN-ETSU CHEMICAL CO., LTD., Tokyo (JP)

(72) Inventors: Jun HATAKEYAMA, Joetsu-shi (JP); Takayuki FUJIWARA, Joetsu-shi (JP)

(73) Assignee: SHIN-ETSU CHEMICAL CO., LTD., Tokyo (JP)

(21) Appl. No.: 17/748,606

(22) Filed: May 19, 2022

(30) Foreign Application Priority Data
Jun. 10, 2021 (JP) 2021-097616

(51) Int. Cl. G03F 7/004; G03F 7/039

(52) U.S. Cl. CPC G03F 7/0045; G03F 7/0392

(57) ABSTRACT

The present invention is a positive resist material containing: an acid generator being a sulfonium salt of a sulfonate ion bonded to a polymer main chain; and a quencher being a sulfonium salt shown by the following general formula (1). R¹ represents a fluorine atom, phenyl group, phenyloxycarbonyl group, alkyl group, alkoxy group, alkenyl group, alkynyl group, or alkoxycarbonyl group. Hydrogen atoms of these groups are optionally substituted. R² to R⁴ each independently represent a halogen atom or hydrocarbyl group. R² and R³, or R² and R⁴, are optionally bonded with each other to form a ring with a sulfur atom that is bonded thereto. Thus, the present invention provides: a positive resist material having higher sensitivity than conventional positive resist materials, and having little edge roughness (LWR) and dimensional variation (CDU) in an exposure pattern; and a patterning process using the positive resist material.

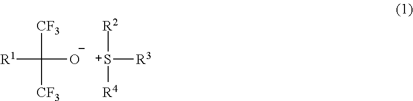

### TECHNICAL FIELD

The present invention relates to: a positive resist material; and a patterning process.

### BACKGROUND ART

As LSIs advance toward higher integration and higher processing speed, miniaturization of pattern rule is progressing rapidly. Especially, the expansion of logic memory market caused by the spread of smartphones leads this miniaturization. As cutting-edge technology for miniaturization, mass productions of 7-nm node devices by double patterning using ArF immersion lithography and 5-nm node devices by extreme ultraviolet ray (EUV) lithography are in progress. For the next-generation 3-nm node and the following-generation 2-nm node also, EUV lithography is considered as a candidate.

The wavelength of EUV 13.5 nm is 1 over 14.3 of the wavelength of an ArF excimer laser 193 nm, and this makes it possible to form fine patterns. However, since the photon number in EUV exposure is 1 over 14.3 of that in ArF exposure, edge roughness (LWR) becomes large due to variation in photon number, and a problem of shot noise such as degradation of critical dimension uniformity (CDU) occurs (Non Patent Document 1).

It is pointed out that dimensions vary due to variation in acid generator and quencher components within a resist film in addition to variation due to shot noise (Non Patent Document 2). A homogeneous dispersion resist is required in EUV lithography for forming extremely fine dimensions.

The introduction of fluorine into a cation moiety of a sulfonium salt used for an acid generator or a quencher is being considered (Patent Document 1). It is shown that by introducing fluorine into a cation moiety of a sulfonium salt, not only is absorption of EUV light increased, but decomposition efficiency is improved, so that higher sensitivity is achieved (Patent Document 2).

A method for producing a sulfonium salt of a weak acid has been proposed (Patent Document 3). When a sulfonium salt of a weak acid is used as a quencher, a generated acid swells so little in an alkali developer that it is possible to prevent pattern collapse and increase in edge roughness (LWR).

### CITATION LIST

### Patent Literature

Patent Document 1: JP 2017-015777 A
Patent Document 2: JP 2015-200886 A
Patent Document 3: WO 2020/175495 A1

### Non Patent Literature

Non Patent Document 1: SPIE Vol. 3331 p 531 (1998)
Non Patent Document 2: SPIE Vol. 9776 p 97760V-1 (2016)

### SUMMARY OF INVENTION

### Technical Problem

The present invention has been made in view of the above-described circumstances, and an object thereof is to provide: a positive resist material having higher sensitivity than conventional positive resist materials, and having little edge roughness (LWR) and dimensional variation (CDU) in an exposure pattern; and a patterning process using the positive resist material.

### Solution to Problem

To achieve the object, the present invention provides a positive resist material comprising:

an acid generator being a sulfonium salt of a sulfonate ion bonded to a polymer main chain; and

a quencher being a sulfonium salt shown by the following general formula (1),

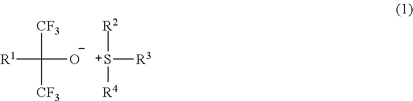

wherein R¹ represents a fluorine atom, a phenyl group, a phenyloxycarbonyl group, an alkyl group having 1 to 4 carbon atoms, an alkoxy group having 1 to 4 carbon atoms, an alkenyl group having 2 to 4 carbon atoms, an alkynyl group having 2 to 4 carbon atoms, or an alkoxycarbonyl group having 1 to 20 carbon atoms; the phenyl group and the phenyloxycarbonyl group have some or all of hydrogen atoms optionally substituted with one or more selected from a fluorine atom, a chlorine atom, a bromine atom, an iodine atom, a fluorinated alkyl group having 1 to 4 carbon atoms, a fluorinated alkyloxy group having 1 to 4 carbon atoms, a trifluoromethylthio group, a cyano group, a nitro group, and a hydroxy group; the alkyl group, the alkoxy group, the alkenyl group, the alkynyl group, and the alkoxycarbonyl group have some or all of hydrogen atoms optionally substituted with one or more selected from a fluorine atom, a chlorine atom, a bromine atom, an iodine atom, a trifluoromethyl group, a trifluoromethoxy group, a trifluoromethylthio group, a cyano group, a nitro group, a phenyl group, and a hydroxy group, or optionally having an ester group, an ether group, or a sulfonyl group; R² to R⁴ each independently represent a halogen atom, or a hydrocarbyl group having 1 to 25 carbon atoms and optionally having at least one selected from an oxygen atom, a sulfur atom, a nitrogen atom, and a halogen atom; and R² and R³, or R² and R⁴, are optionally bonded with each other to form a ring with a sulfur atom that is bonded thereto.

Such a positive resist material has higher sensitivity and resolution than conventional positive resist materials, smaller edge roughness (LWR) and dimensional variation (CDU), as well as favorable pattern profile after exposure.

The acid generator bonded to the polymer main chain is preferably contained in a base polymer comprising a repeating unit(s) shown by the following general formula(e) (a1) and/or (a2),

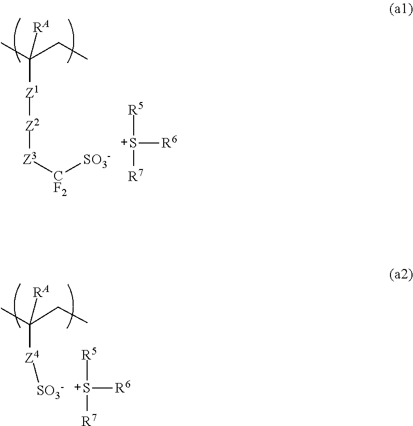

wherein each R^{A} independently represents a hydrogen atom or a methyl group; Z¹ represents a single bond, an ester bond, or a phenylene group; Z² represents a single bond, —Z²¹—C(═O)—O—, —Z²¹—O—, or —Z²¹—O—C(═O)—; Z²¹ represents a hydrocarbylene group having 1 to 12 carbon atoms, a phenylene group, or a group which is a combination thereof having 7 to 18 carbon atoms, the Z²¹ optionally containing a carbonyl group, an ester bond, an ether bond, a sulfur atom, an oxygen atom, a bromine atom, or an iodine atom; Z³ represents a methylene group, a 2,2,2-trifluoro-1,1-ethanediyl group, a hydrocarbon group having 2 to 4 carbon atoms optionally substituted with fluorine, or a carbonyl group; Z⁴ represents a fluorinated phenylene group, a phenylene group substituted with a trifluoromethyl group or an iodine atom, —Z⁴¹—, —O—Z⁴¹—, —C(═O)—O—Z⁴¹—, or —C(═O)—NH—Z⁴¹—; Z⁴¹ represents a fluorinated phenylene group, a phenylene group substituted with a trifluoromethyl group or an iodine atom, or a hydrocarbylene group having 1 to 15 carbon atoms substituted with a halogen atom and optionally containing an ester group and/or an aromatic hydrocarbon group therein; R⁵ to R⁷ each independently represent a hydrocarbyl group having 1 to 25 carbon atoms, and optionally have an oxygen atom, a sulfur atom, a nitrogen atom, or a halogen atom other than fluorine; and R⁵ and R⁶, or R⁵ and R⁷, are optionally bonded with each other to form a ring with a sulfur atom that is bonded thereto.

The base polymer preferably comprises a repeating unit shown by the following general formula (b1) in which a hydrogen atom of a carboxy group is substituted with an acid labile group and/or a repeating unit shown by the following general formula (b2) in which a hydrogen atom of a phenolic hydroxy group is substituted with an acid labile group,

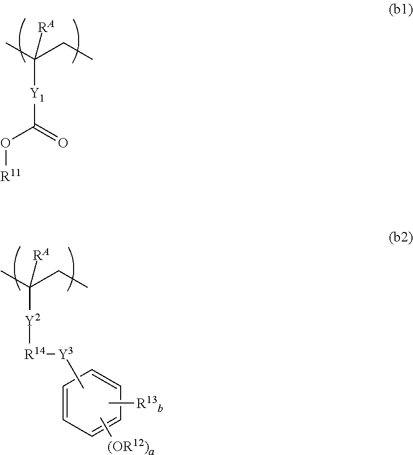

wherein each R^{A} independently represents a hydrogen atom or a methyl group; Y¹ represents a single bond, a phenylene group, a naphthylene group, or a linking group having 1 to 15 carbon atoms containing at least one selected from an ester bond, an ether bond, and a lactone ring; Y² represents a single bond, an ester bond, or an amide bond; Y³ represents a single bond, an ether bond, or an ester bond; R¹¹ and R¹² each represent an acid labile group; R¹³ represents a fluorine atom, a trifluoromethyl group, a cyano group, or a saturated hydrocarbyl group having 1 to 6 carbon atoms; R¹⁴ represents a single bond or an alkanediyl group having 1 to 6 carbon atoms, and some of the carbon atoms are optionally substituted with an ether bond or an ester bond; and “a” represents 1 or 2, and “b” represents an integer of 0 to 4, with 1≤a+b≤5.

Such positive resist materials can further enhance the advantageous effects of the present invention.

In addition, the base polymer preferably further comprises a repeating unit comprising an adhesive group selected from a hydroxy group, a carboxy group, a lactone ring, a carbonate group, a thiocarbonate group, a carbonyl group, a cyclic acetal group, an ether bond, an ester bond, a sulfonic acid ester group, a cyano group, an amide bond, —O—C(═O)—S—, and —O—C(═O)—NH—.

Such a positive resist material can enhance adhesiveness.

Preferably, the positive resist material further comprises one or more of an acid generator other than the acid generator of the sulfonium salt, an organic solvent, a quencher other than the quencher of the sulfonium salt, and a surfactant.

In this manner, the inventive positive resist material has a favorable effect as a chemically amplified positive resist material.

Additionally, the present invention provides a patterning process comprising steps of:

forming a resist film on a substrate by using the above-described positive resist material;

exposing the resist film to a high-energy beam; and

developing the exposed resist film by using a developer.

The high-energy beam is preferably an i-line beam, a KrF excimer laser beam, an ArF excimer laser beam, an electron beam, or an extreme ultraviolet ray having a wavelength of 3 to 15 nm.

According to such a patterning process, a target positive pattern is favorably formed.

### Advantageous Effects of Invention

The inventive positive resist material is a resist material containing a combination of: an acid generator being a sulfonium salt of fluorosulfonic acid bonded to a polymer main chain; and a quencher being a sulfonium salt of a fluoroalcohol (fluoroalkoxide ion) with a particular structure. Such sulfonium salt of fluorosulfonic acid bonded to a polymer main chain is capable of controlling acid diffusion from the fluorosulfonic acid. The quencher which is a sulfonium salt of a fluoroalcohol swells little in an alkali developer and has high water repellency. Thus, stress during rinsing with pure water becomes less influential, so that pattern collapse hardly occurs and the LWR is favorable. Because of these excellent properties, the inventive positive resist material is quite highly practical and very useful as a material for forming fine patterns particularly for manufacturing very LSI circuits or for photomask in EB (electron beam) drawing, or as a material for forming patterns for EB or EUV exposure. The inventive positive resist material is applicable to not only lithography in forming, for example, semiconductor circuits, but also formations of mask circuit patterns, micro-machines, and thin-film magnetic head circuits.

### BRIEF DESCRIPTION OF DRAWINGS

FIG. 1 shows nuclear magnetic resonance spectrum data (¹H-NMR) of synthesized Quencher Q-1; and

FIG. 2 shows nuclear magnetic resonance spectrum data (¹⁹F-NMR) of synthesized Quencher Q-1.

### DESCRIPTION OF EMBODIMENTS

It has been demanded to obtain a positive resist material which has high resolution and little edge roughness and dimensional variation required in recent years, and which hardly causes bridge within a pattern and pattern collapse.

Thus, the present inventors have earnestly studied and consequently considered that to achieve the above object, it is effective to: minimize acid diffusion, suppress swelling during development, and reduce stress during drying of rinsing liquid for the developer. Thus, the inventors have found that for these purposes, it is effective to combine: an acid generator which is a sulfonium salt of a sulfonate bonded to a polymer main chain; and a quencher which is a sulfonium salt of a fluoroalcohol with a particular structure. Thereby, the present invention has been completed.

Specifically, the present invention is a positive resist material comprising:

an acid generator being a sulfonium salt of a sulfonate ion bonded to a polymer main chain; and

a quencher being a sulfonium salt shown by the following general formula (1),

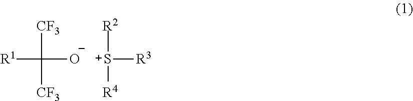

wherein R¹ represents a fluorine atom, a phenyl group, a phenyloxycarbonyl group, an alkyl group having 1 to 4 carbon atoms, an alkoxy group having 1 to 4 carbon atoms, an alkenyl group having 2 to 4 carbon atoms, an alkynyl group having 2 to 4 carbon atoms, or an alkoxycarbonyl group having 1 to 20 carbon atoms; the phenyl group and the phenyloxycarbonyl group have some or all of hydrogen atoms optionally substituted with one or more selected from a fluorine atom, a chlorine atom, a bromine atom, an iodine atom, a fluorinated alkyl group having 1 to 4 carbon atoms, a fluorinated alkyloxy group having 1 to 4 carbon atoms, a trifluoromethylthio group, a cyano group, a nitro group, and a hydroxy group; the alkyl group, the alkoxy group, the alkenyl group, the alkynyl group, and the alkoxycarbonyl group have some or all of hydrogen atoms optionally substituted with one or more selected from a fluorine atom, a chlorine atom, a bromine atom, an iodine atom, a trifluoromethyl group, a trifluoromethoxy group, a trifluoromethylthio group, a cyano group, a nitro group, a phenyl group, and hydroxy group, or optionally having an ester group, an ether group, or a sulfonyl group; R² to R⁴ each independently represent a halogen atom, or a hydrocarbyl group having 1 to 25 carbon atoms and optionally having at least one selected from an oxygen atom, a sulfur atom, a nitrogen atom, and a halogen atom; and R² and R³, or R² and R⁴, are optionally bonded with each other to form a ring with a sulfur atom that is bonded thereto.

Hereinafter, the present invention will be described in detail, but the present invention is not limited thereto.

### [Positive Resist Material]

The inventive positive resist material contains: an acid generator being a sulfonium salt of a sulfonate ion bonded to a polymer main chain; and a quencher being a sulfonium salt of a fluoroalcohol with a particular structure. The acid generator which is a sulfonium salt of a sulfonate ion bonded to a polymer main chain is excellent in ability to control acid diffusion. In the quencher which is a sulfonium salt of a fluoroalcohol with a particular structure, the number of fluorine atoms contained is so large that the fluorine atoms repel each other and the quencher hardly coheres. The fluoroalcohol swells little in an alkali developer and has high water repellency, making it possible to reduce stress applied to a pattern during drying for pure-water rinsing after development. Thus, the LWR and CDU of the resist pattern after the development are improved, and pattern collapse and bridge within the pattern can be prevented.

### [Quencher: Sulfonium Salt of Fluoroalcohol]

The quencher which is a sulfonium salt of a fluoroalcohol is a sulfonium salt quencher shown by the following general formula (1).

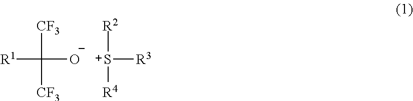

In the formula, R¹ represents a fluorine atom, a phenyl group, a phenyloxycarbonyl group, an alkyl group having 1 to 4 carbon atoms, an alkoxy group having 1 to 4 carbon atoms, an alkenyl group having 2 to 4 carbon atoms, an alkynyl group having 2 to 4 carbon atoms, or an alkoxycarbonyl group having 1 to 20 carbon atoms. The phenyl group and the phenyloxycarbonyl group have some or all of hydrogen atoms optionally substituted with one or more selected from a fluorine atom, a chlorine atom, a bromine atom, an iodine atom, a fluorinated alkyl group having 1 to 4 carbon atoms, a fluorinated alkyloxy group having 1 to 4 carbon atoms, a trifluoromethylthio group, a cyano group, a nitro group, and a hydroxy group. The alkyl group, the alkoxy group, the alkenyl group, the alkynyl group, and the alkoxycarbonyl group have some or all of hydrogen atoms optionally substituted with one or more selected from a fluorine atom, a chlorine atom, a bromine atom, an iodine atom, a trifluoromethyl group, a trifluoromethoxy group, a trifluoromethylthio group, a cyano group, a nitro group, a phenyl group, and a hydroxy group, or optionally having an ester group, an ether group, or a sulfonyl group. R² to R⁴ each independently represent a halogen atom, or a hydrocarbyl group having 1 to 25 carbon atoms and optionally having at least one selected from an oxygen atom, a sulfur atom, a nitrogen atom, and a halogen atom. Alternatively, R² and R³, or R² and R⁴, are optionally bonded with each other to form a ring with a sulfur atom that is bonded thereto.

Here, R¹ is a fluorine atom, a phenyl group, a phenyloxycarbonyl group, an alkyl group having 1 to 4 carbon atoms, an alkoxy group having 1 to 4 carbon atoms, an alkenyl group having 2 to 4 carbon atoms, an alkynyl group having 2 to 4 carbon atoms, or an alkoxycarbonyl group having 1 to 20 carbon atoms. Some or all of hydrogen atoms in the phenyl group and the phenyloxycarbonyl group (hydrogen atoms of the phenyl groups included as R′) are optionally substituted with one or more selected from a fluorine atom, a chlorine atom, a bromine atom, an iodine atom, a fluorinated alkyl group having 1 to 4 carbon atoms, a fluorinated alkyloxy group having 1 to 4 carbon atoms, a trifluoromethylthio group, a cyano group, a nitro group, and a hydroxy group. Moreover, some or all of hydrogen atoms in the alkyl group, the alkoxy group, the alkenyl group, the alkynyl group, and the alkoxycarbonyl group are optionally substituted with one or more selected from a fluorine atom, a chlorine atom, a bromine atom, an iodine atom, a trifluoromethyl group, a trifluoromethoxy group, a trifluoromethylthio group, a cyano group, a nitro group, a phenyl group, and a hydroxy group. The alkyl group, the alkoxy group, the alkenyl group, the alkynyl group, and the alkoxycarbonyl group may have an ester group, an ether group, or a sulfonyl group.

The alkyl group, the alkoxy group, the alkenyl group, the alkynyl group, and the alkoxycarbonyl group may each have a linear, branched, or cyclic carbon chain, and the carbon chain is not particularly limited. Examples of the alkyl group and the alkoxycarbonyl group whose hydrogen atom(s) are substituted with a phenyl group can include a benzyl group, a benzyloxy group, and a benzyloxycarbonyl group. The phenyl group mentioned here may have some or all of hydrogen atoms substituted with one or more selected from the above-described atoms and groups.

R² to R⁴ are each independently a halogen atom, or a hydrocarbyl group having 1 to 25 carbon atoms. The hydrocarbyl group optionally has at least one selected from an oxygen atom, a sulfur atom, a nitrogen atom, and a halogen atom. Alternatively, R² and R³, or R² and R⁴, may bond with each other to form a ring together with a sulfur atom bonded to R² and R³, or R² and R⁴.

Examples of the alkoxide ion shown in the general formula (1) include ones shown below, but are not limited thereto.

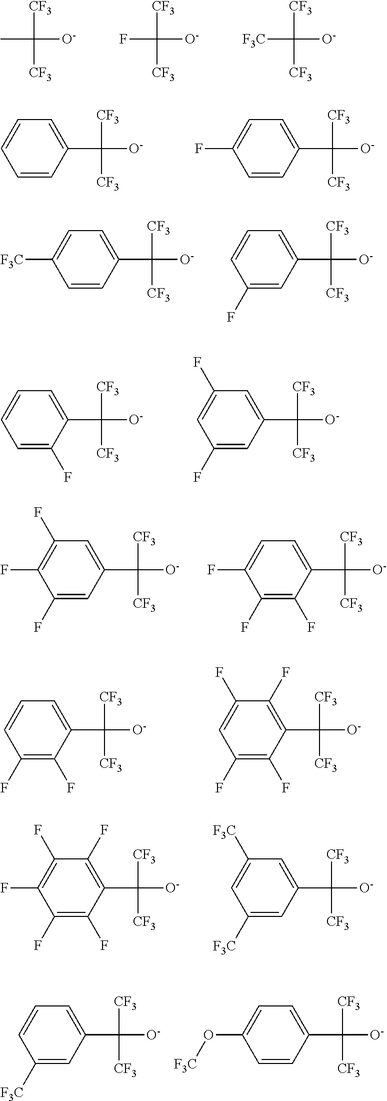

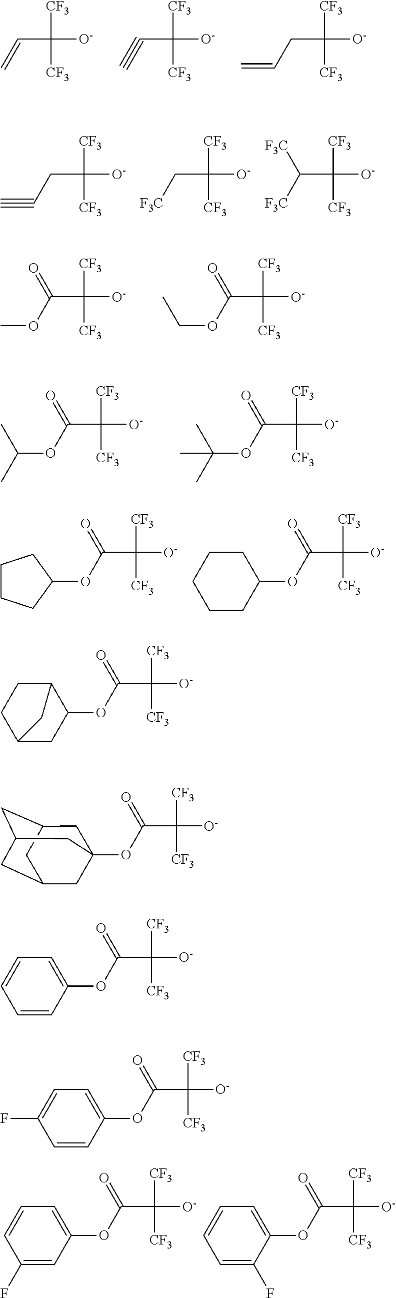

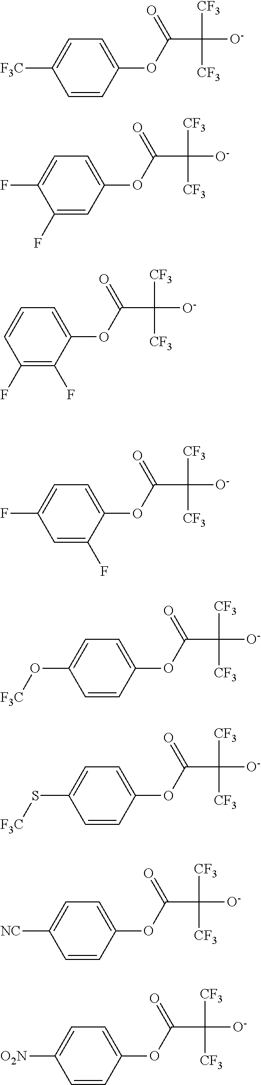

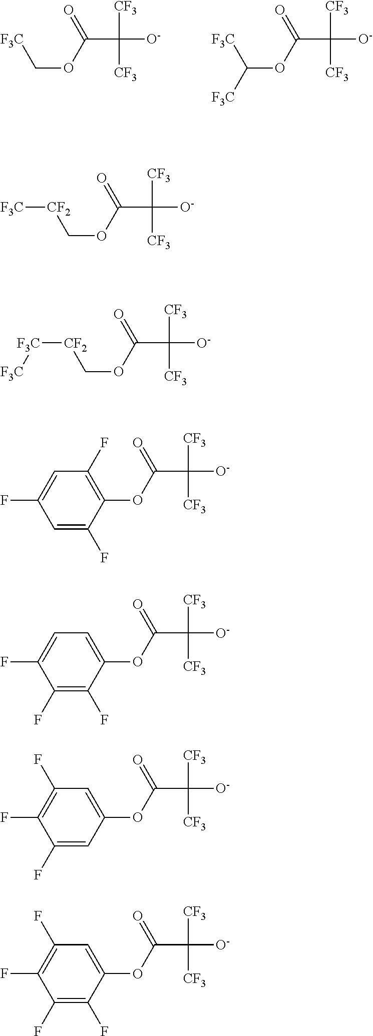

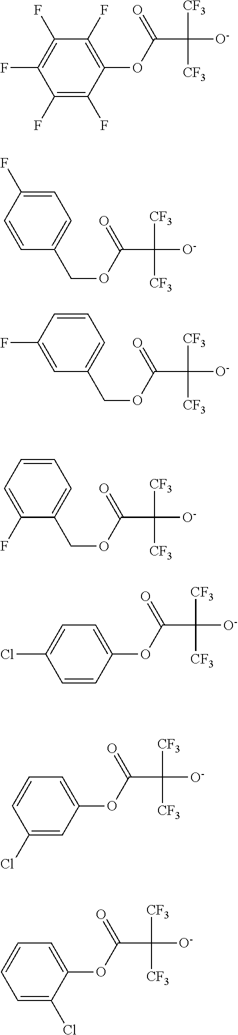

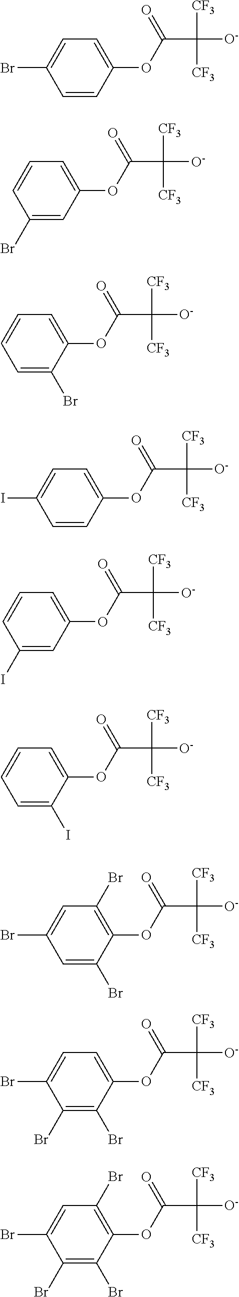

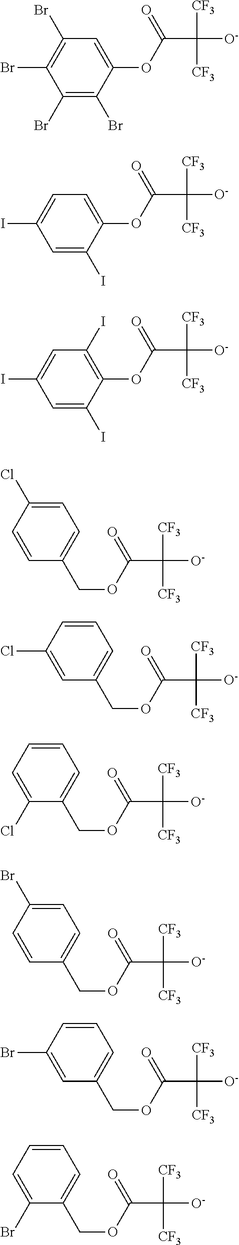

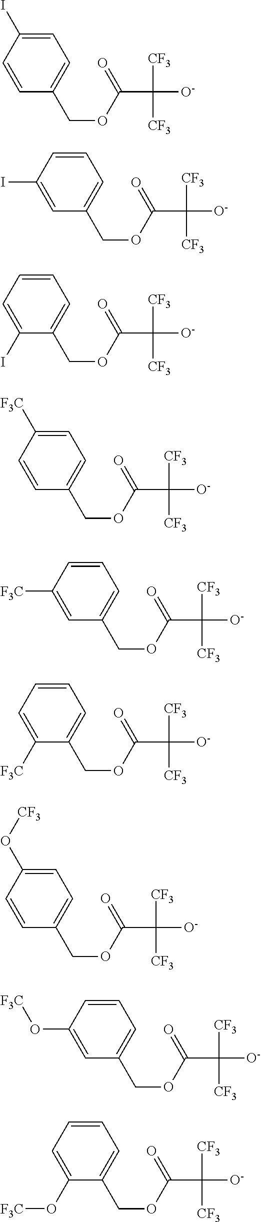

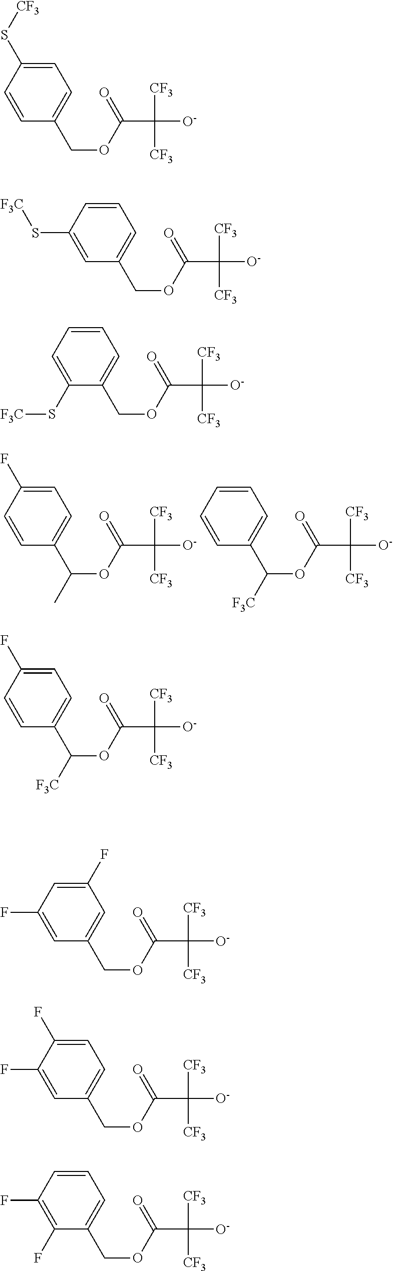

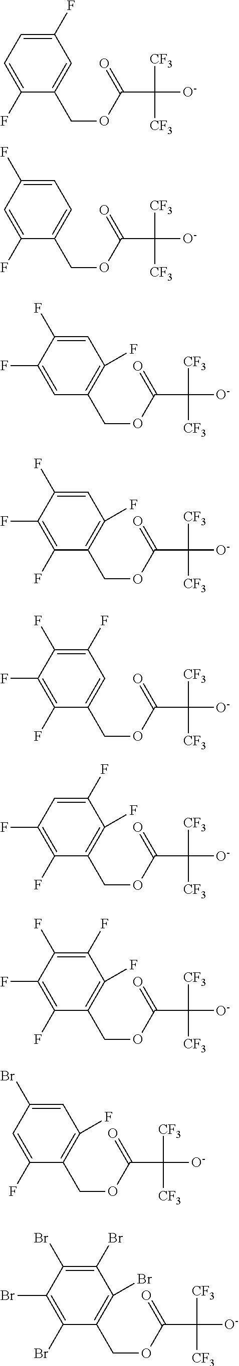

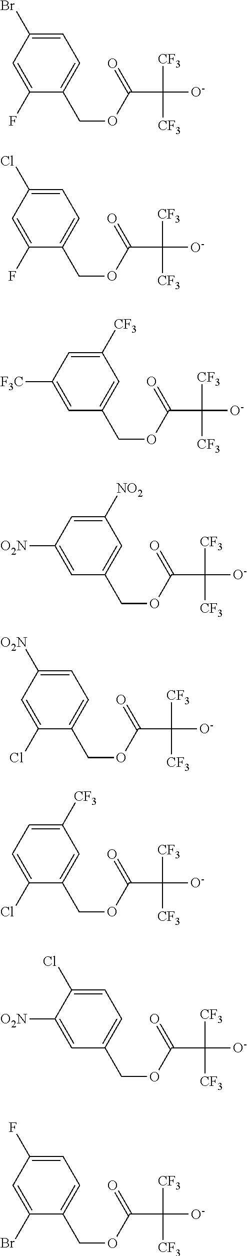

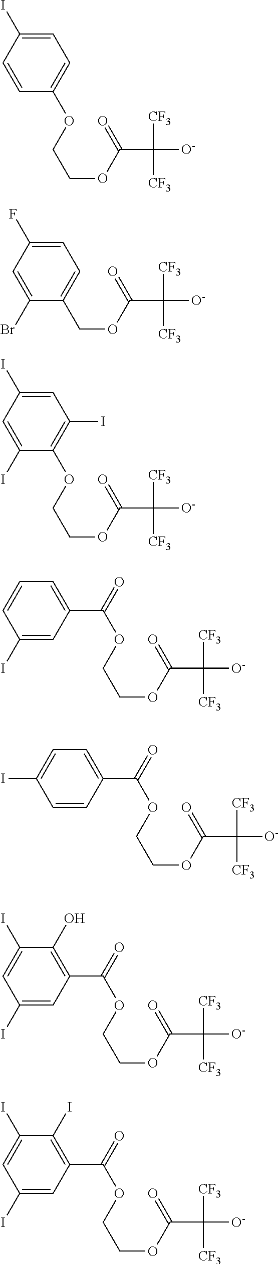

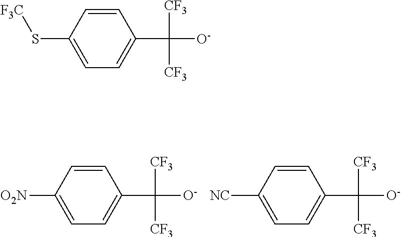

Examples of the cation of the sulfonium salt shown in the general formula (1) include ones shown below, but are not limited thereto.

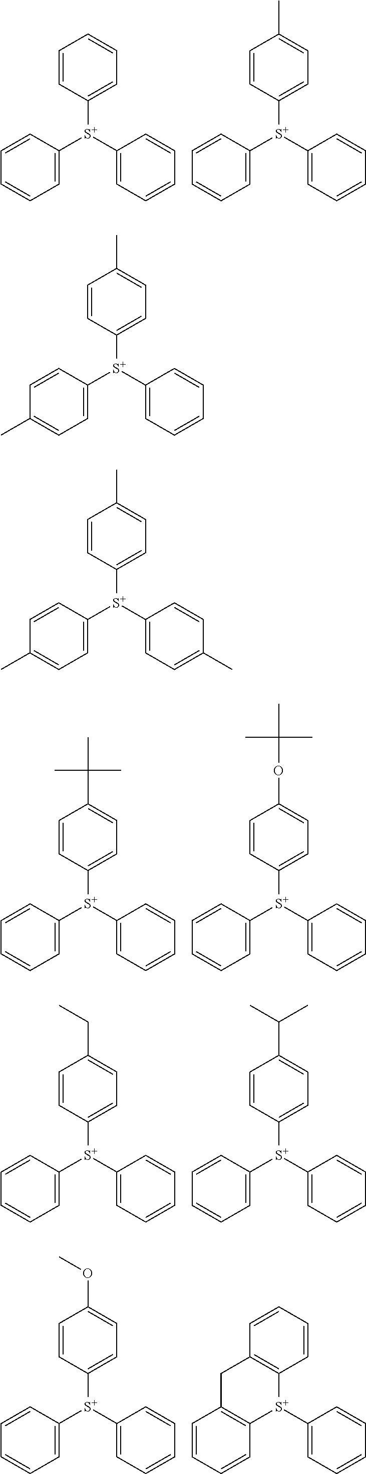

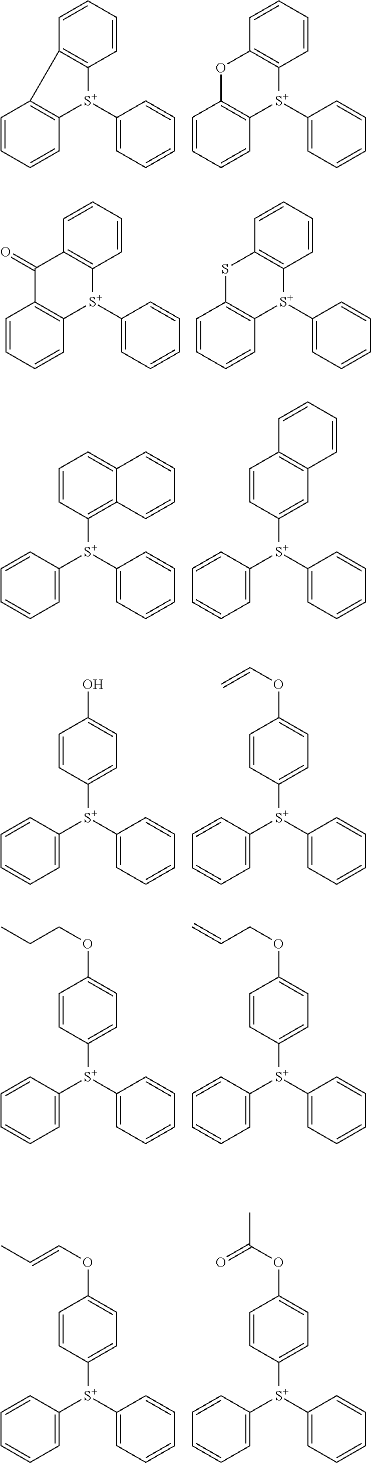

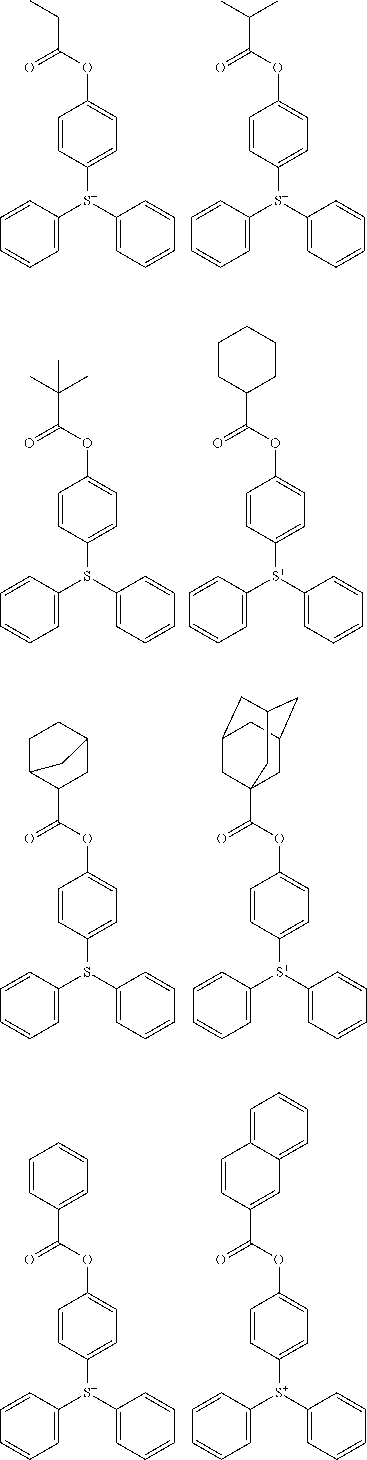

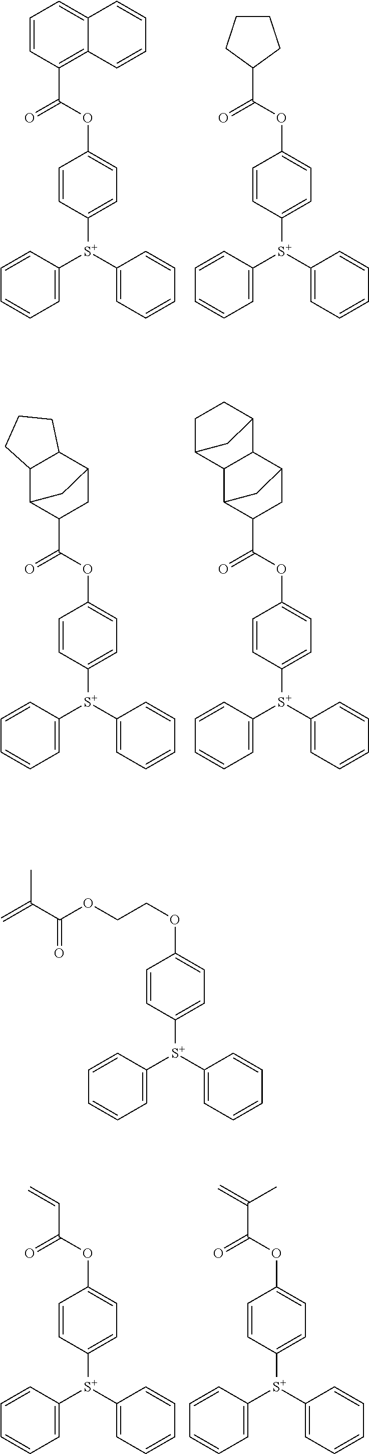

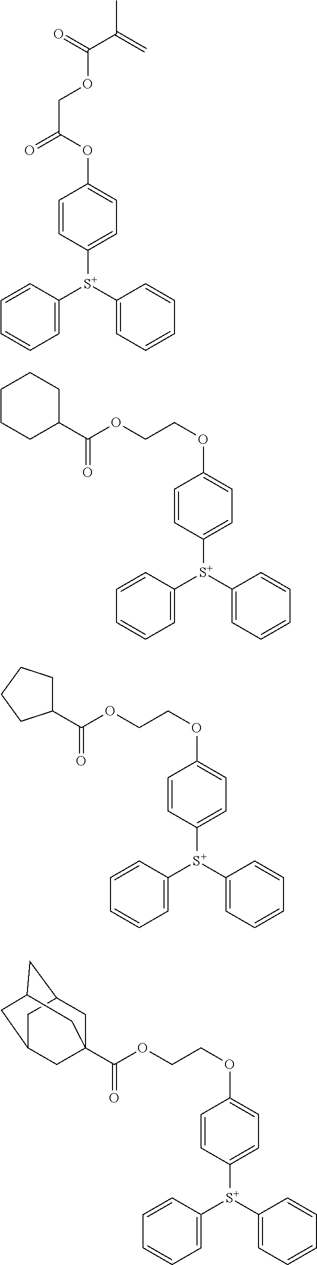

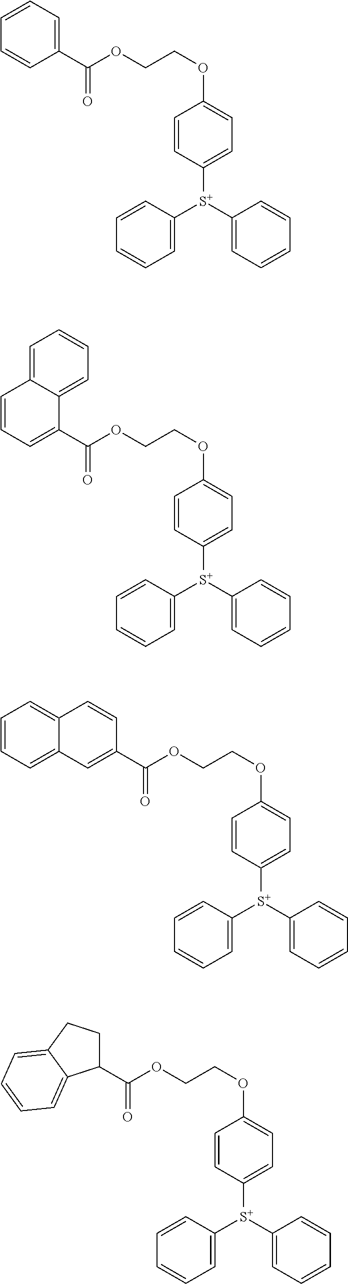

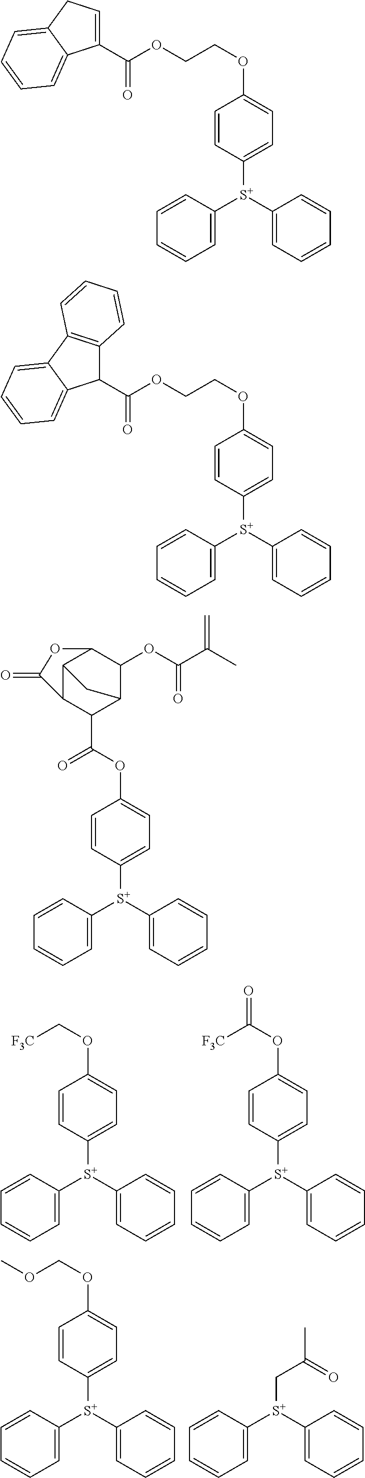

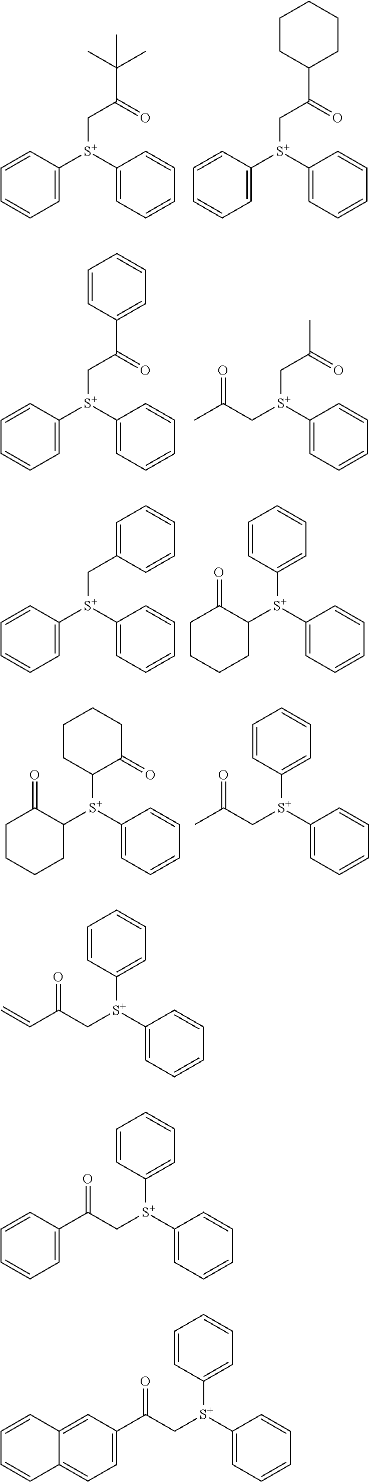

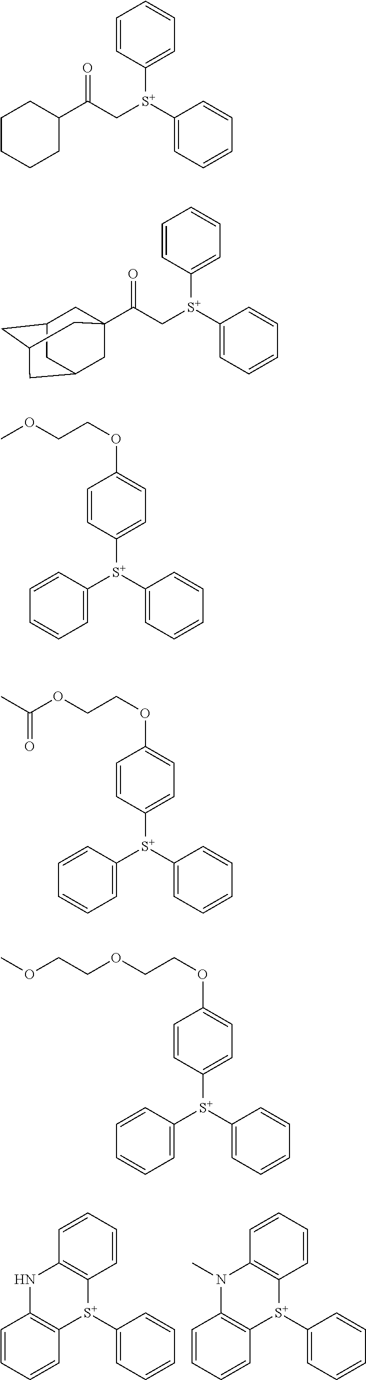

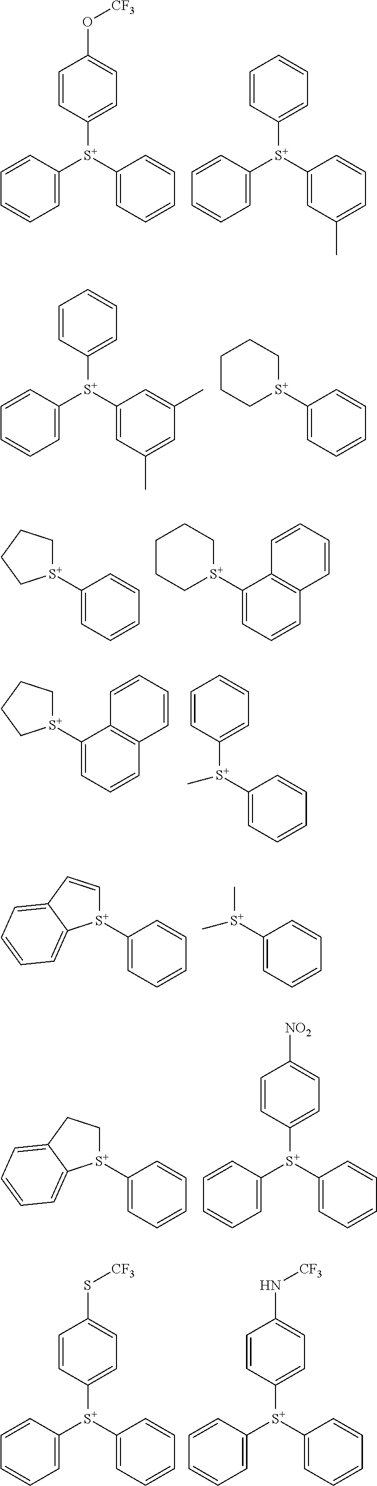

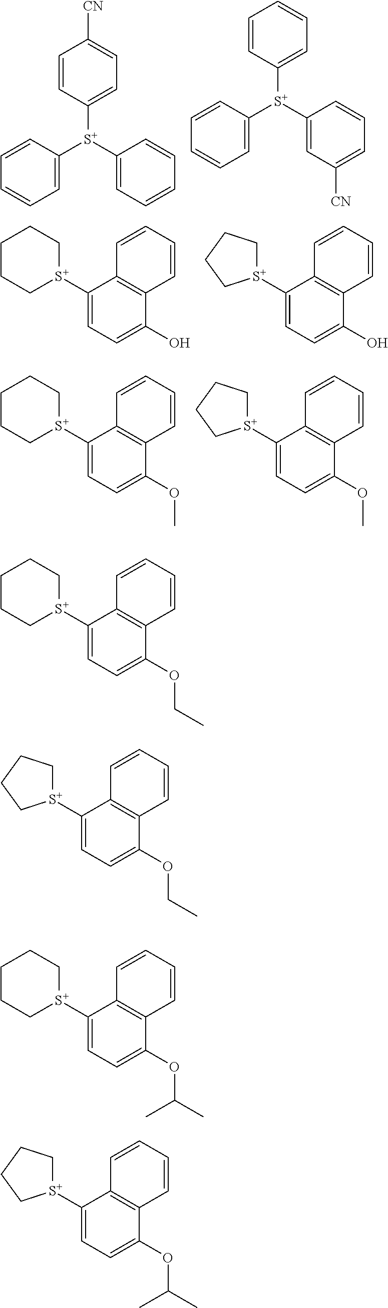

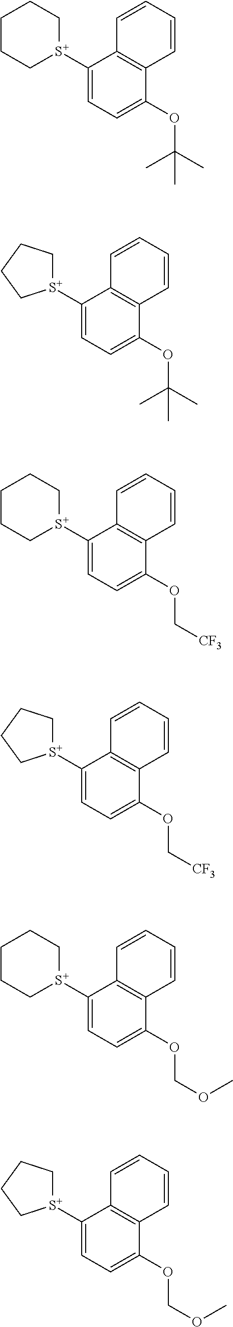

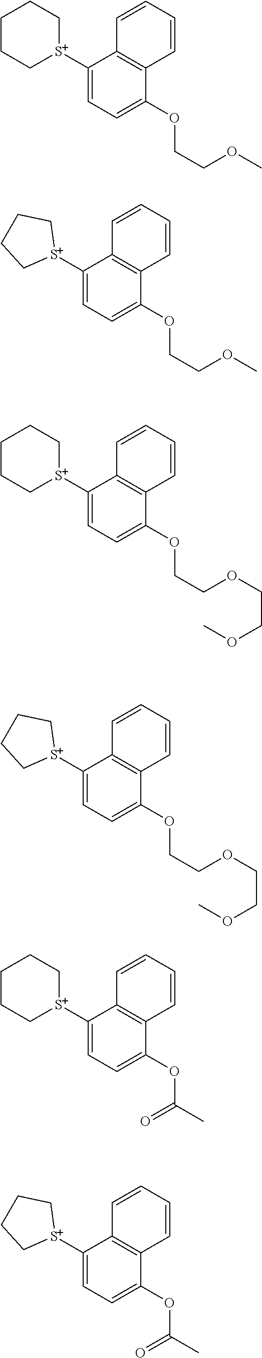

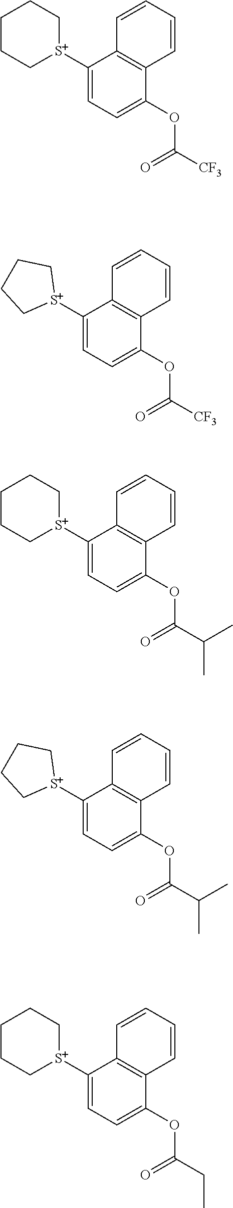

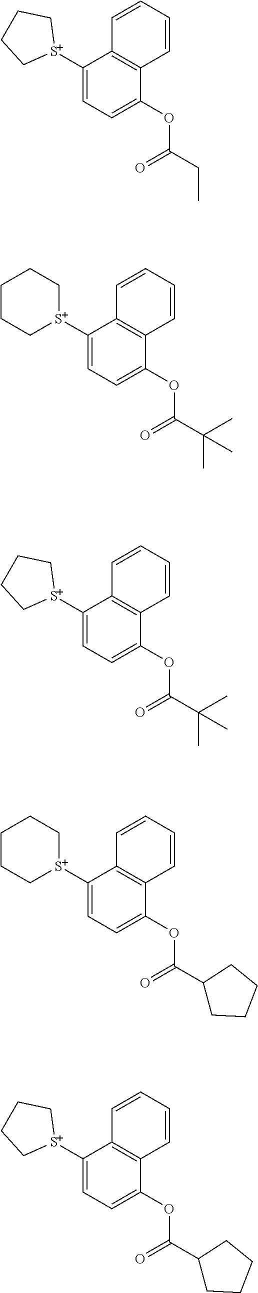

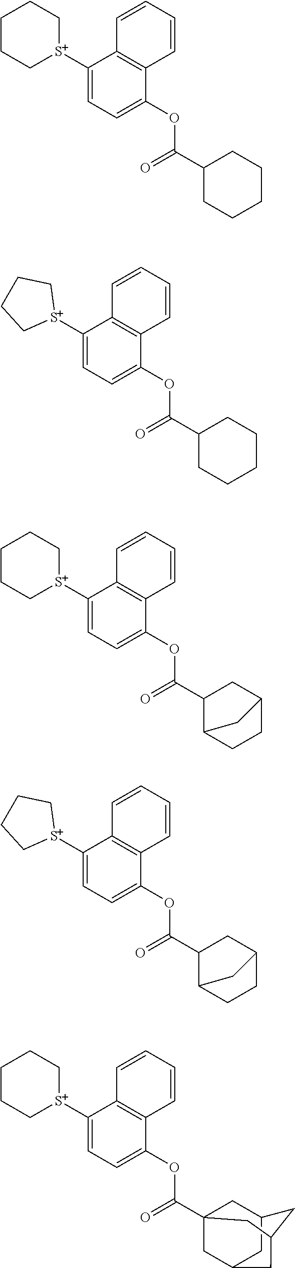

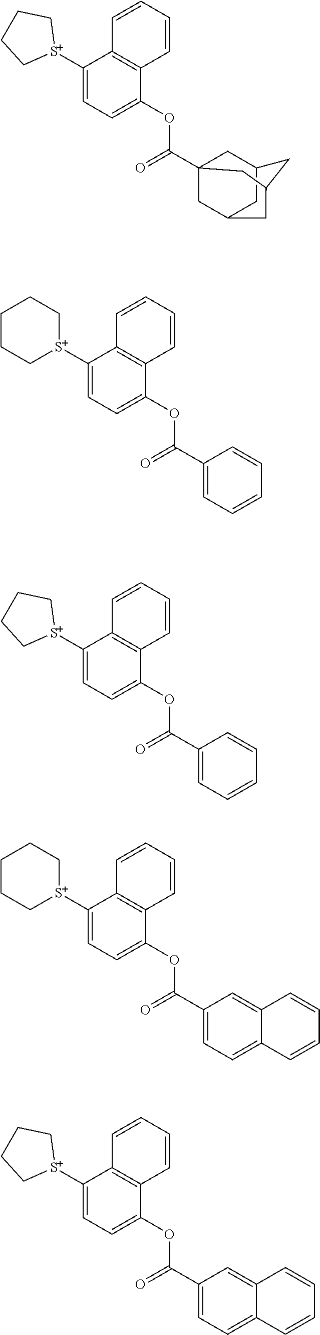

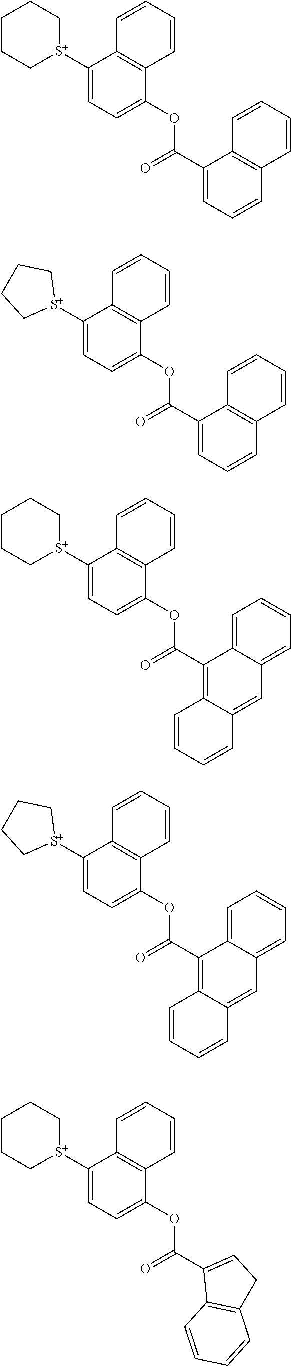

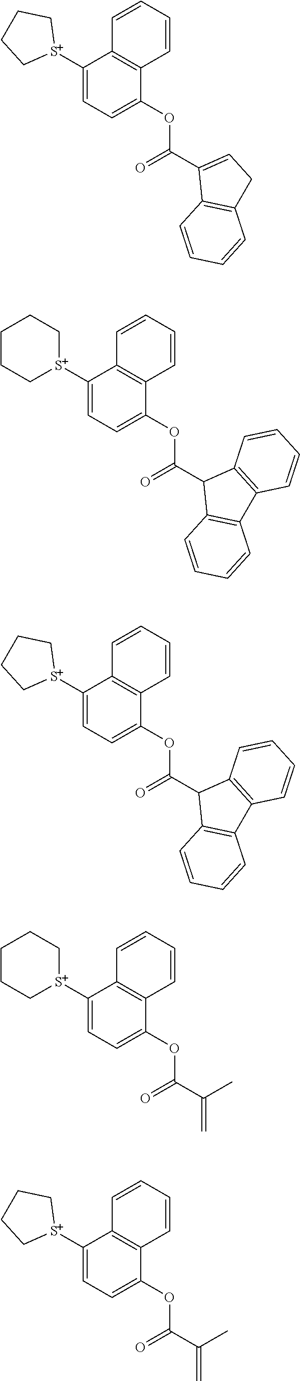

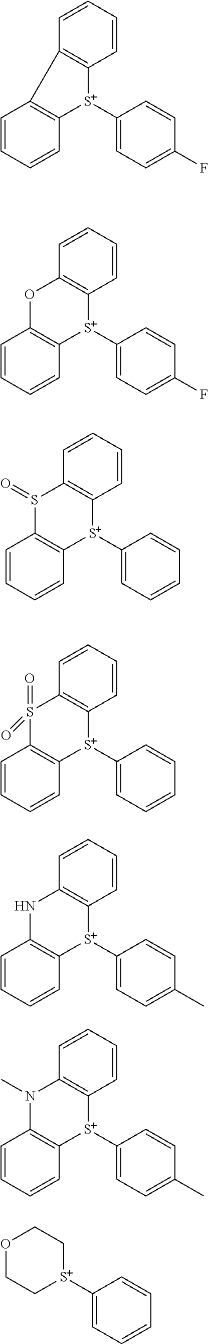

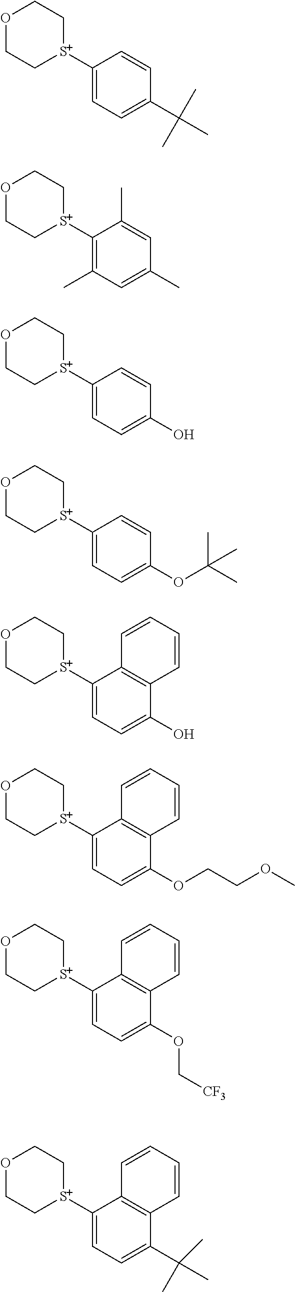

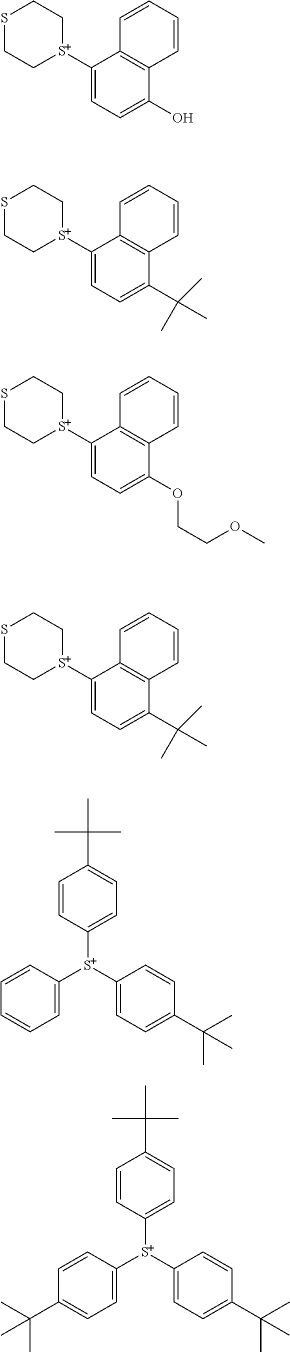

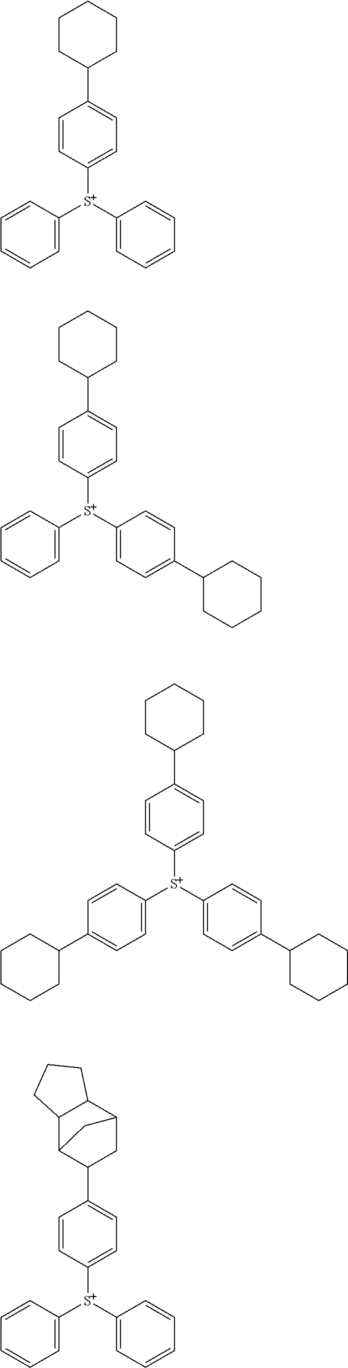

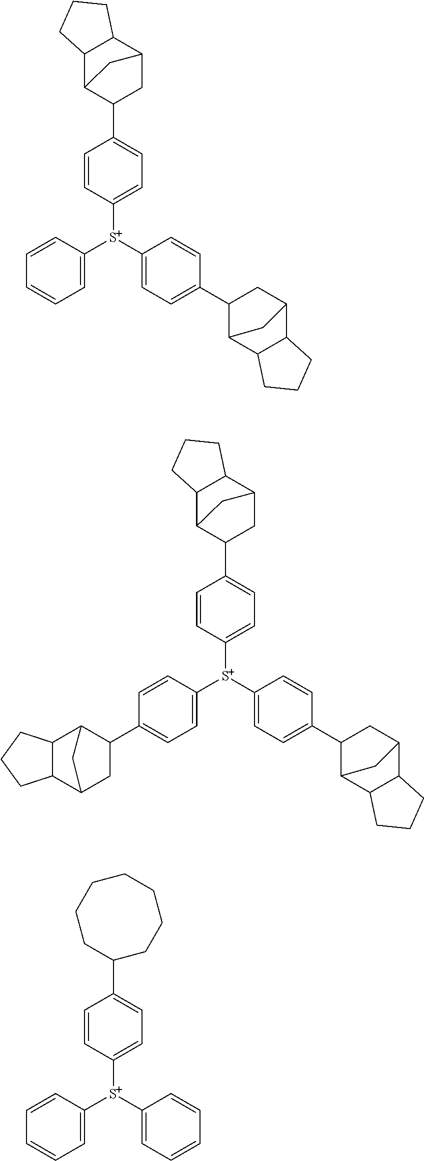

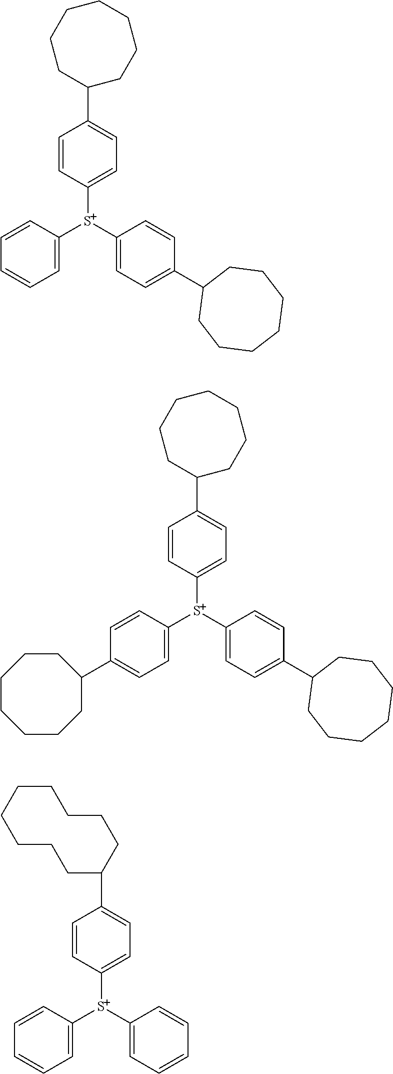

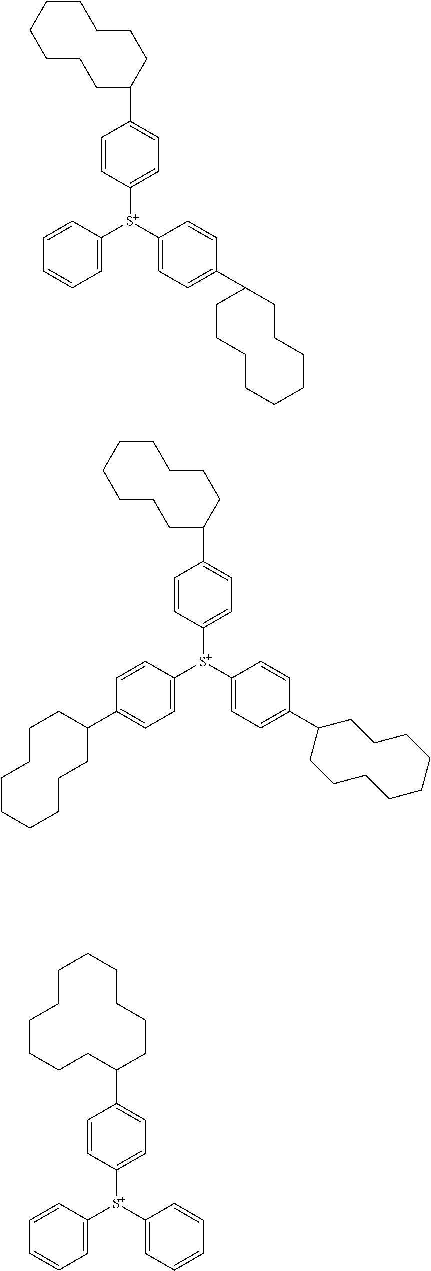

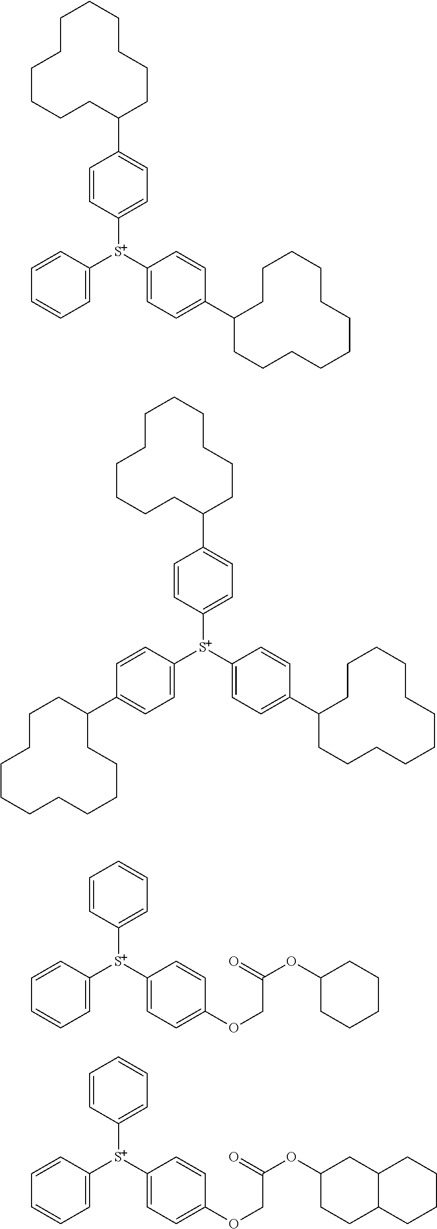

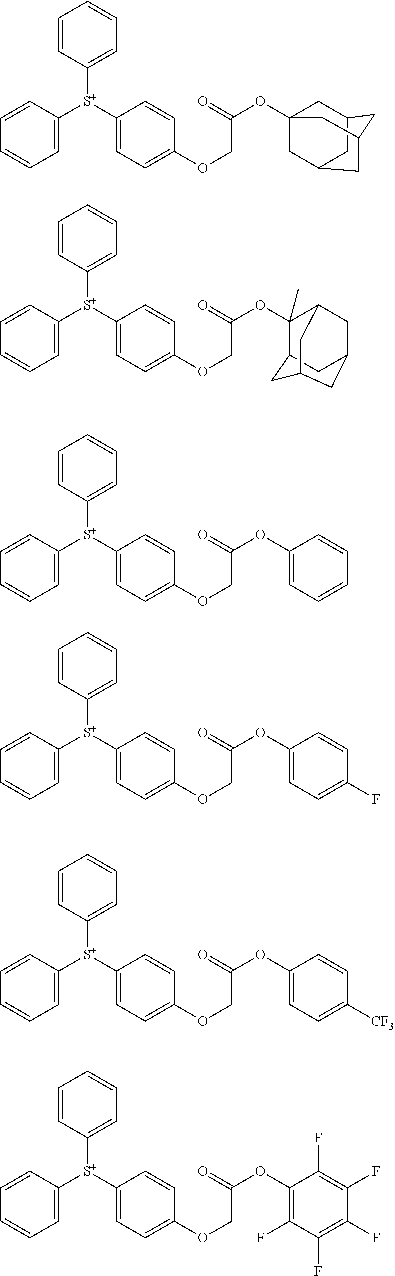

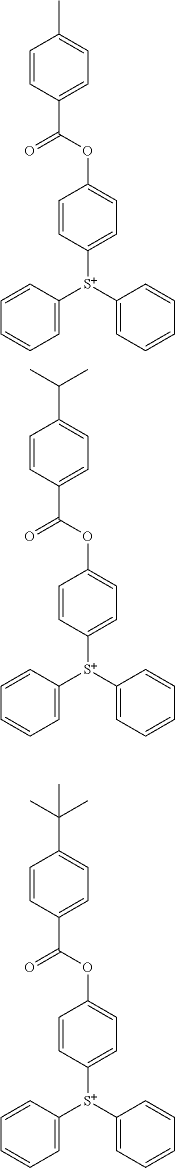

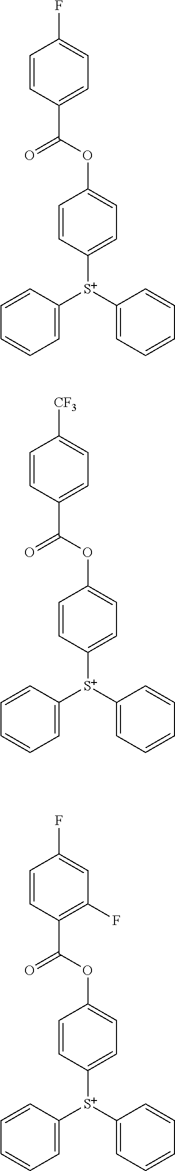

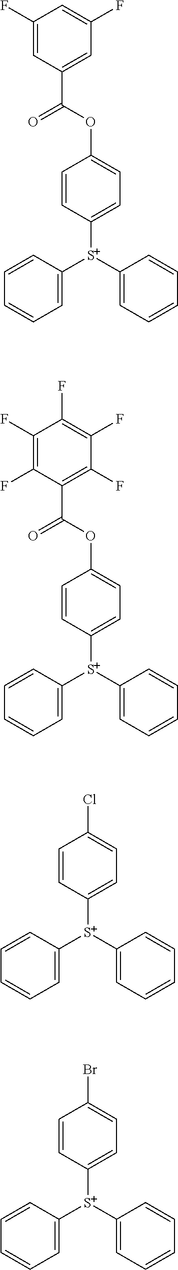

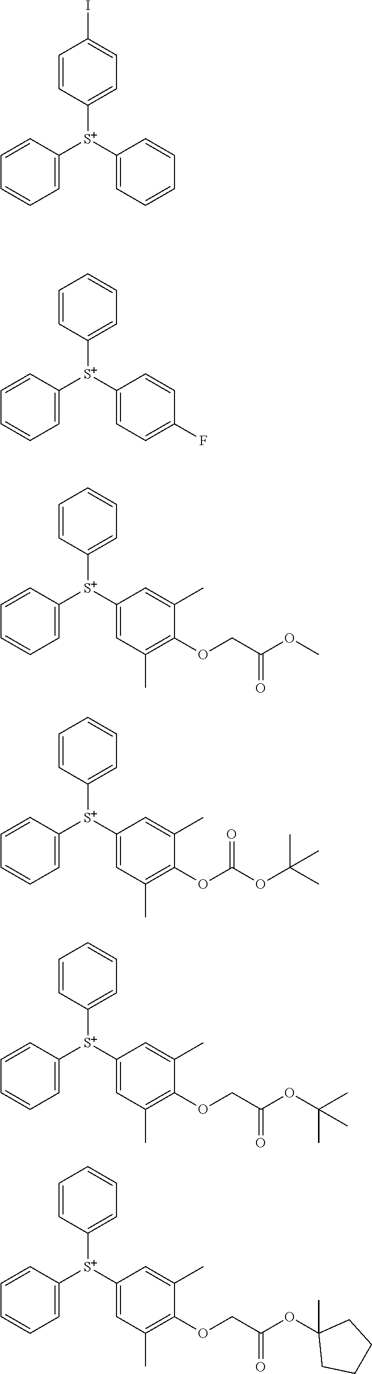

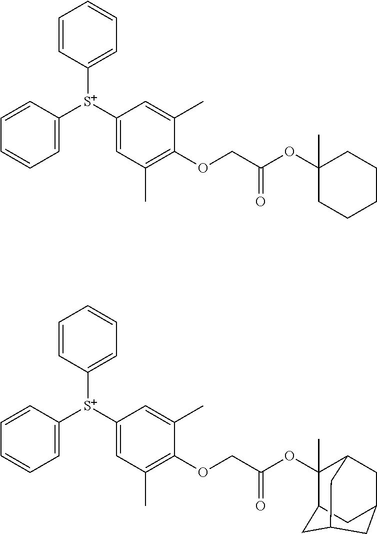

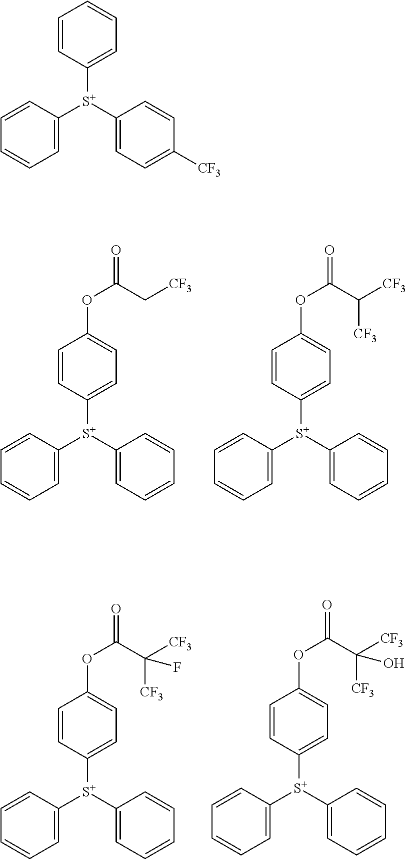

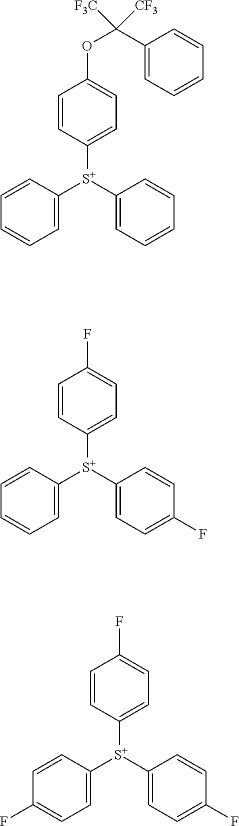

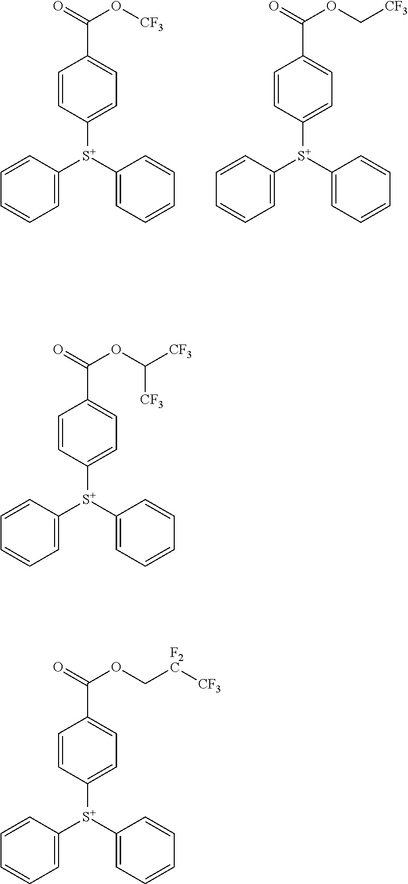

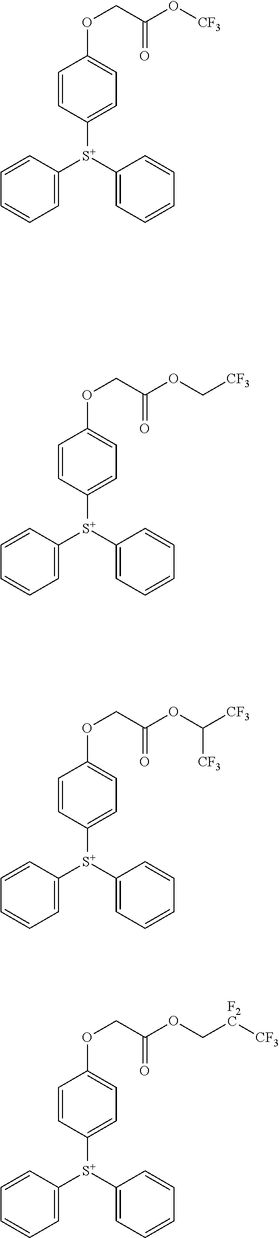

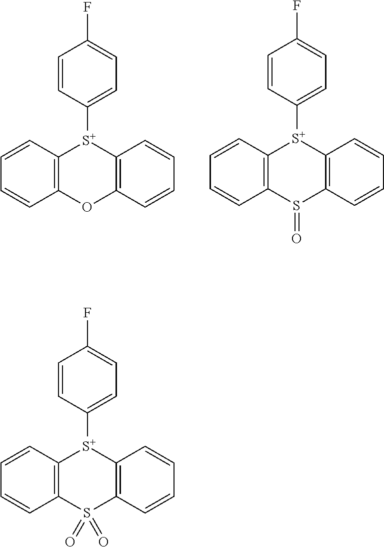

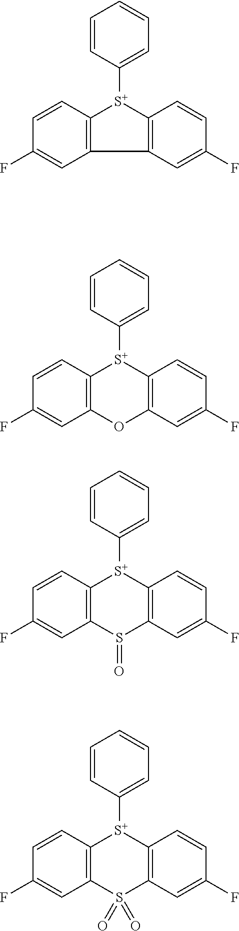

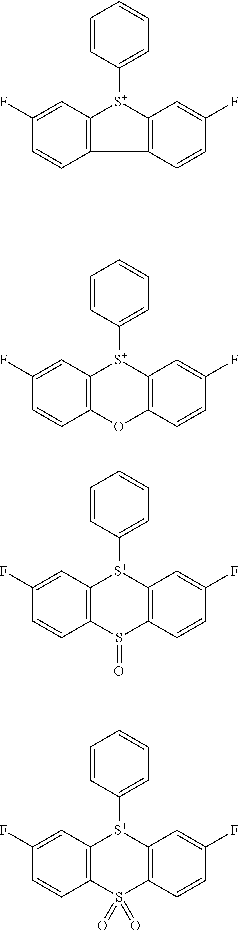

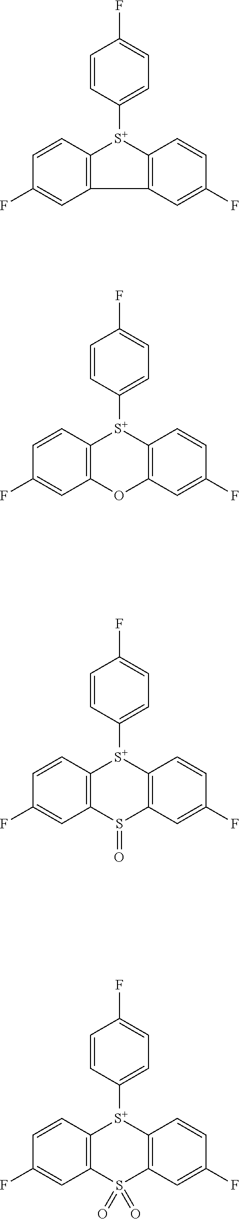

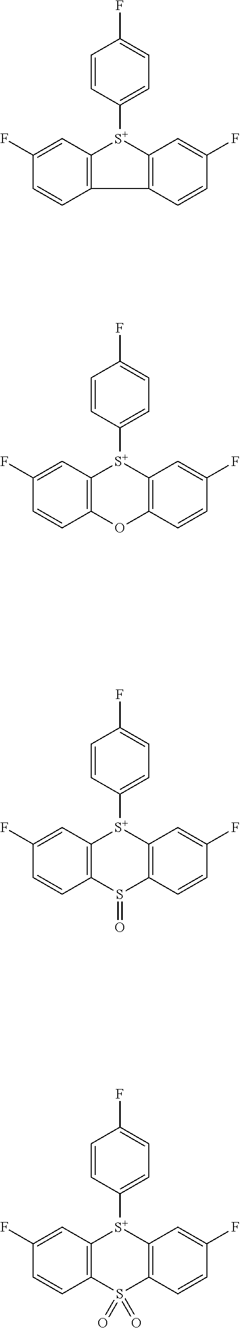

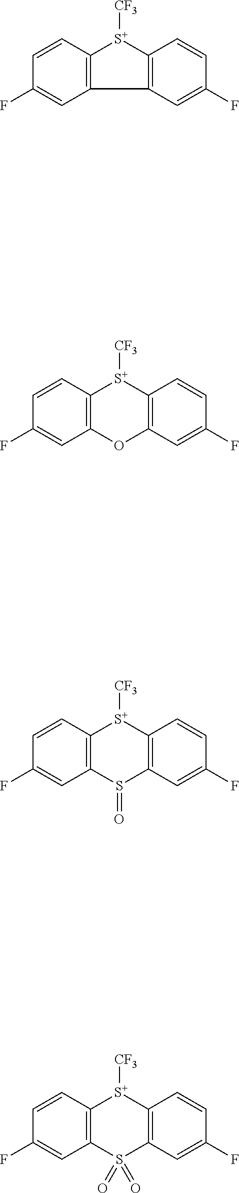

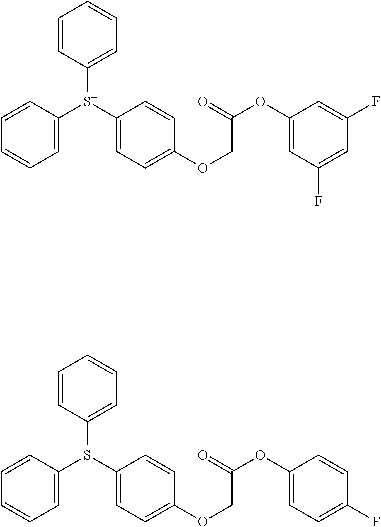

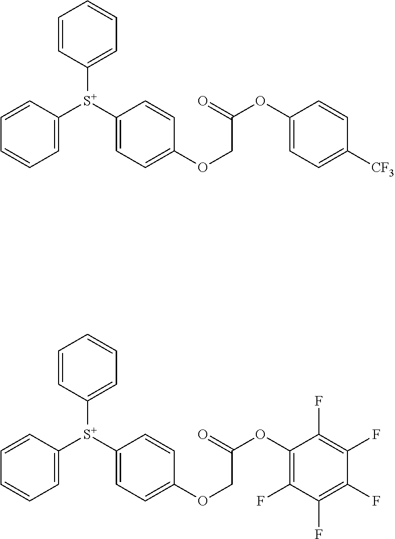

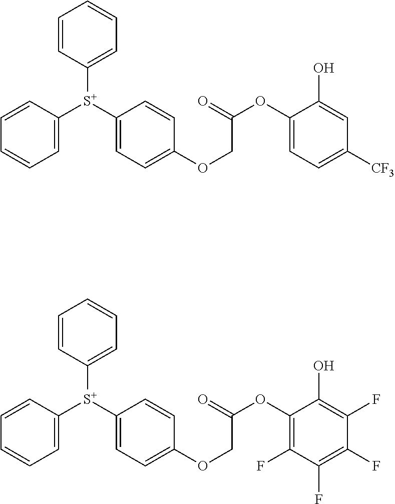

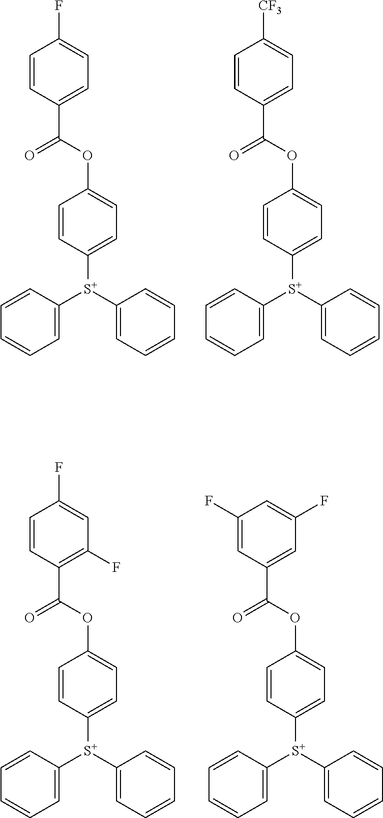

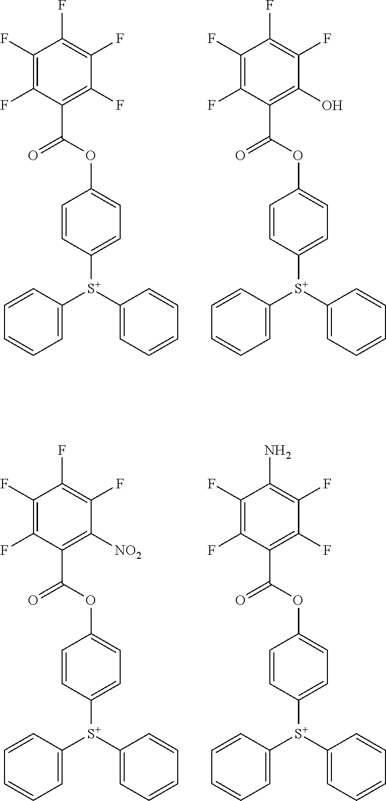

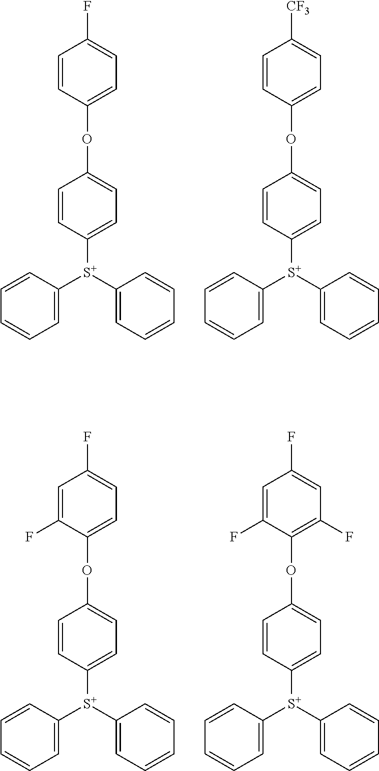

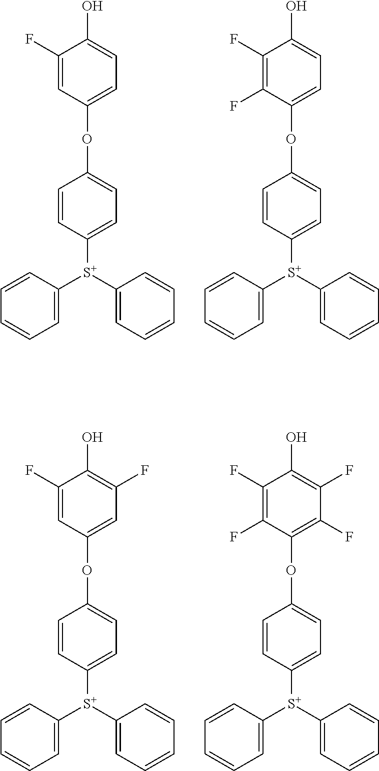

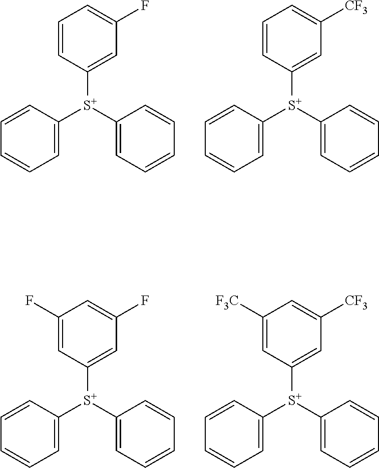

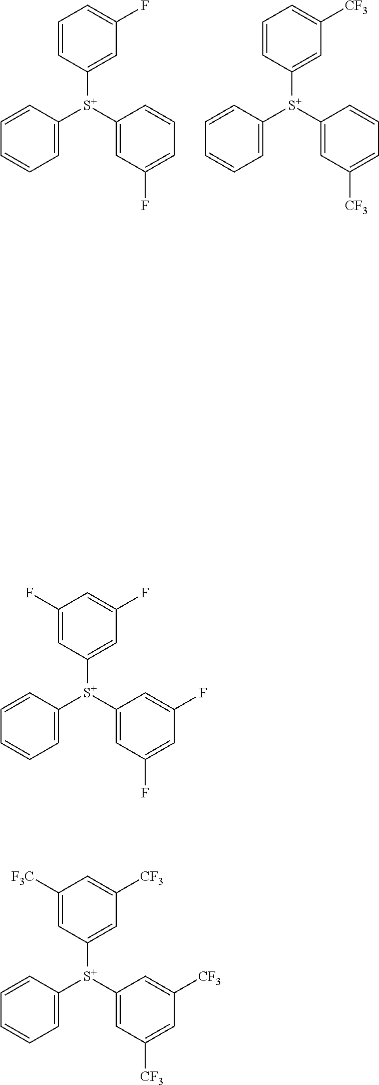

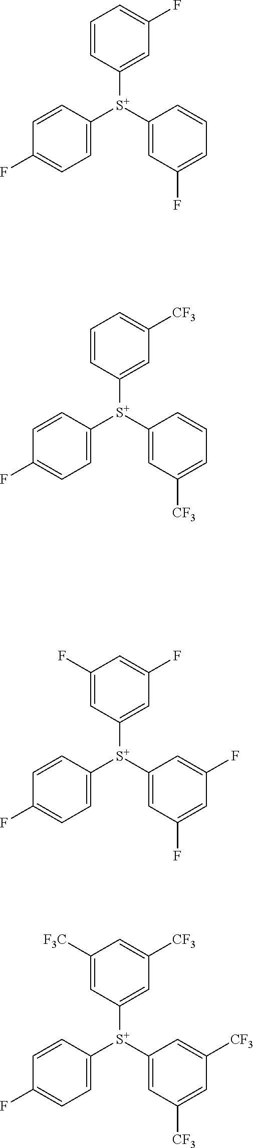

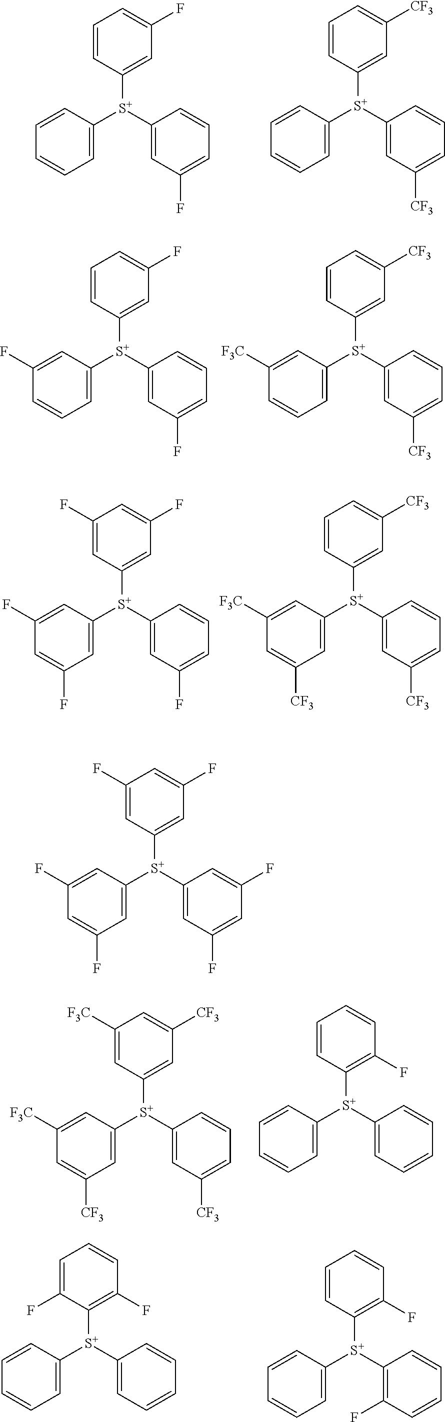

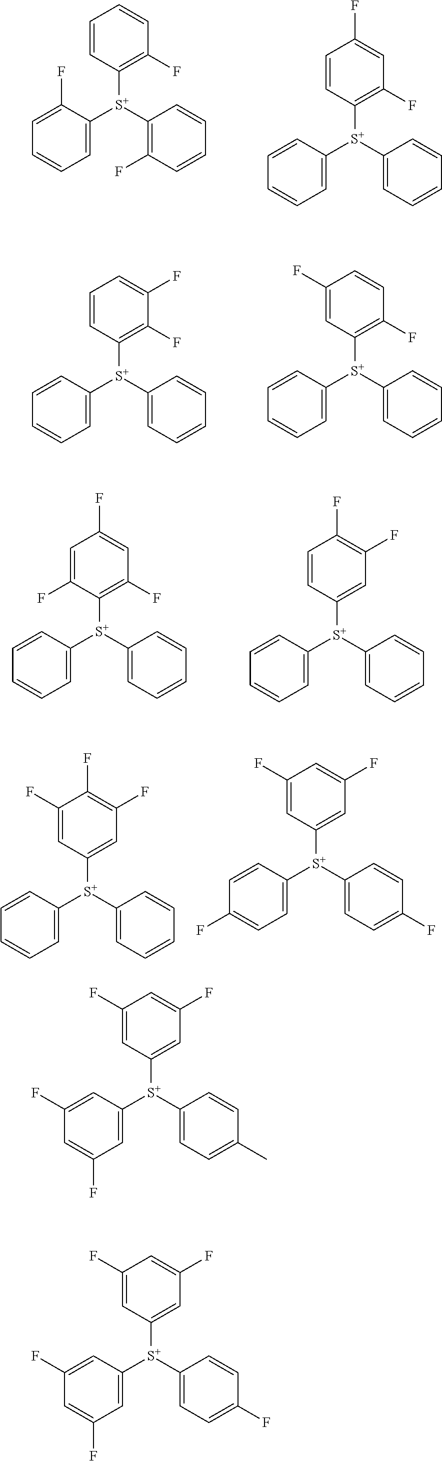

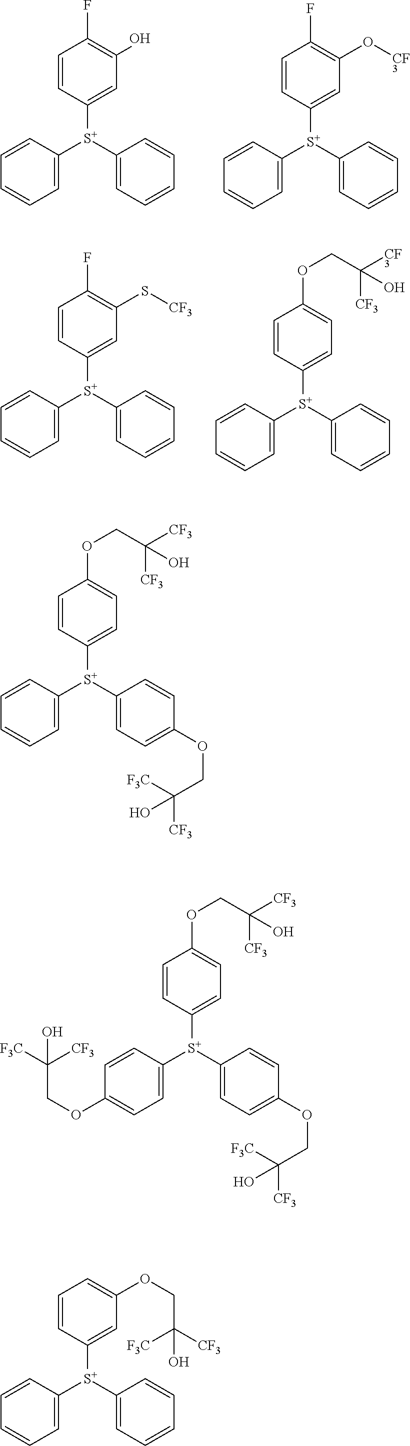

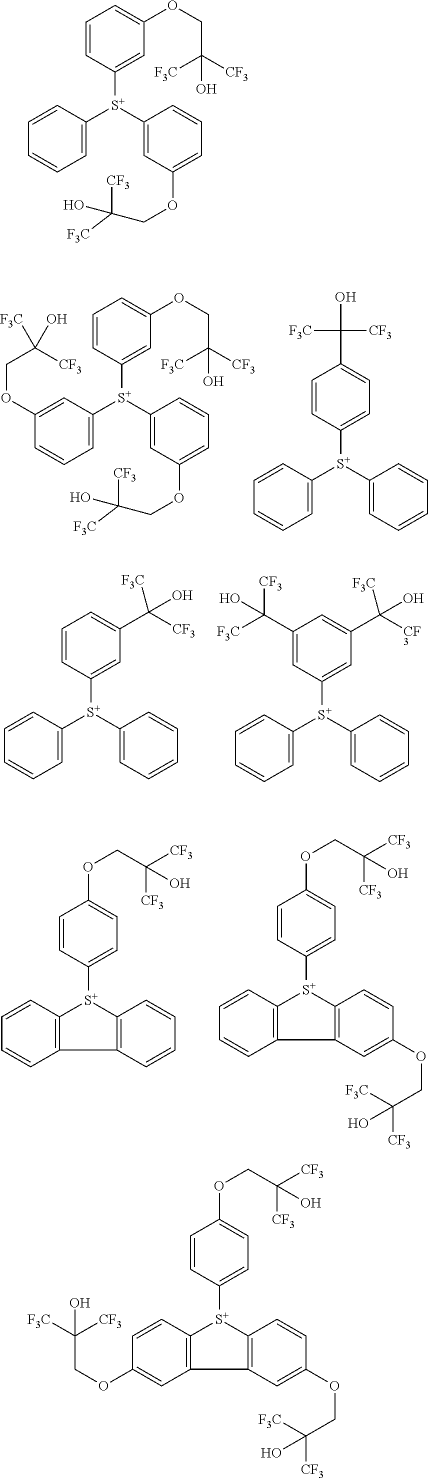

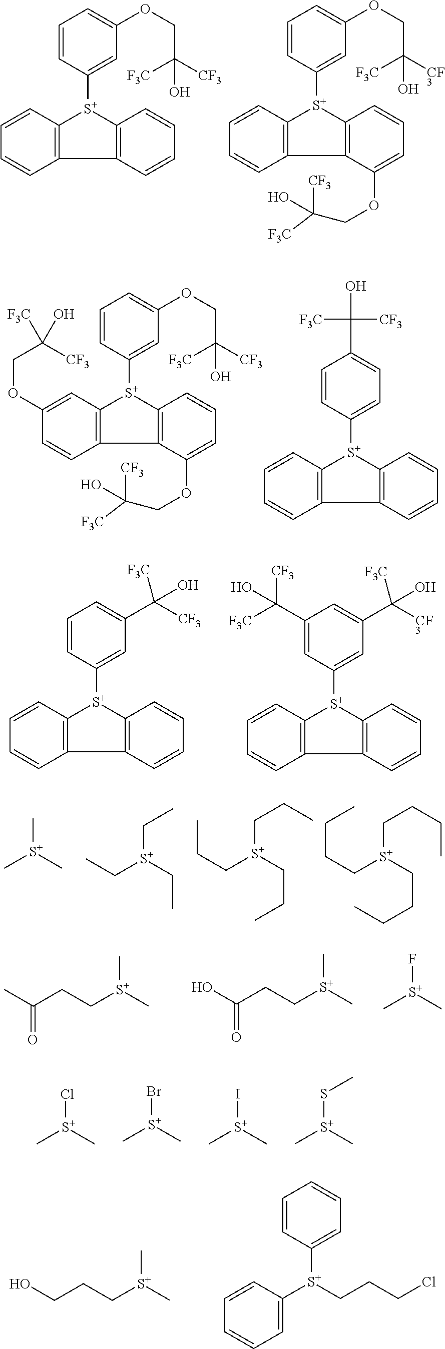

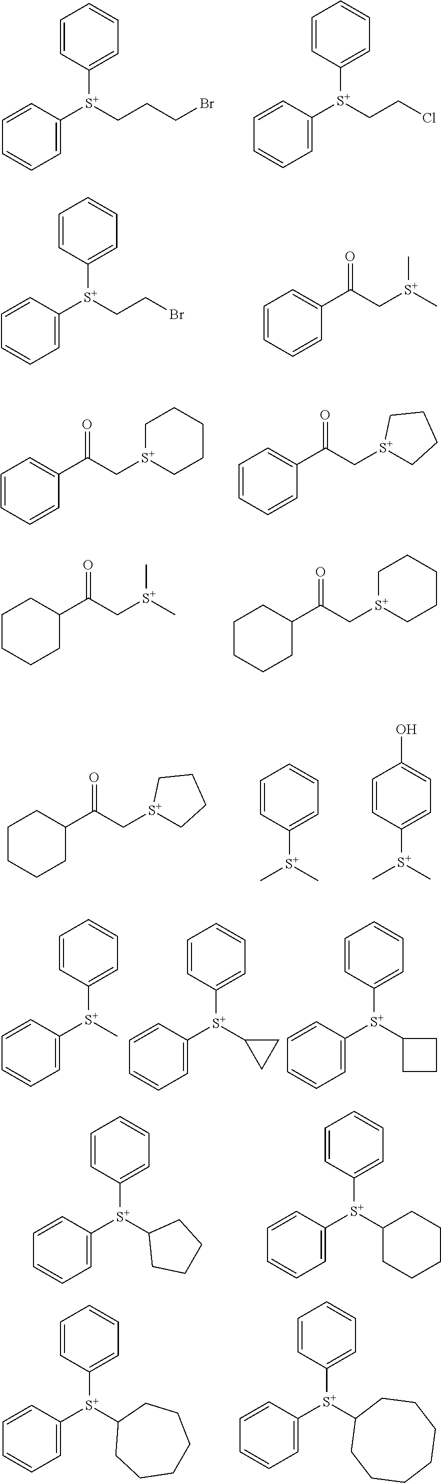

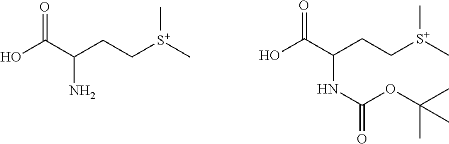

[Acid Generator: Sulfonium Salt of Sulfonate Ion bonded to Polymer Main Chain]

The acid generator which is a sulfonium salt bonded to a polymer main chain is preferably a sulfonium salt of fluorosulfonic acid, and may be shown by the following general formula (a1) or (a2).

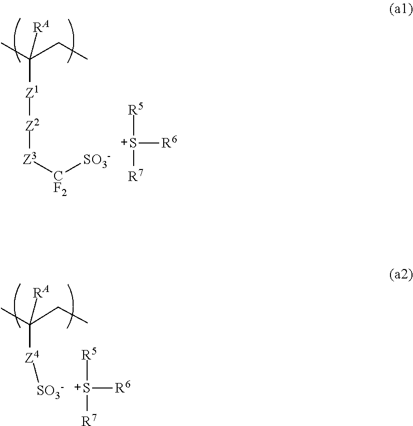

In the formulae, each R^{A} independently represents a hydrogen atom or a methyl group. Z¹ represents a single bond, an ester bond, or a phenylene group. Z² represents a single bond, —Z²¹—C(═O)—O—, —Z²¹—O—, or —Z²¹—O—C(═O)—. Z²¹ represents a hydrocarbylene group having 1 to 12 carbon atoms, a phenylene group, or a group which is a combination thereof having 7 to 18 carbon atoms, and the Z²¹ optionally contains a carbonyl group, an ester bond, an ether bond, a sulfur atom, an oxygen atom, a bromine atom, or an iodine atom. Z³ represents a methylene group, a 2,2,2-trifluoro-1,1-ethanediyl group, a hydrocarbon group having 2 to 4 carbon atoms optionally substituted with fluorine, or a carbonyl group. Z⁴ represents a fluorinated phenylene group, a phenylene group substituted with a trifluoromethyl group or an iodine atom, —Z⁴¹—, —O—Z⁴¹—, —C(═O)—O—Z⁴¹—, or —C(═O)—NH—Z⁴¹—. Z⁴¹ represents a fluorinated phenylene group, a phenylene group substituted with a trifluoromethyl group or an iodine atom, or a hydrocarbylene group having 1 to 15 carbon atoms substituted with a halogen atom and optionally containing an ester group and/or an aromatic hydrocarbon group therein. R⁵ to R⁷ each independently represent a hydrocarbyl group having 1 to 25 carbon atoms, and optionally have an oxygen atom, a sulfur atom, a nitrogen atom, or a halogen atom other than fluorine. Alternatively, R⁵ and R⁶, or R⁵ and R⁷, are optionally bonded with each other to form a ring with a sulfur atom that is bonded to R⁵ and R⁶, or R⁵ and R⁷.

Hereinafter, the repeating unit shown by the general formula (a1) is referred to as “repeating unit-a1”, and the repeating unit shown by the general formula (a2) is referred to as “repeating unit-a2”.

In the sulfonate ion of the repeating unit-a1 or -a2, the number of fluorine atoms is preferably one or more, more preferably two or more, further preferably three or more, particularly preferably four or more.

Examples of the anion of a monomer to give the repeating unit-a1 include ones shown below, but are not limited thereto. Note that, in the following formulae, R^{A} is as defined above.

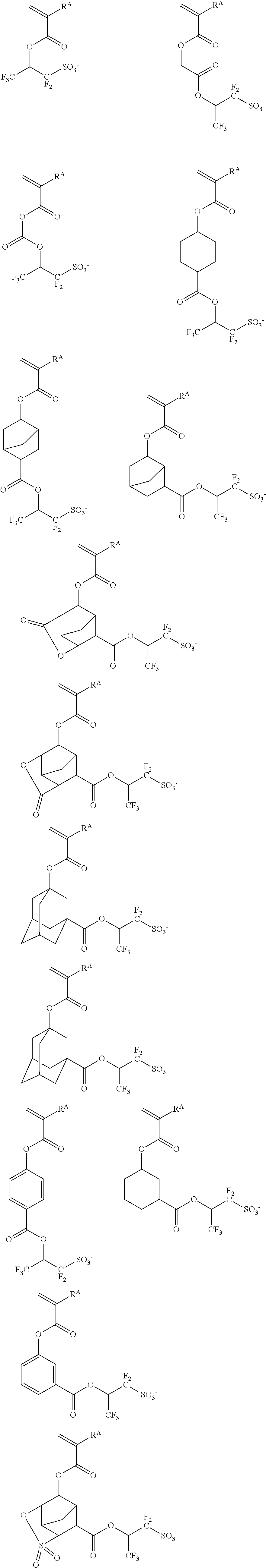

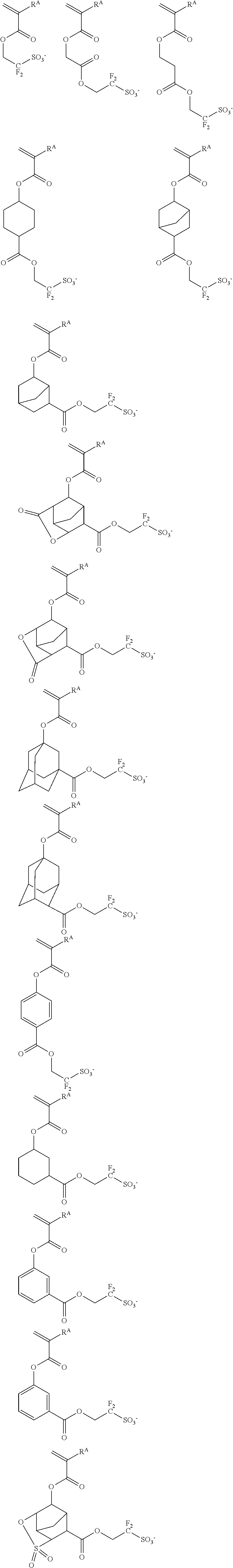

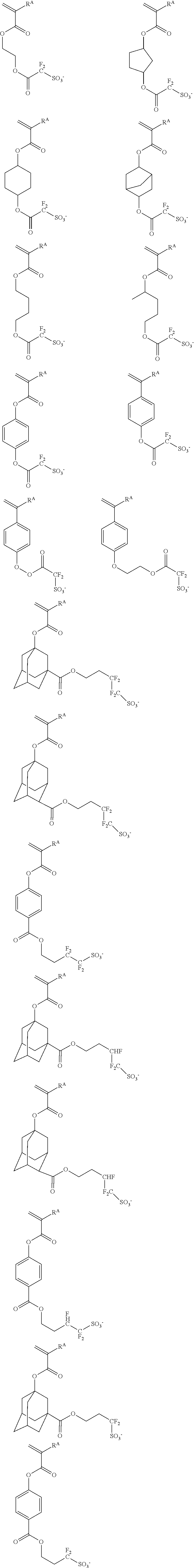

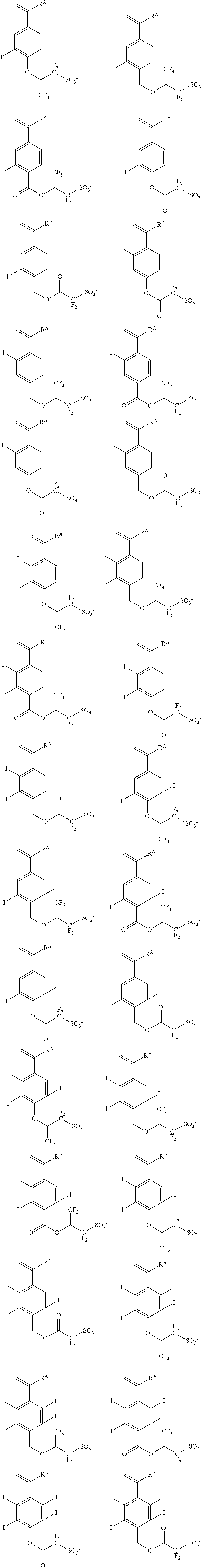

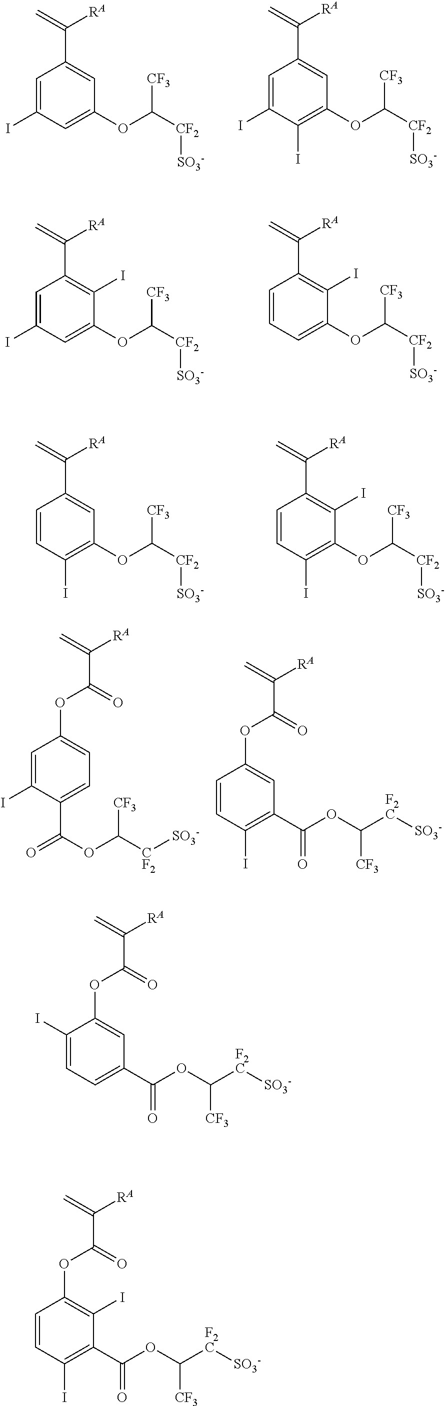

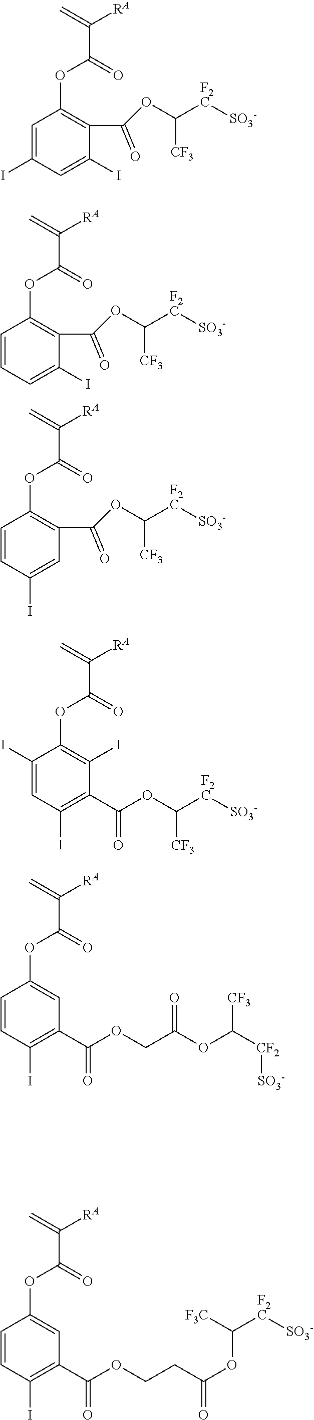

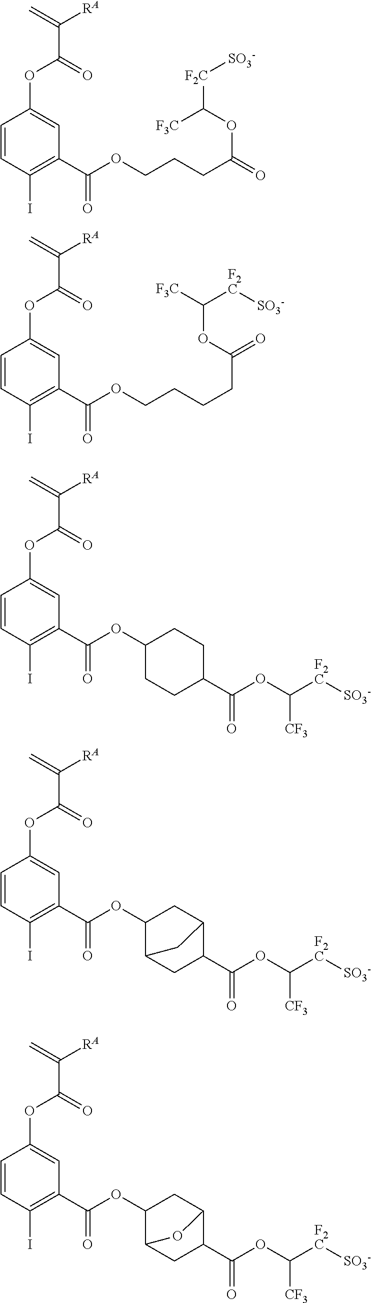

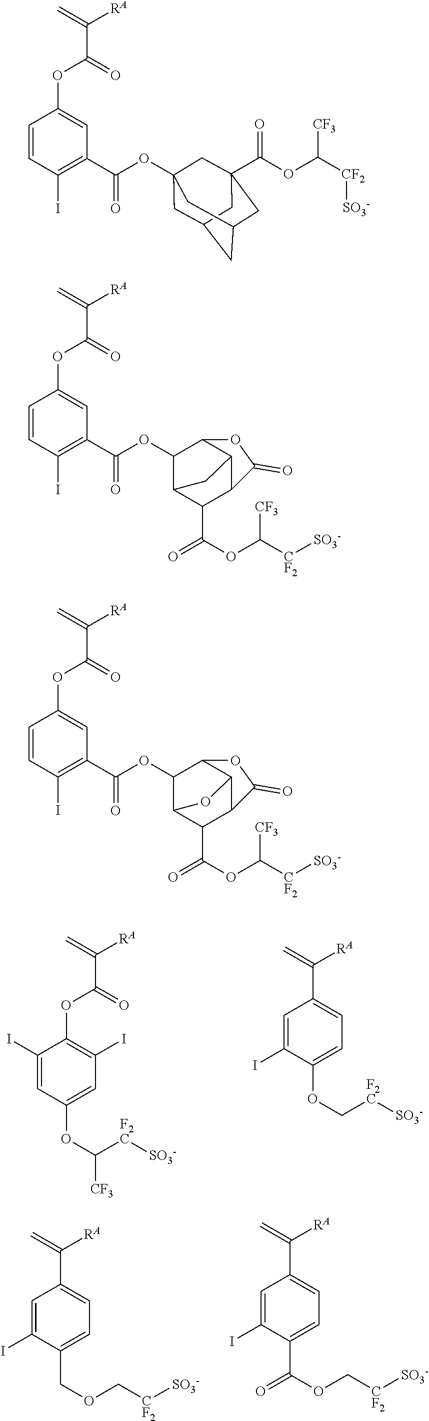

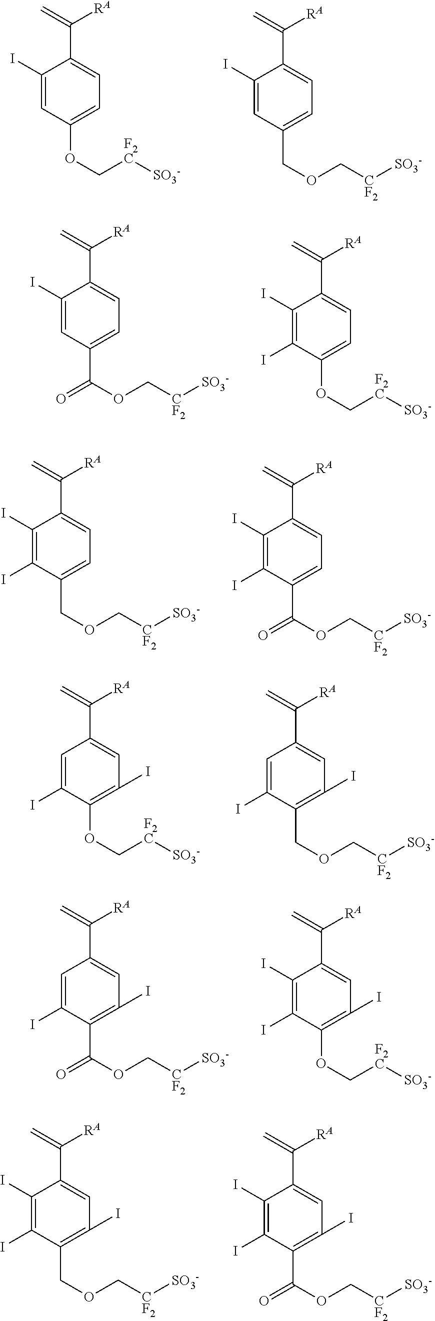

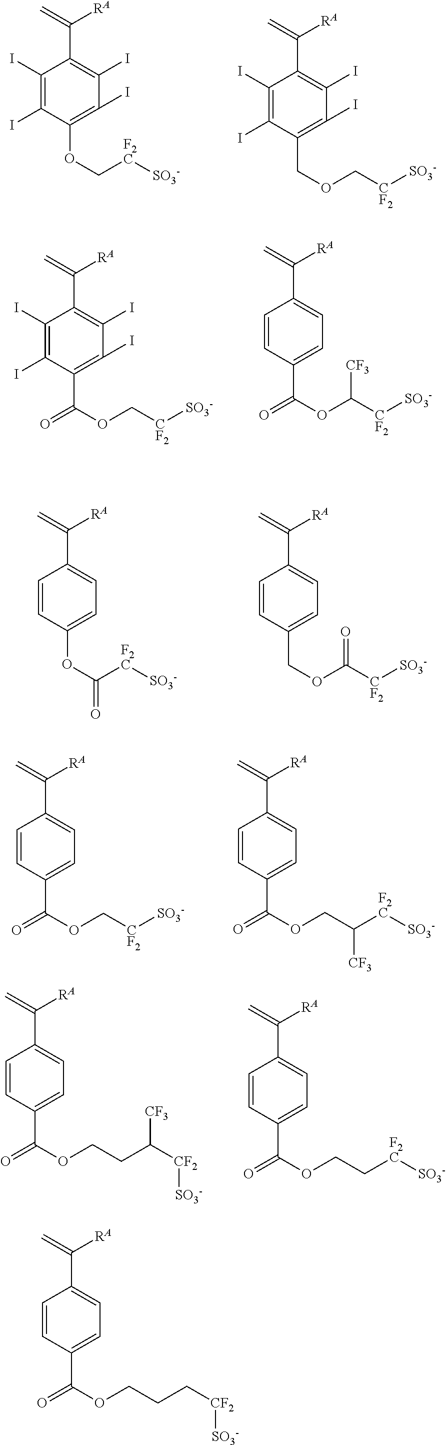

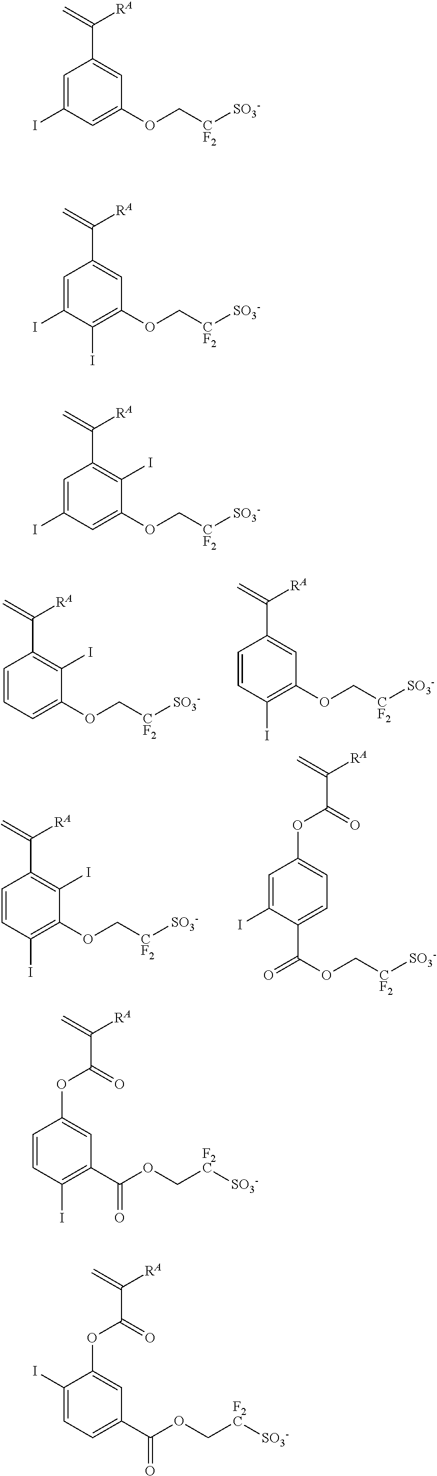

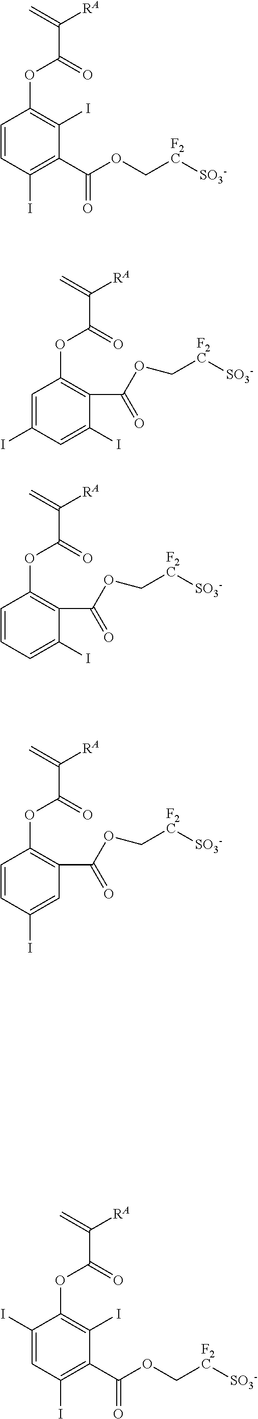

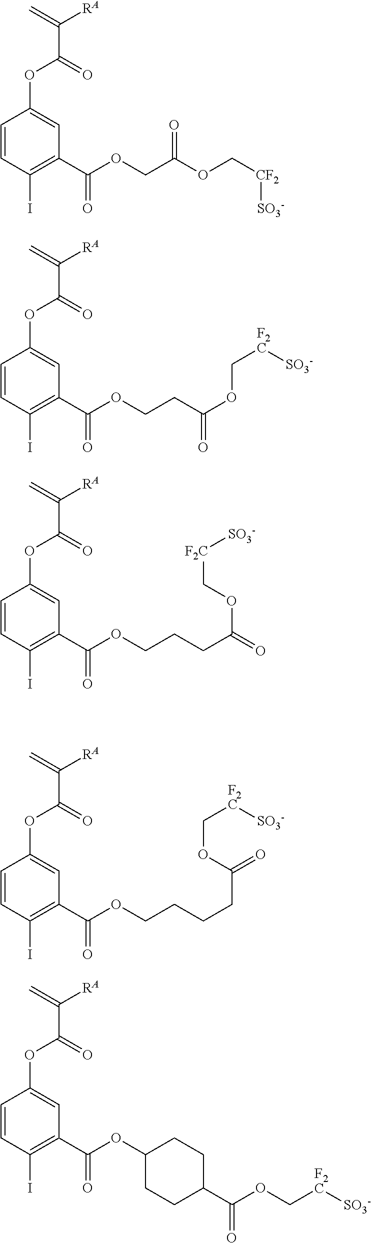

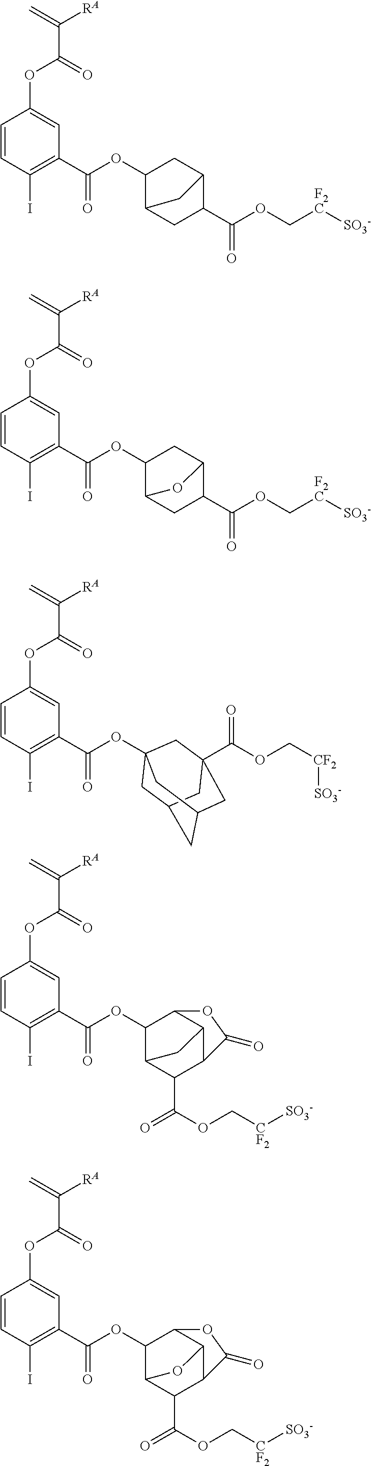

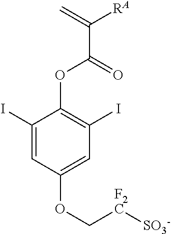

Examples of the anion of a monomer to give the repeating unit-a2 include ones shown below, but are not limited thereto. Note that, in the following formulae, R^{A} is as defined above.

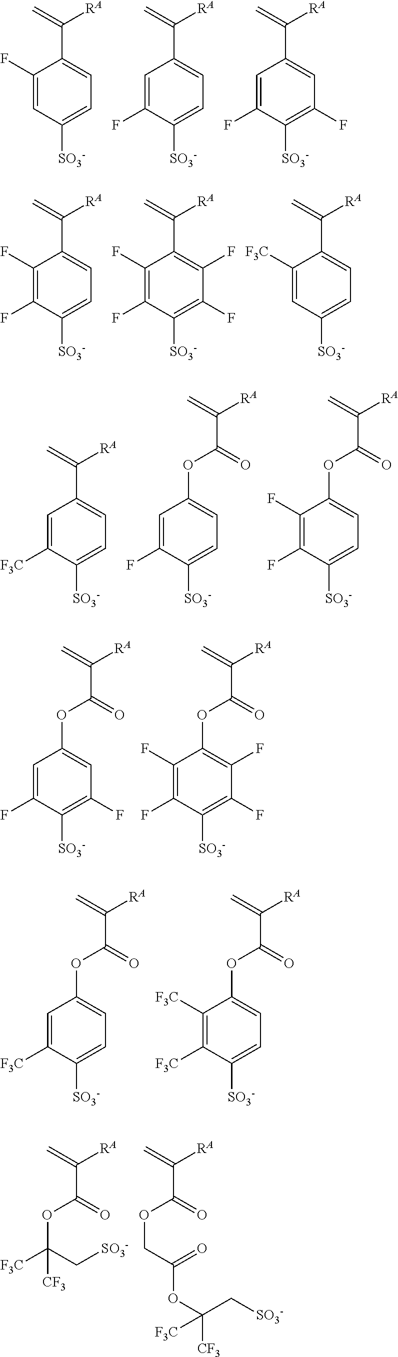

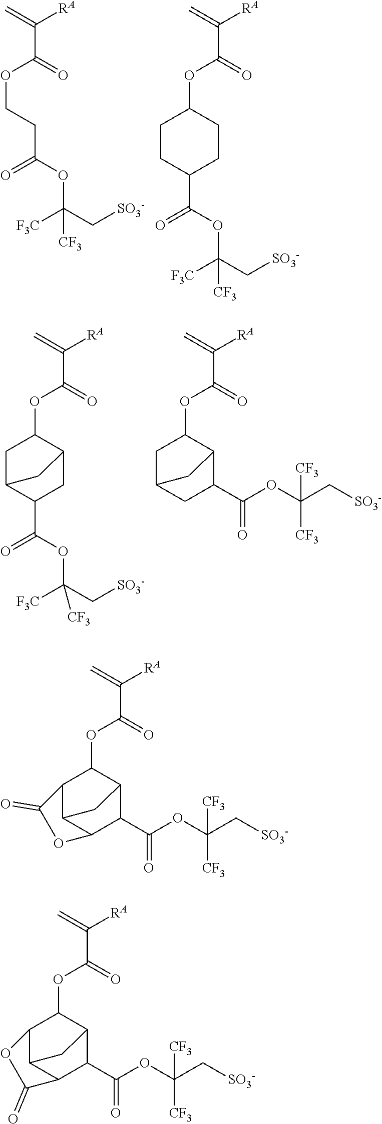

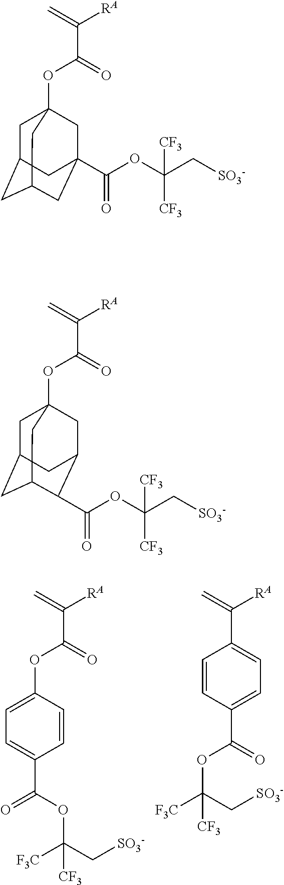

Examples of the cations of sulfonium salts of the repeating units-a1 and -a2 include, but are not limited to, the above-exemplified cations of the sulfonium salt shown in the general formula (1) which have no fluorine atom in the structures.

Preferably, a base polymer contains a repeating unit in which a hydrogen atom of a carboxy group is substituted with an acid labile group and/or a repeating unit in which a hydrogen atom of a phenolic hydroxy group is substituted with an acid labile group, the repeating units being respectively a repeating unit shown by the following general formula (b1) and a repeating unit shown by the following general formula (b2).

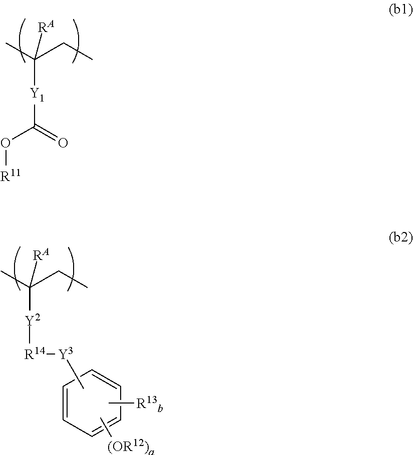

In the formulae, each R^{A} independently represents a hydrogen atom or a methyl group. Y¹ represents a single bond, a phenylene group, a naphthylene group, or a linking group having 1 to 15 carbon atoms containing at least one selected from an ester bond, an ether bond, and a lactone ring. Y² represents a single bond, an ester bond, or an amide bond. Y³ represents a single bond, an ether bond, or an ester bond. R¹¹ and R¹² each represent an acid labile group. R¹³ represents a fluorine atom, a trifluoromethyl group, a cyano group, or a saturated hydrocarbyl group having 1 to 6 carbon atoms. R¹⁴ represents a single bond or an alkanediyl group having 1 to 6 carbon atoms, and some of the carbon atoms are optionally substituted with an ether bond or an ester bond. “a” represents 1 or 2, and “b” represents an integer of 0 to 4, with 1≤a+b≤5.

Examples of a monomer to give the repeating unit shown by the general formula (b1) (repeating unit-b1) include ones shown below, but are not limited thereto. Note that, in the following formulae, R^{A} and R¹¹ are as defined above.

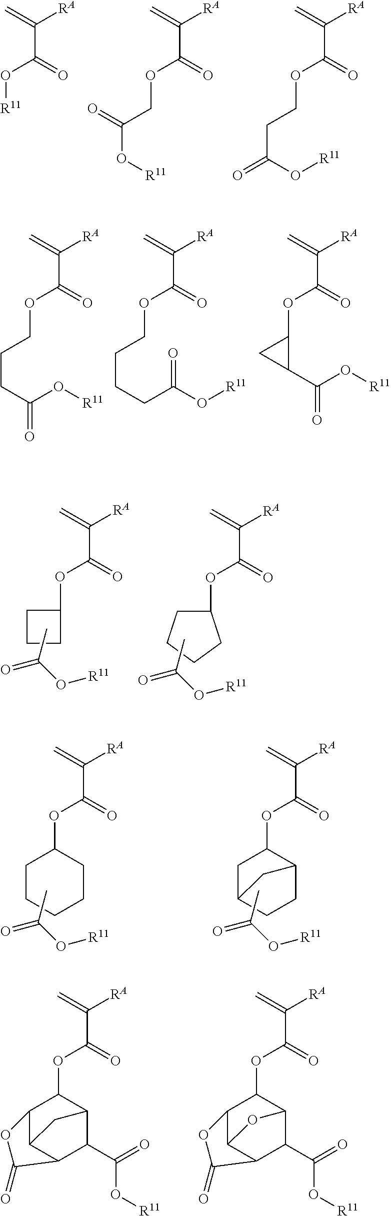

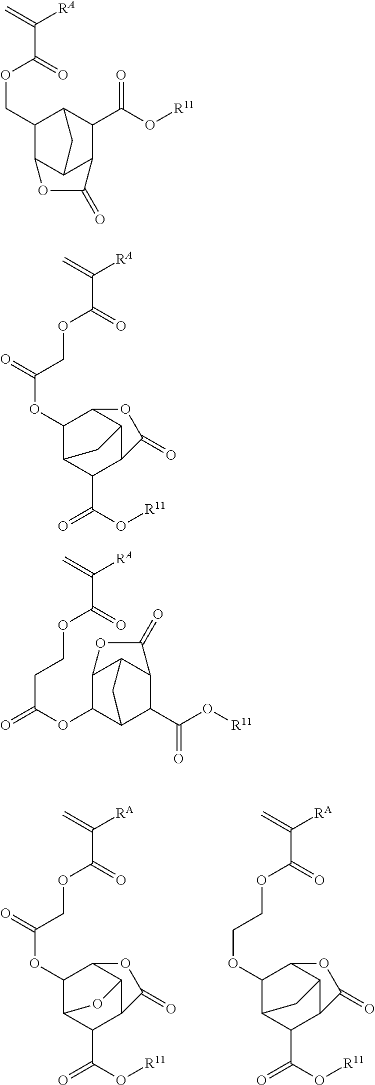

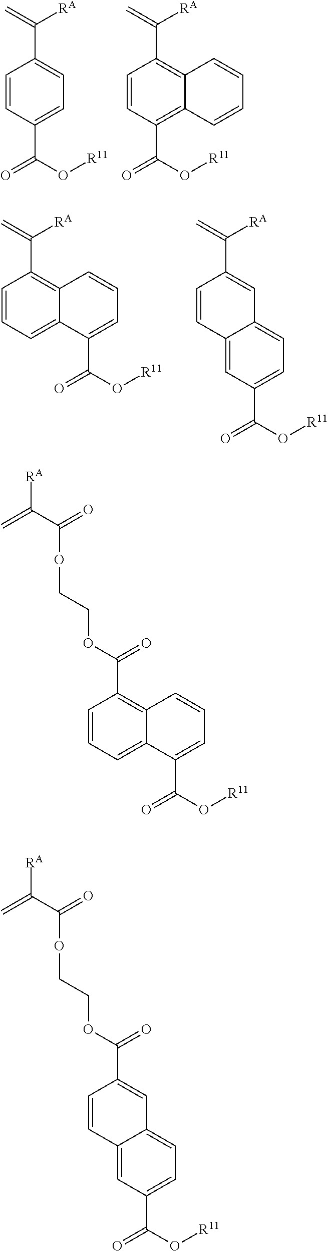

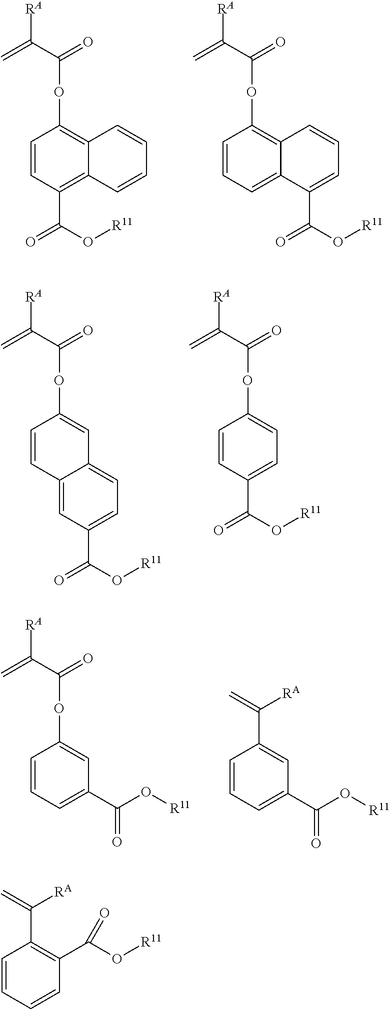

Examples of a monomer to give the repeating unit shown by the general formula (b2) (repeating unit-b2) include ones shown below, but are not limited thereto. Note that, in the following formulae, R^{A} and R¹² are as defined above.

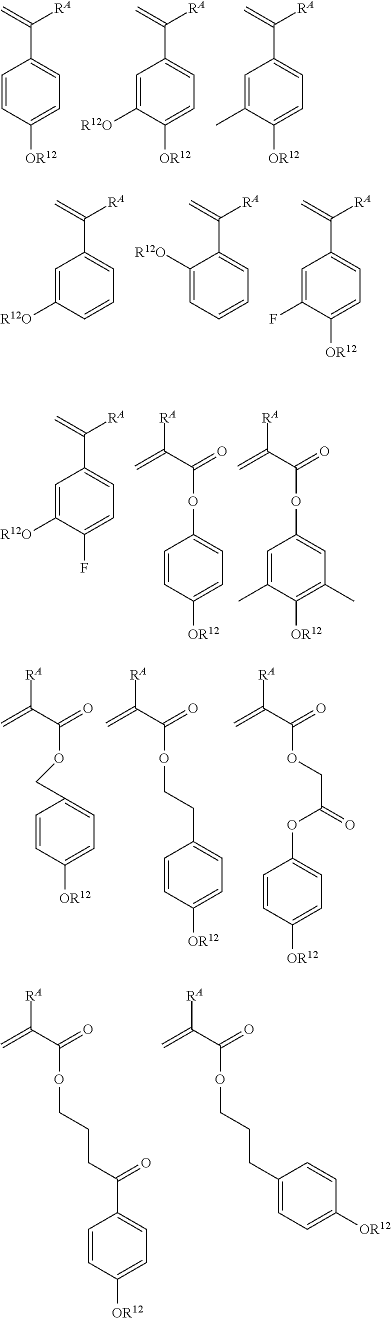

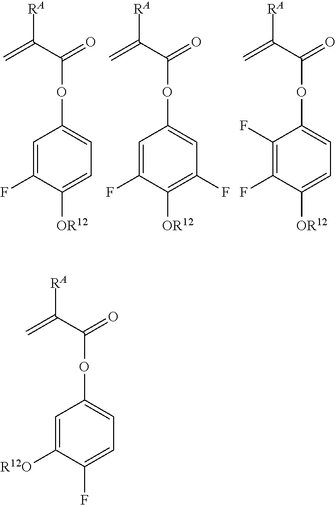

Various acid labile groups shown by R¹¹ or R¹² can be selected. Examples thereof include ones shown by the following general formulae (AL-1) to (AL-3).

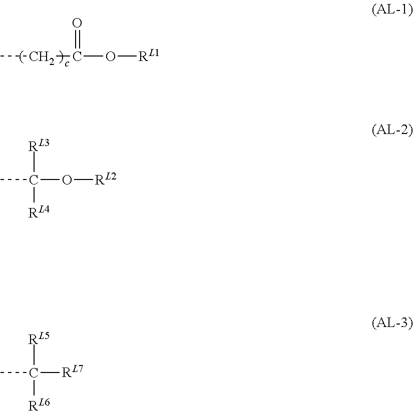

In the general formula (AL-1), “c” represents an integer of 0 to 6. R^{L1} represents a tertiary hydrocarbyl group having 4 to 61 carbon atoms, preferably 4 to 15 carbon atoms; a trihydrocarbylsilyl group in which hydrocarbyl groups are each a saturated hydrocarbyl group having 1 to 6 carbon atoms; a saturated hydrocarbyl group having 4 to 20 carbon atoms containing a carbonyl group, an ether bond, or an ester bond; or a group shown by the formula (AL-3).

The tertiary hydrocarbyl group represented by R^{L1} may be saturated or unsaturated, and may be branched or cyclic. Specific examples thereof include a tert-butyl group, a tert-pentyl group, a 1,1-diethylpropyl group, a 1-ethylcyclopentyl group, a 1-butylcyclopentyl group, a 1-ethylcyclohexyl group, a 1-butylcyclohexyl group, a 1-ethyl-2-cyclopentenyl group, a 1-ethyl-2-cyclohexenyl group, a 2-methyl-2-adamantyl group, etc. Examples of the trialkylsilyl group (trihydrocarbylsilyl group) include a trimethylsilyl group, a triethylsilyl group, a dimethyl-tert-butylsilyl group, etc. The saturated hydrocarbyl group containing a carbonyl group, an ether bond, or an ester bond may be linear, branched, or cyclic, and is preferably cyclic. Specific examples thereof include a 3-oxocyclohexyl group, a 4-methyl-2-oxooxan-4-yl group, a 5-methyl-2-oxooxolan-5-yl group, a 2-tetrahydropyranyl group, a 2-tetrahydrofuranyl group, etc.

Examples of the acid labile group shown by the general formula (AL-1) include a tert-butoxycarbonyl group, a tert-butoxycarbonylmethyl group, a tert-pentyloxycarbonyl group, a tert-pentyloxycarbonylmethyl group, a 1,1-diethylpropyloxycarbonyl group, a 1,1-diethylpropyloxycarbonylmethyl group, a 1-ethylcyclopentyloxycarbonyl group, a 1-ethylcyclopentyloxycarbonylmethyl group, a 1-ethyl-2-cyclopentenyloxycarbonyl group, a 1-ethyl-2-cyclopentenyloxycarbonylmethyl group, a 1-ethoxyethoxycarbonylmethyl group, a 2-tetrahydropyranyloxycarbonylmethyl group, a 2-tetrahydrofuranyloxycarbonylmethyl group, etc.

Other examples of the acid labile group shown by the general formula (AL-1) include groups shown by the following general formulae (AL-1)-1 to (AL-1)-10.

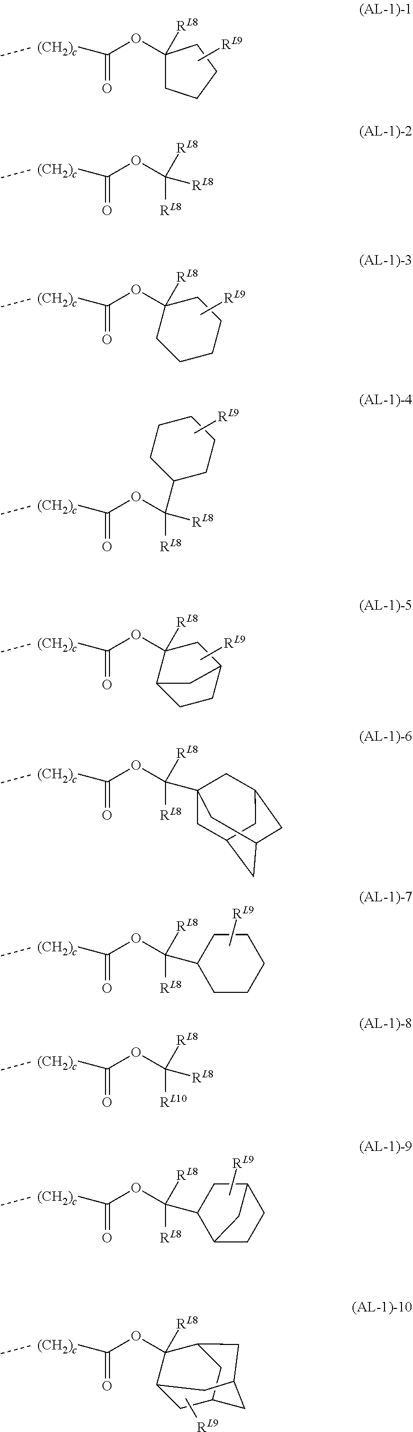

In the formulae, each broken line represents an attachment point.

In the general formulae (AL-1)-1 to (AL-1)-10, “c” is as defined above. Each R^{L8} independently represents a saturated hydrocarbyl group having 1 to 10 carbon atoms or an aryl group having 6 to 20 carbon atoms. R^{L9} represents a hydrogen atom or a saturated hydrocarbyl group having 1 to 10 carbon atoms. R^{L10} represents a saturated hydrocarbyl group having 2 to 10 carbon atoms or an aryl group having 6 to 20 carbon atoms. The saturated hydrocarbyl groups may be linear, branched, or cyclic.

In the general formula (AL-2), R^{L3} and R^{L4} each independently represent a hydrogen atom or a saturated hydrocarbyl group having 1 to 18 carbon atoms, preferably 1 to 10 carbon atoms. The saturated hydrocarbyl group may be linear, branched, or cyclic. Specific examples thereof include a methyl group, an ethyl group, a propyl group, an isopropyl group, an n-butyl group, a sec-butyl group, a tert-butyl group, a cyclopentyl group, a cyclohexyl group, a 2-ethylhexyl group, an n-octyl group, etc.

In the general formula (AL-2), R^{L2} represents a hydrocarbyl group having 1 to 18 carbon atoms, preferably 1 to 10 carbon atoms, and optionally contains a heteroatom. The hydrocarbyl group may be saturated or unsaturated, and may be linear, branched, or cyclic. Examples of the hydrocarbyl group include saturated hydrocarbyl groups having 1 to 18 carbon atoms, etc., and some of the hydrogen atoms thereof may be substituted with a hydroxy group, an alkoxy group, an oxo group, an amino group, an alkylamino group, or the like. Examples of such substituted saturated hydrocarbyl groups include ones shown below, etc.

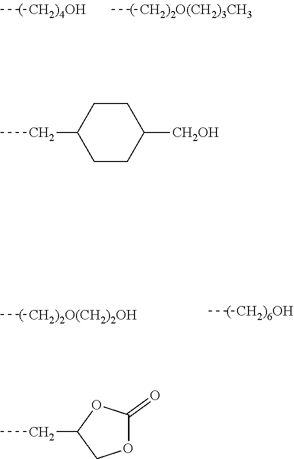

In the formulae, each broken line represents an attachment point.

R^{L2} and R^{L3}, R^{L2} and R^{L4}, or R^{L3} and R^{L4}, optionally bond with each other to form a ring together with a carbon atom bonded with R^{L2} and R^{L3}, R^{L2} and R^{L4}, or R^{L3} and R^{L4}, or together with the carbon atom and an oxygen atom. In this case, R^{L2} and R^{L3}, R^{L2} and R^{L4}, or R^{L3} and R^{L4}, involved in the ring formation each independently represent an alkanediyl group having 1 to 18 carbon atoms, preferably 1 to 10 carbon atoms. The number of carbon atoms in the ring obtained by bonding these is preferably 3 to 10, more preferably 4 to 10.

Examples of the linear and branched acid labile groups shown by the general formula (AL-2) include ones shown by the following formulae (AL-2)-1 to (AL-2)-69, but are not limited thereto. Note that, in the following formulae, each broken line represents an attachment point.

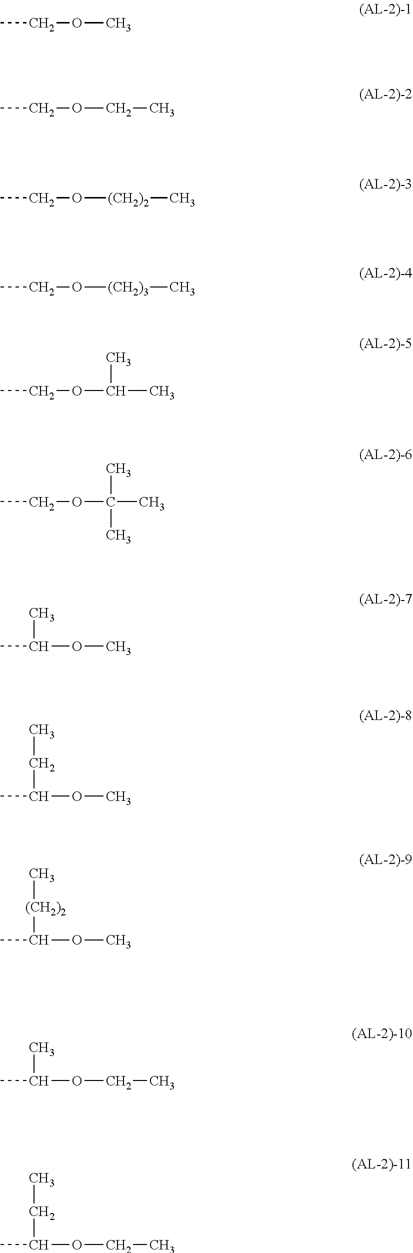

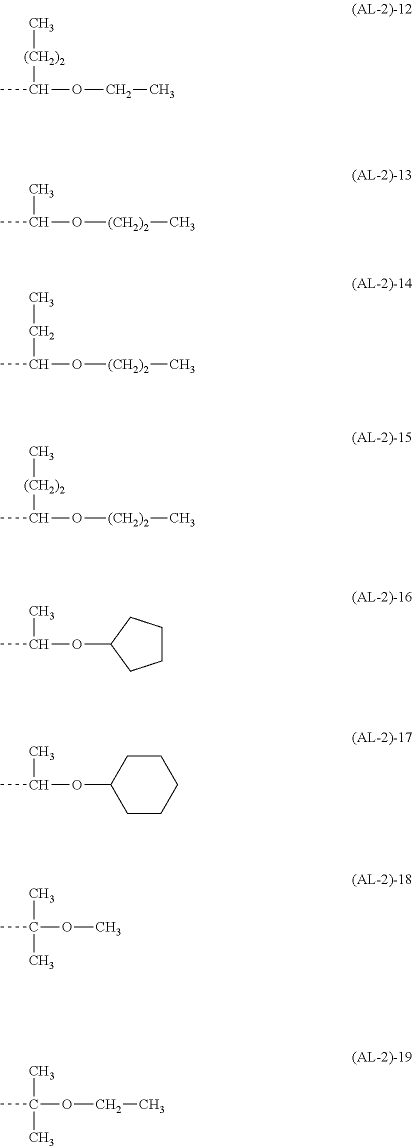

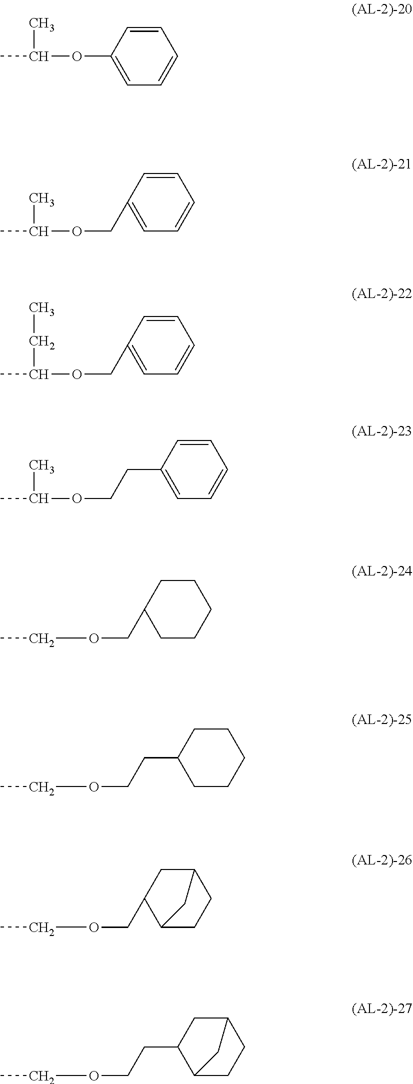

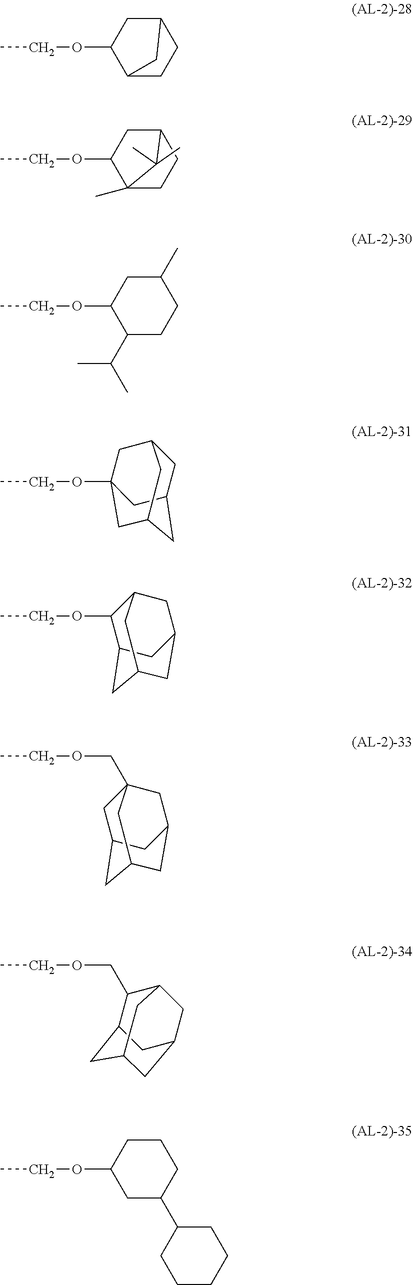

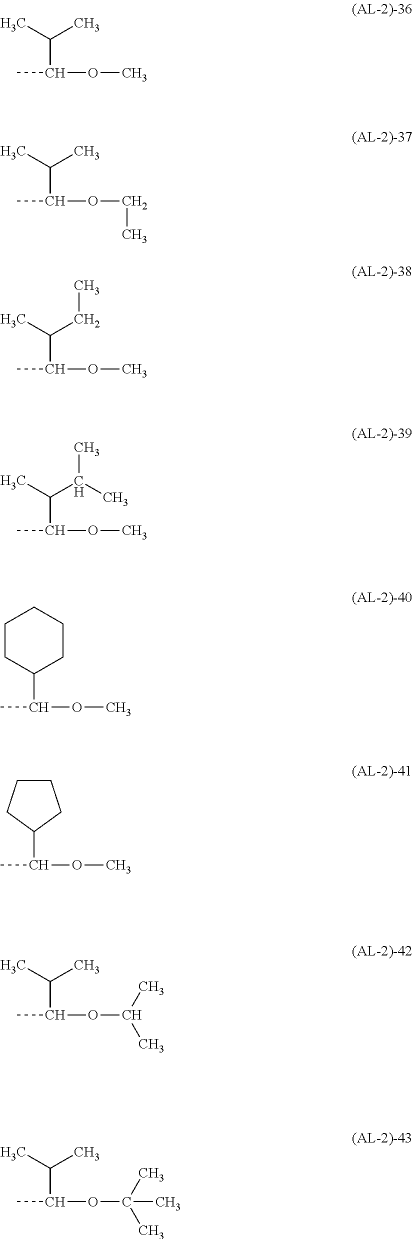

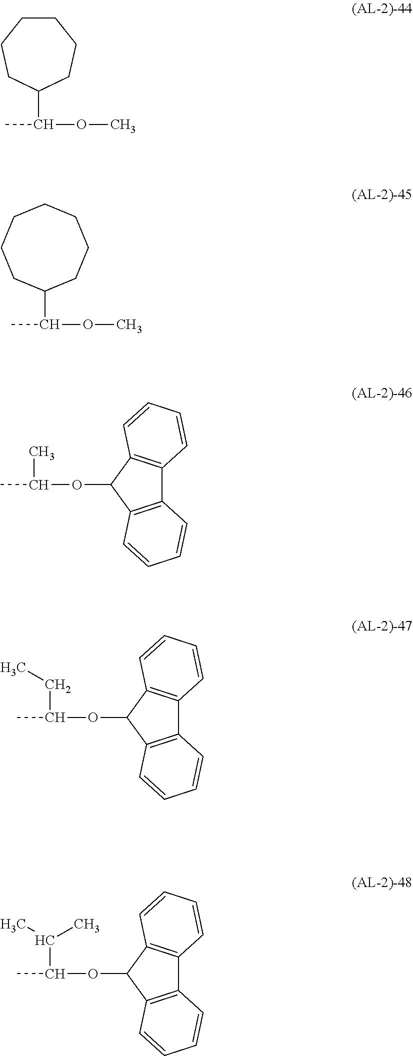

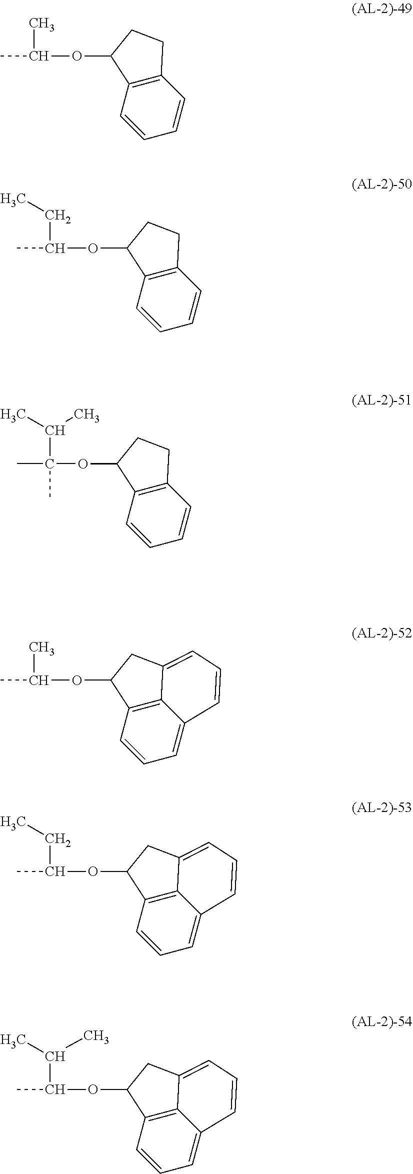

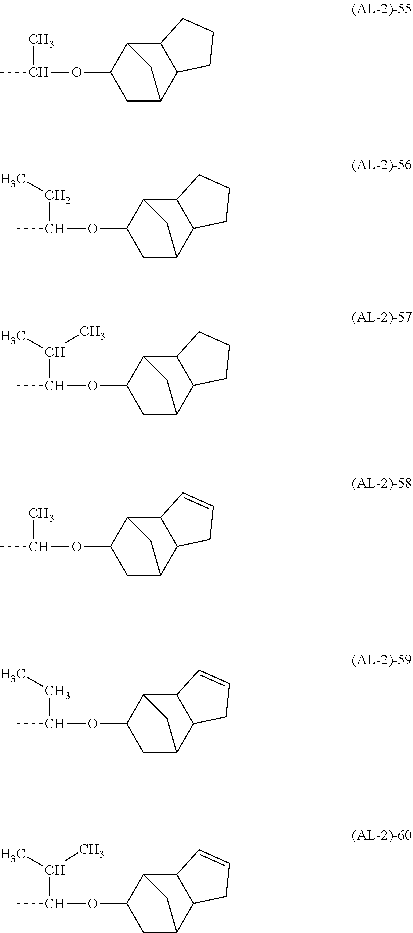

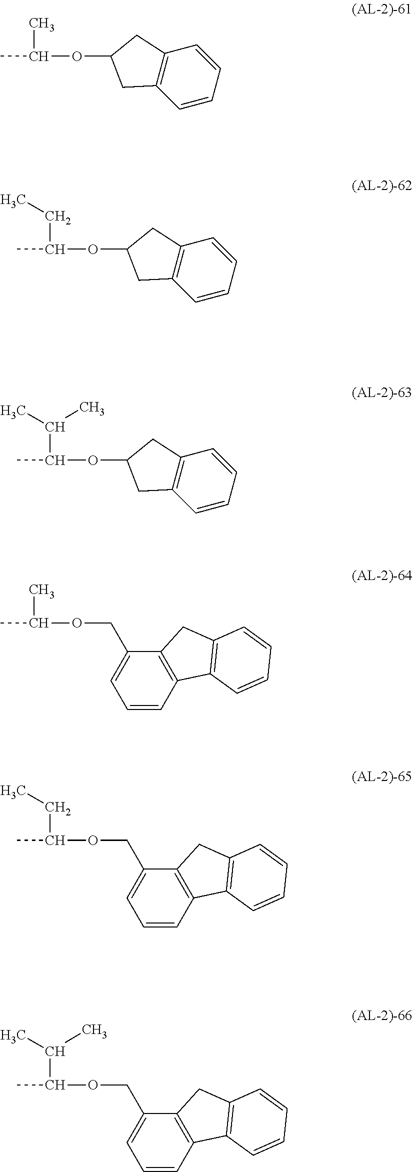

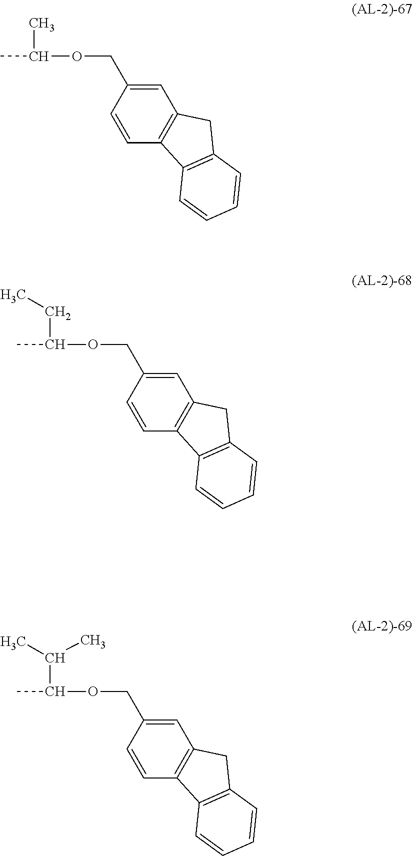

Examples of the cyclic acid labile group shown by the general formula (AL-2) include a tetrahydrofuran-2-yl group, a 2-methyltetrahydrofuran-2-yl group, a tetrahydropyran-2-yl group, a 2-methyltetrahydropyran-2-yl group, etc.

In addition, examples of the acid labile groups include crosslinking acetal groups shown by the following general formula (AL-2a) or (AL-2b). The acid labile group may crosslink the base polymer intermolecularly or intramolecularly.

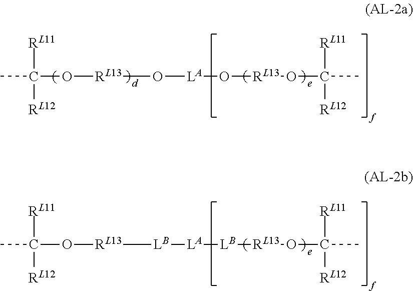

In the formulae, each broken line represents an attachment point.

In the general formula (AL-2a) or (AL-2b), R^{L11} and R^{L12} each independently represent a hydrogen atom or a saturated hydrocarbyl group having 1 to 8 carbon atoms. The saturated hydrocarbyl group may be linear, branched, or cyclic. Alternatively, R^{L11} and R^{L12} may bond with each other to form a ring together with a carbon atom bonded with R^{L11} and R^{L12}. In this case, R^{L11} and R^{L12} each independently represent an alkanediyl group having 1 to 8 carbon atoms. Each R^{L13} independently represents a saturated hydrocarbylene group having 1 to 10 carbon atoms. The saturated hydrocarbylene group may be linear, branched, or cyclic. “d” and “e” each independently represent an integer of 0 to 10, preferably an integer of 0 to 5. “f” represents an integer of 1 to 7, preferably an integer of 1 to 3.

In the general formula (AL-2a) or (AL-2b), LA represents an aliphatic saturated hydrocarbon group having a valency of (f+1) with 1 to 50 carbon atoms, an alicyclic saturated hydrocarbon group having a valency of (f+1) with 3 to 50 carbon atoms, an aromatic hydrocarbon group having a valency of (f+1) with 6 to 50 carbon atoms, or a heterocyclic group having a valency of (f+1) with 3 to 50 carbon atoms. Some of the carbon atoms of these groups may be substituted with a heteroatom-containing group, and some hydrogen atoms bonded to the carbon atoms of these groups may be substituted with a hydroxy group, a carboxy group, an acyl group, or a fluorine atom. LA is preferably an arylene group having 6 to 30 carbon atoms, a saturated hydrocarbon group, such as a saturated hydrocarbylene group, a trivalent saturated hydrocarbon group, and a tetravalent saturated hydrocarbon group each of which has 1 to 20 carbon atoms, or the like. The saturated hydrocarbon group may be linear, branched, or cyclic. L^{B} represents —C(═O)—O—, —NH—C(═O)—O—, or —NH—C(═O)—NH—.

Examples of the crosslinking acetal groups shown by the general formulae (AL-2a) and (AL-2b) include groups shown by the following formulae (AL-2)-70 to (AL-2)-77, etc.

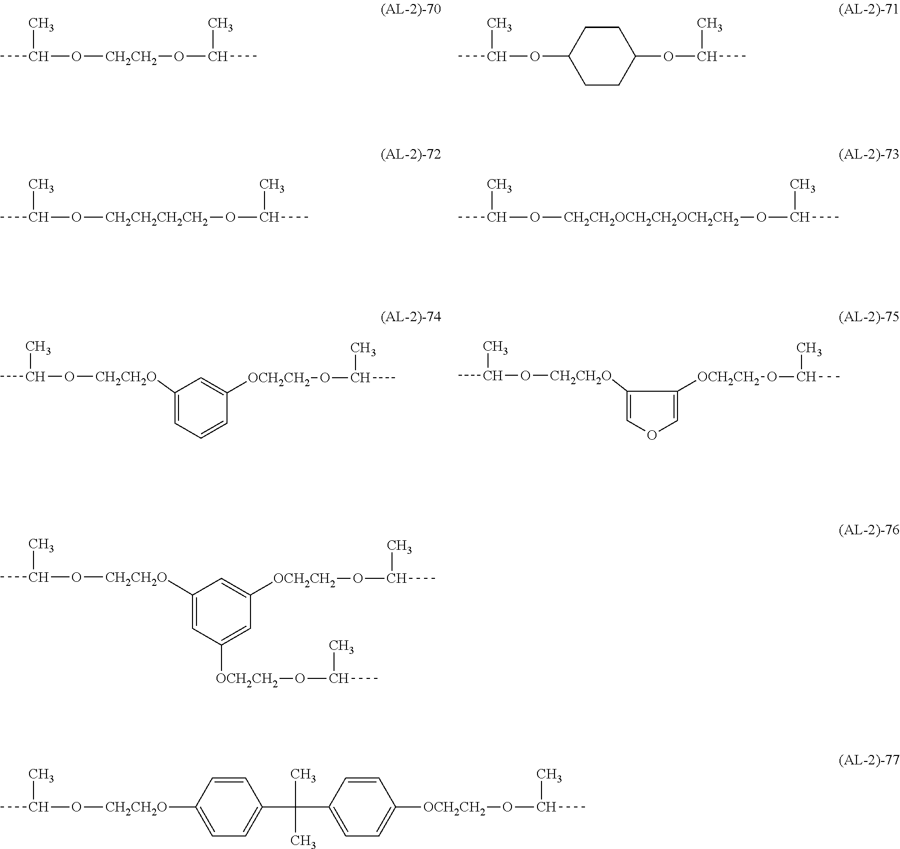

In the formulae, each broken line represents an attachment point.

In the general formula (AL-3), R^{L5}, R^{L6}, and R^{L7} each independently represent a hydrocarbyl group having 1 to 20 carbon atoms, and optionally contain a heteroatom, such as an oxygen atom, a sulfur atom, a nitrogen atom, and a fluorine atom. The hydrocarbyl group may be saturated or unsaturated, and may be linear, branched, or cyclic. Specific examples thereof include alkyl groups having 1 to 20 carbon atoms, cyclic saturated hydrocarbyl groups having 3 to 20 carbon atoms, alkenyl groups having 2 to 20 carbon atoms, cyclic unsaturated hydrocarbyl groups having 3 to 20 carbon atoms, aryl groups having 6 to 10 carbon atoms, etc. Alternatively, R^{L5} and R^{L6}, R^{L5} and R^{L7}, or R^{L6} and R^{L7}, may bond with each other to form an alicyclic group having 3 to 20 carbon atoms, together with a carbon atom bonded therewith.

Examples of the group shown by the general formula (AL-3) include a tert-butyl group, a 1,1-diethylpropyl group, a 1-ethylnorbornyl group, a 1-methylcyclopentyl group, a 1-isopropylcyclopentyl group, a 1-ethylcyclopentyl group, a 1-methylcyclohexyl group, a 2-(2-methyl)adamantyl group, a 2-(2-ethyl)adamantyl group, a tert-pentyl group, etc.

The examples of the group shown by the general formula (AL-3) also include groups shown by the following general formulae (AL-3)-1 to (AL-3)-19.

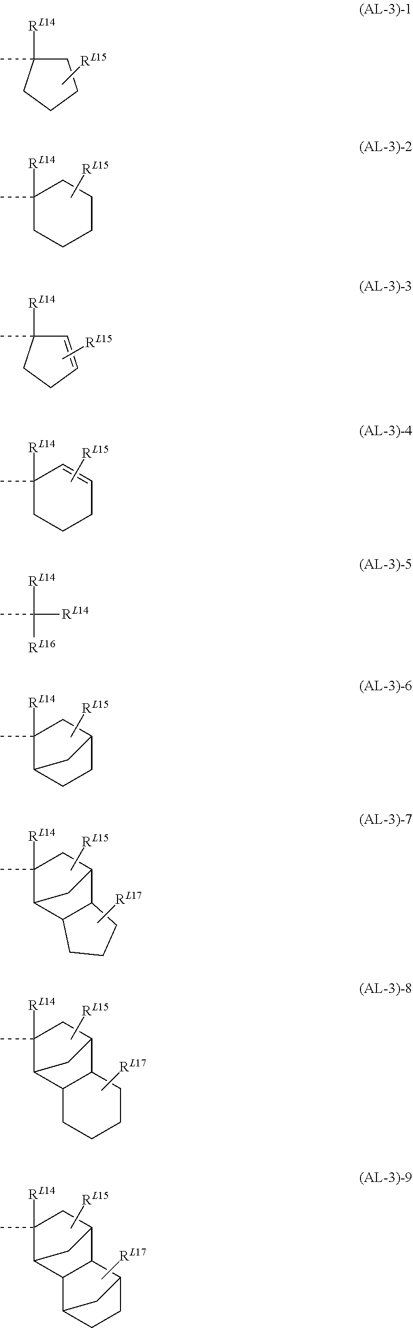

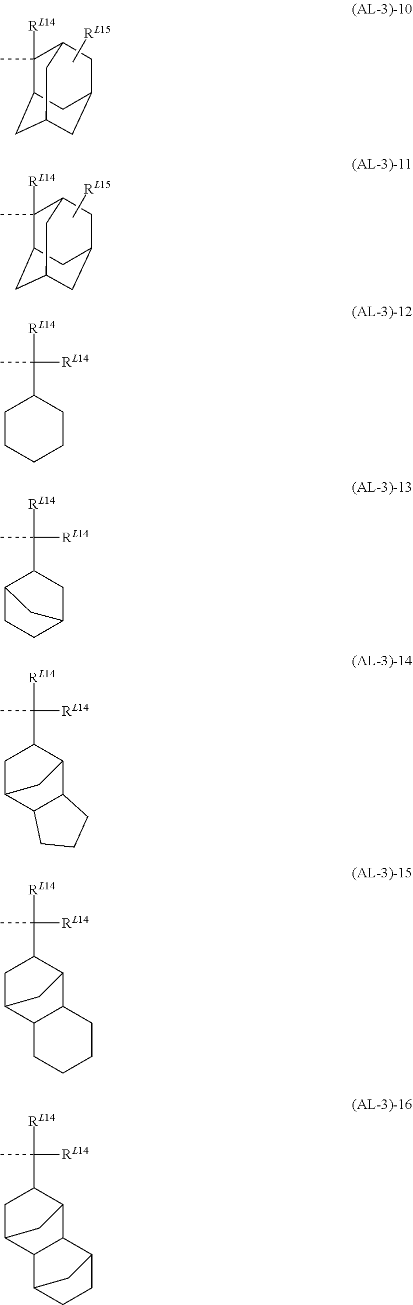

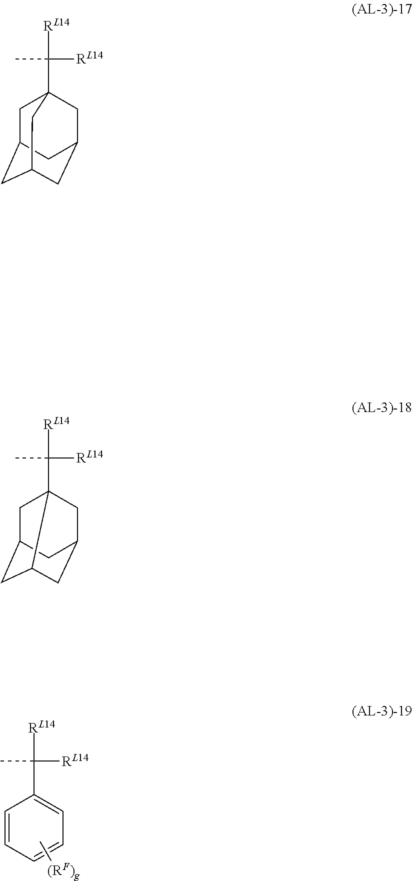

In the formulae, each broken line represents an attachment point.

In the general formulae (AL-3)-1 to (AL-3)-19, each R^{L14} independently represents a saturated hydrocarbyl group having 1 to 8 carbon atoms, or an aryl group having 6 to 20 carbon atoms. R^{L15} and R^{L17} each independently represent a hydrogen atom or a saturated hydrocarbyl group having 1 to 20 carbon atoms. R^{L16} represents an aryl group having 6 to 20 carbon atoms. The saturated hydrocarbyl groups may be linear, branched, or cyclic. The aryl groups are preferably a phenyl group or the like. RF represents a fluorine atom or a trifluoromethyl group. “g” represents an integer of 1 to 5.

Examples of the acid labile group further include groups shown by the following general formula (AL-3)-20 or (AL-3)-21. The acid labile groups may crosslink the polymer intramolecularly or intermolecularly.

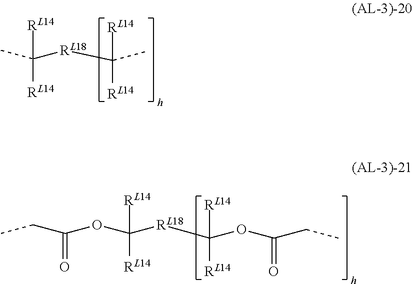

In the formulae, each broken line represents an attachment point.

In the general formulae (AL-3)-20 and (AL-3)-21, R^{L14} is as defined above. R^{L18} represents a saturated hydrocarbylene group having a valency of (h+1) with 1 to 20 carbon atoms, or an arylene group having a valency of (h+1) with 6 to 20 carbon atoms, and optionally contains a heteroatom, such as an oxygen atom, a sulfur atom, and a nitrogen atom. The saturated hydrocarbylene group may be linear, branched, or cyclic. “h” represents an integer of 1 to 3.

Examples of a monomer to give the repeating unit containing the acid labile group shown by the formula (AL-3) include (meth)acrylate having an exo-form structure shown by the following general formula (AL-3)-22.

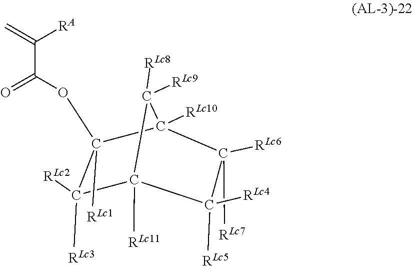

In the general formula (AL-3)-22, R^{A} is as defined above. R^{Lc1} represents a saturated hydrocarbyl group having 1 to 8 carbon atoms, or an aryl group having 6 to 20 carbon atoms and optionally containing a substituent. The saturated hydrocarbyl group may be linear, branched, or cyclic. R^{Lc2} to R^{Lc11} each independently represent a hydrogen atom, or a hydrocarbyl group having 1 to 15 carbon atoms and optionally containing a heteroatom. Examples of the heteroatom include oxygen atom etc. Examples of the hydrocarbyl group include alkyl groups having 1 to 15 carbon atoms, aryl groups having 6 to 15 carbon atoms, etc. R^{Lc2} and R^{Lc3}, R^{Lc4} and R^{Lc6}, R^{Lc4} and R^{Lc7}, R^{Lc5} and R^{Lc7}, R^{Lc5} and R^{Lc11}, R^{Lc6} and R^{Lc10}, R^{Lc8} and R^{Lc9}, or R^{Lc9} and R^{Lc10}, may bond with each other to form a ring together with a carbon atom bonded with the corresponding pair. In this case, a group involved in the bonding is a hydrocarbylene group having 1 to 15 carbon atoms and optionally containing a heteroatom. Alternatively, R^{Lc2} and R^{Lc11}, R^{Lc8} and R^{Lc11}, or R^{Lc4} and R^{Lc6}, all pairs of which are attached to carbon atoms next to each other, may directly bond with each other to form a double bond. Note that the formula also represents an enantiomer.

Examples of the monomer shown by the general formula (AL-3)-22 to give the repeating unit include ones disclosed in JP 2000-327633 A, etc. Specific examples thereof include ones shown below, but are not limited thereto. Note that, in the following formulae, R^{A} is as defined above.

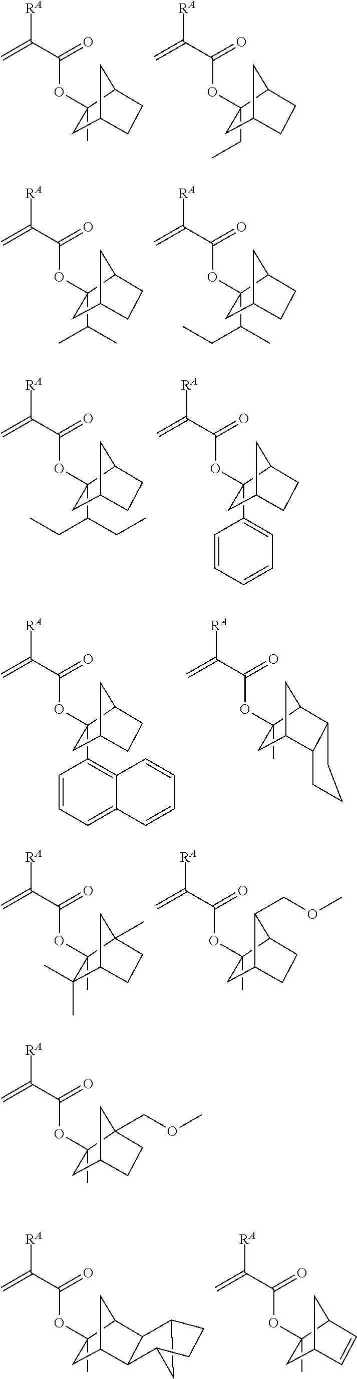

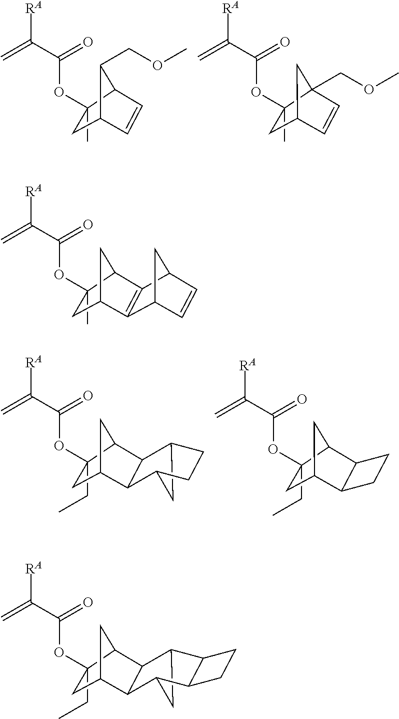

Other examples of the monomer to give the repeating unit containing the acid labile group shown by the general formula (AL-3) include (meth)acrylate containing a furandiyl group, a tetrahydrofurandiyl group, or an oxanorbornanediyl group as shown by the following general formula (AL-3)-23.

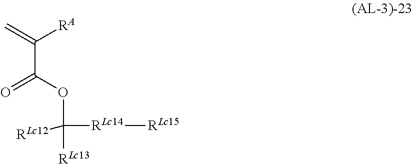

In the general formula (AL-3)-23, R^{A} is as defined above. R^{Lc12} and R^{Lc13} each independently represent a hydrocarbyl group having 1 to 10 carbon atoms. R^{Lc12} and R^{Lc13} may bond with each other to form an alicyclic group together with a carbon atom bonded with R^{Lc12} and R^{Lc13}. R^{Lc14} represents a furandiyl group, a tetrahydrofurandiyl group, or an oxanorbornanediyl group. R^{Lc15} represents a hydrogen atom, or a hydrocarbyl group having 1 to 10 carbon atoms and optionally containing a heteroatom. The hydrocarbyl group may be linear, branched, or cyclic. Specific examples thereof include saturated hydrocarbyl groups having 1 to 10 carbon atoms, etc.

Examples of the monomer shown by the general formula (AL-3)-23 to give the repeating unit include, but are not limited to, ones shown below. Note that, in the following formulae, R^{A} is as defined above, Ac represents an acetyl group, and Me represents a methyl group.

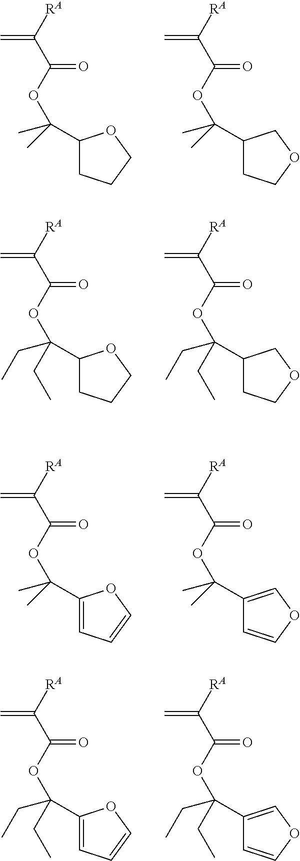

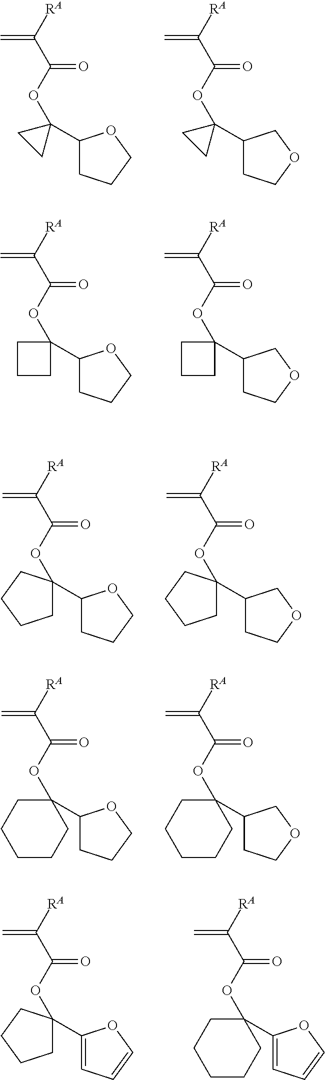

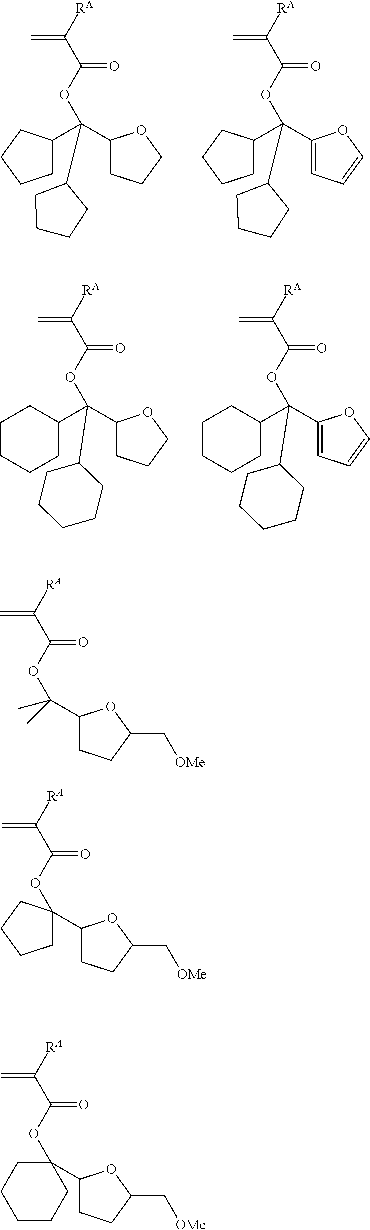

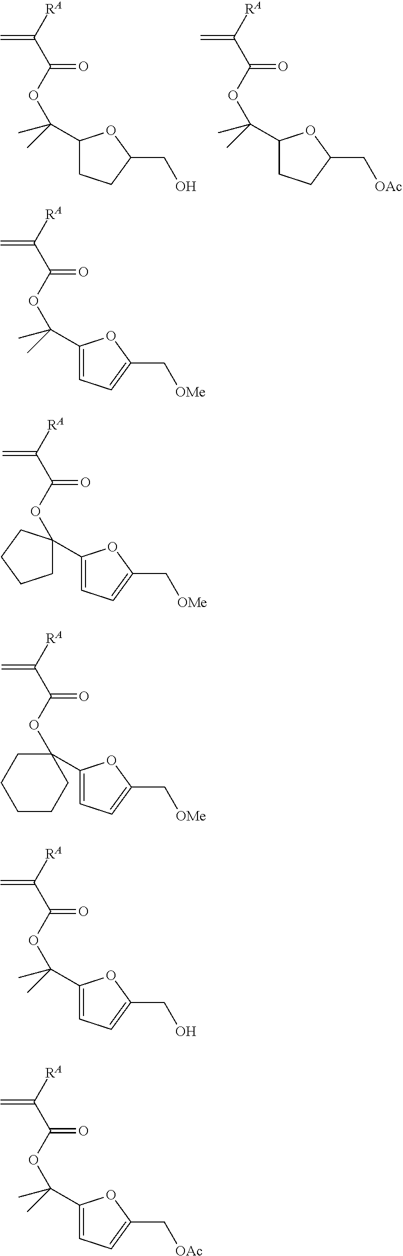

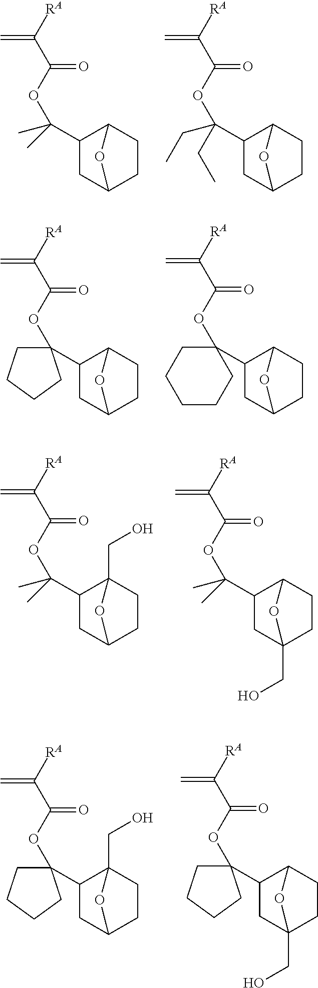

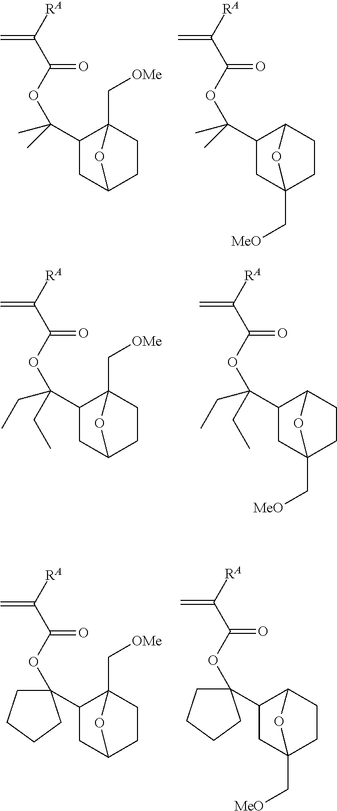

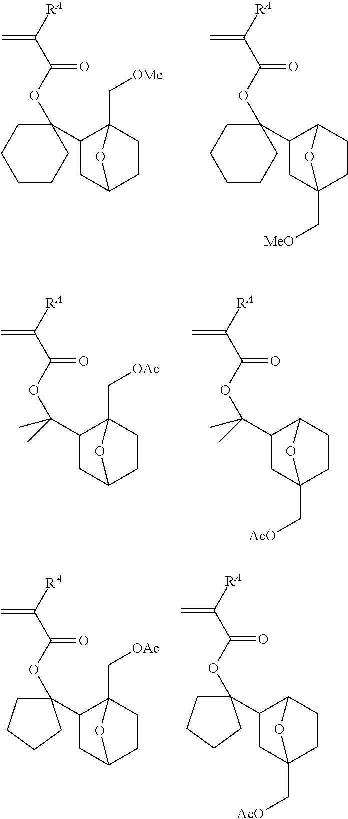

The base polymer may further contain a repeating unit-c having an adhesive group selected from the group consisting of a hydroxy group, a carboxy group, a lactone ring, a carbonate group, a thiocarbonate group, a carbonyl group, a cyclic acetal group, an ether bond, an ester bond, a sulfonic acid ester group, a cyano group, an amide group, —O—C(═O)—S—, and —O—C(═O)—NH—.

Examples of a monomer to give the repeating unit-c include ones shown below, but are not limited thereto. Note that, in the following formulae, R^{A} is as defined above.

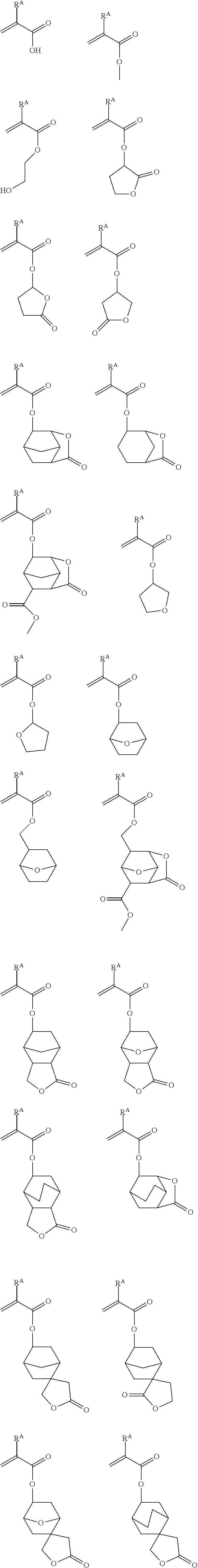

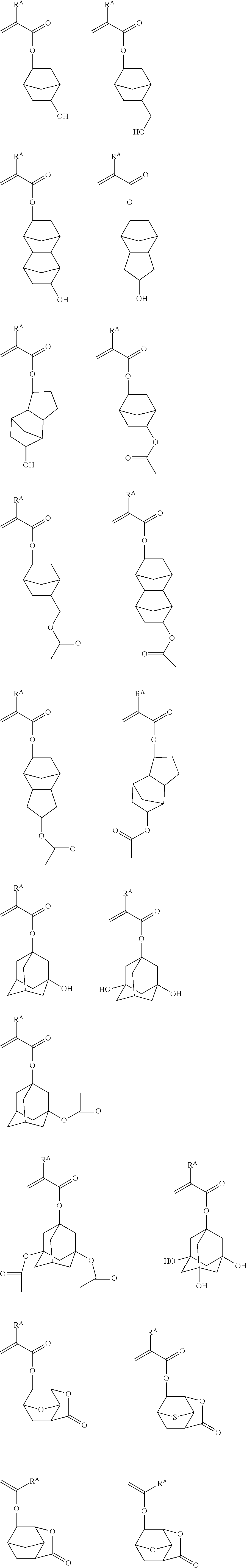

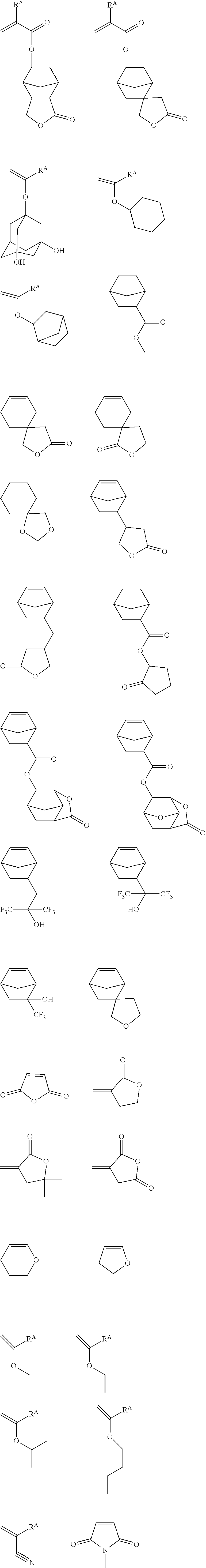

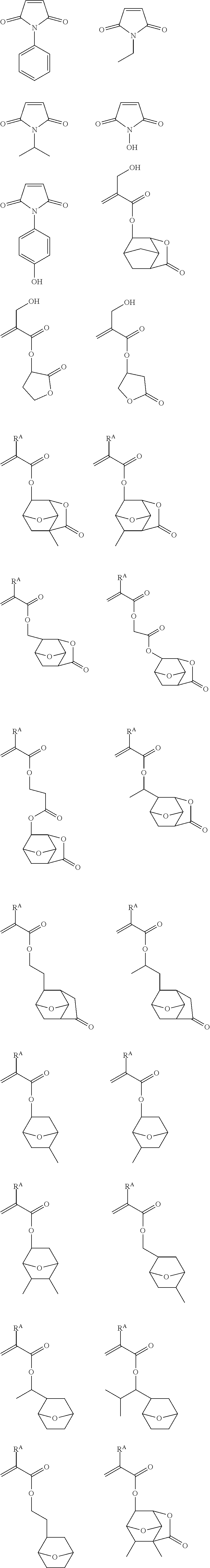

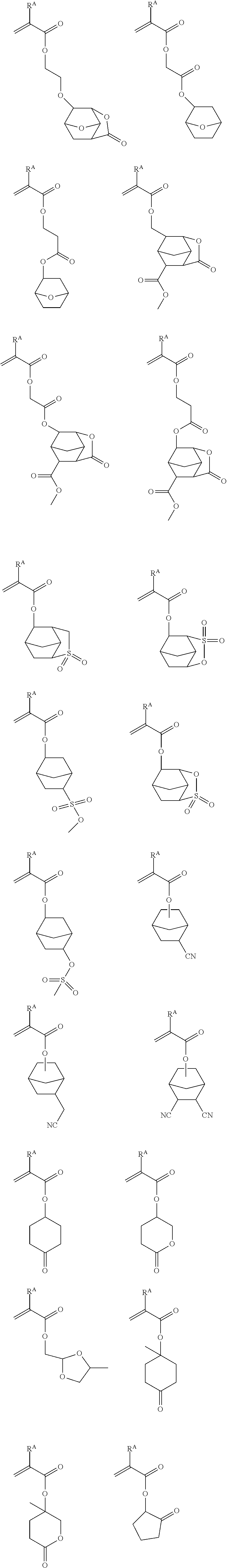

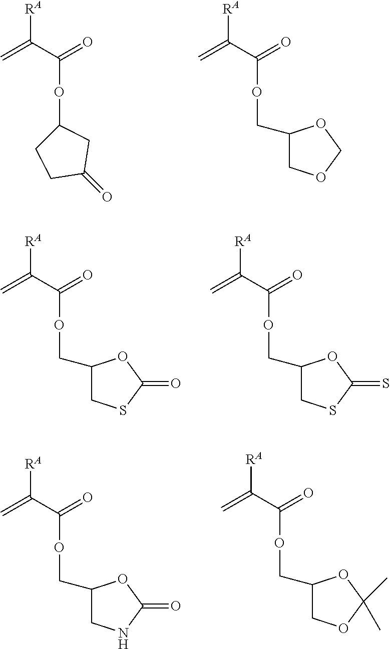

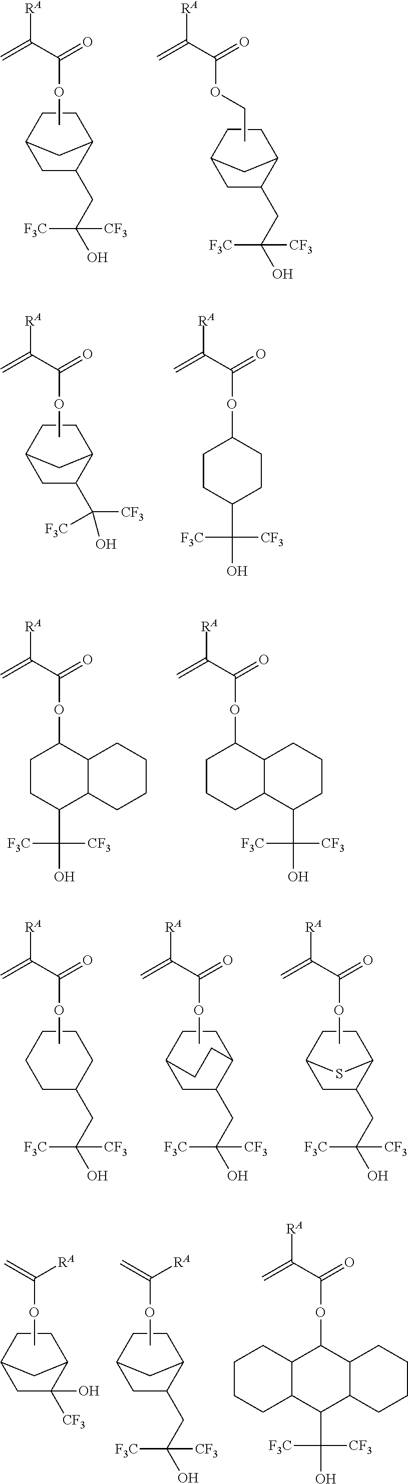

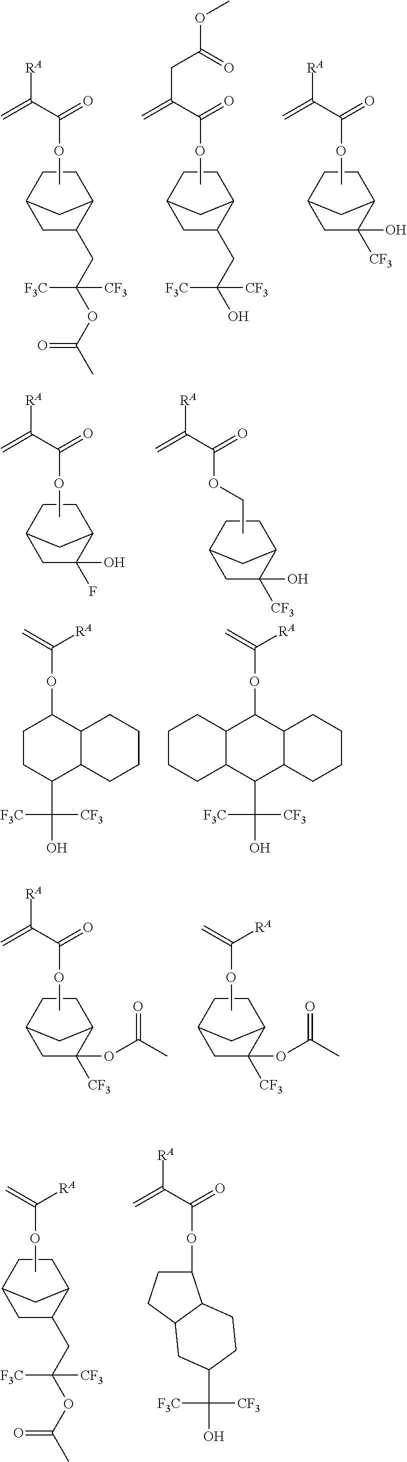

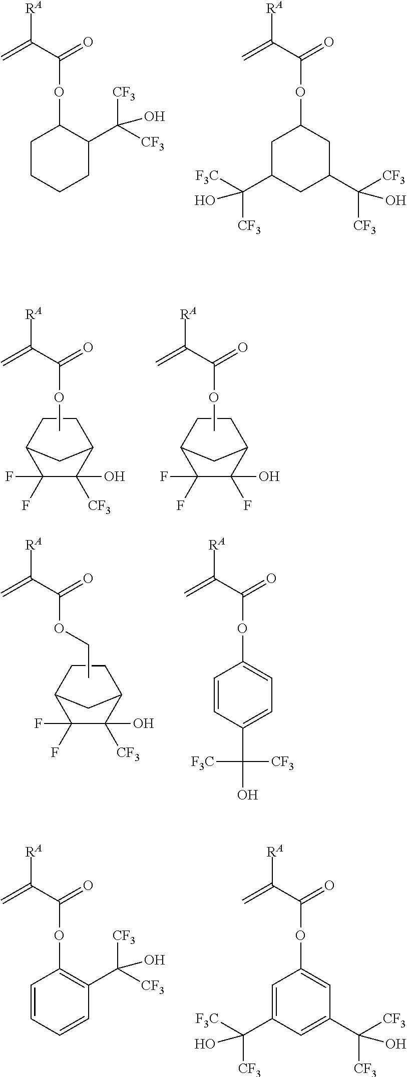

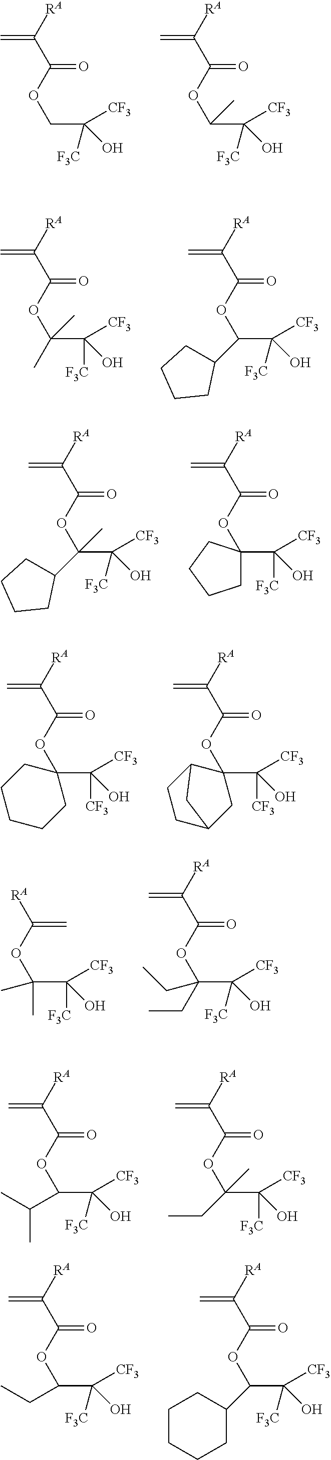

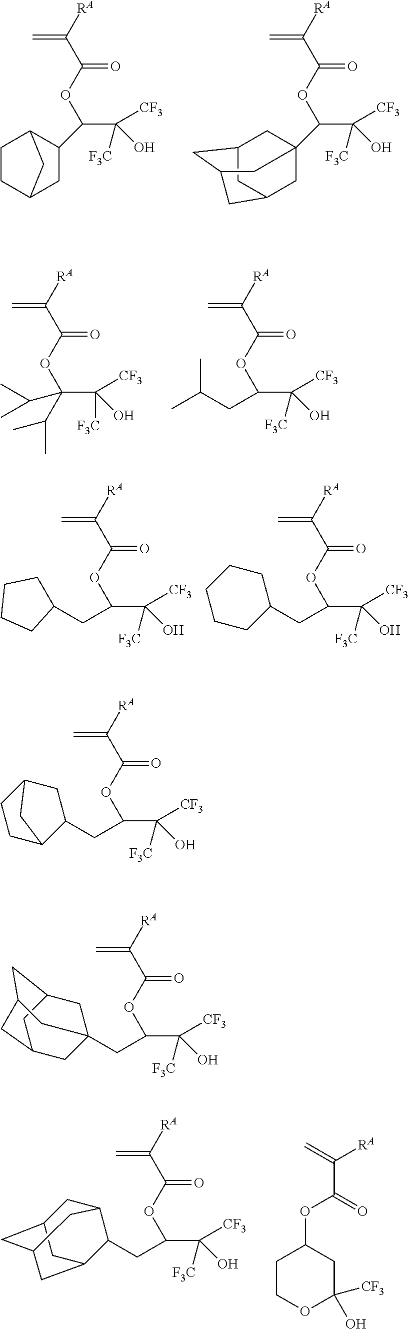

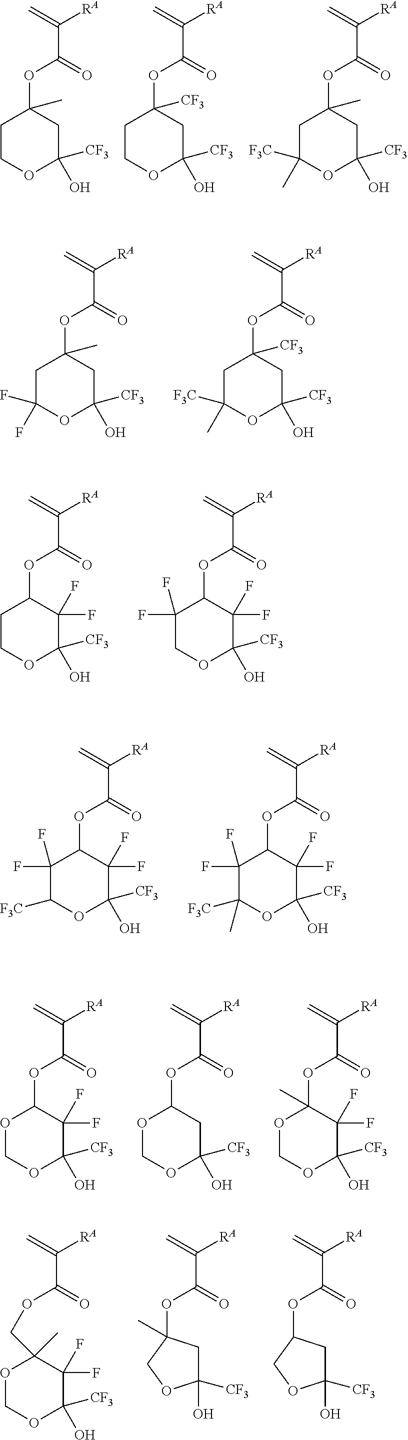

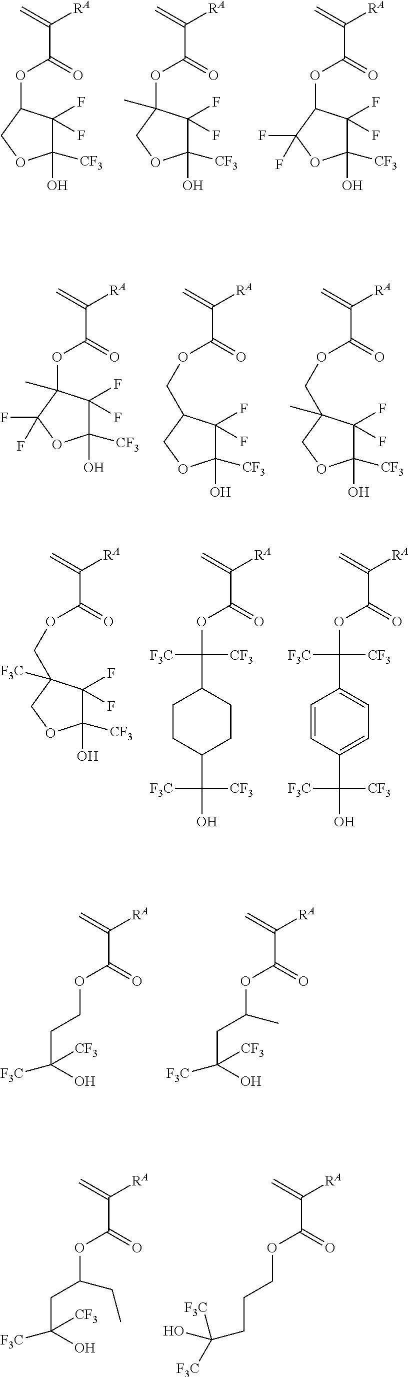

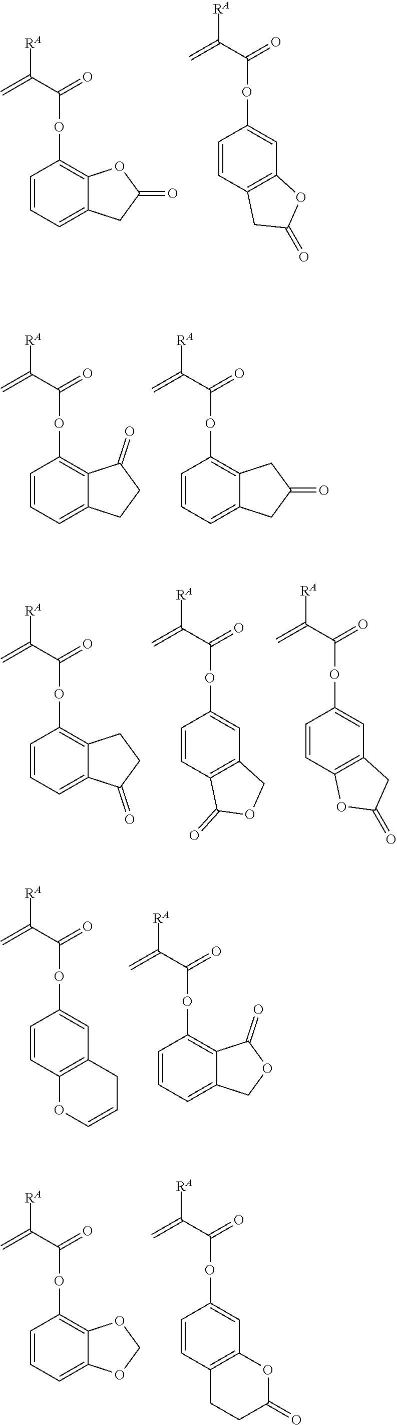

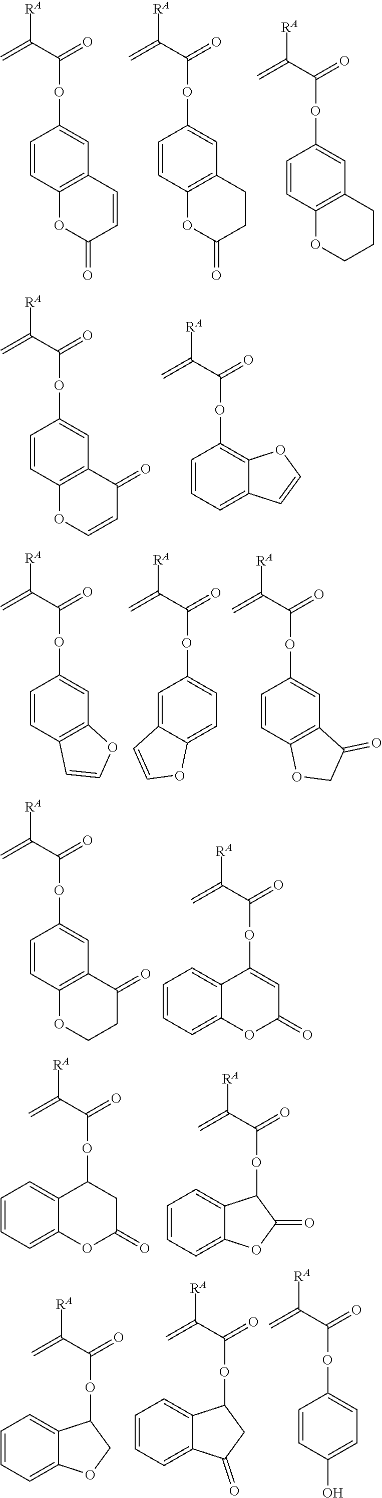

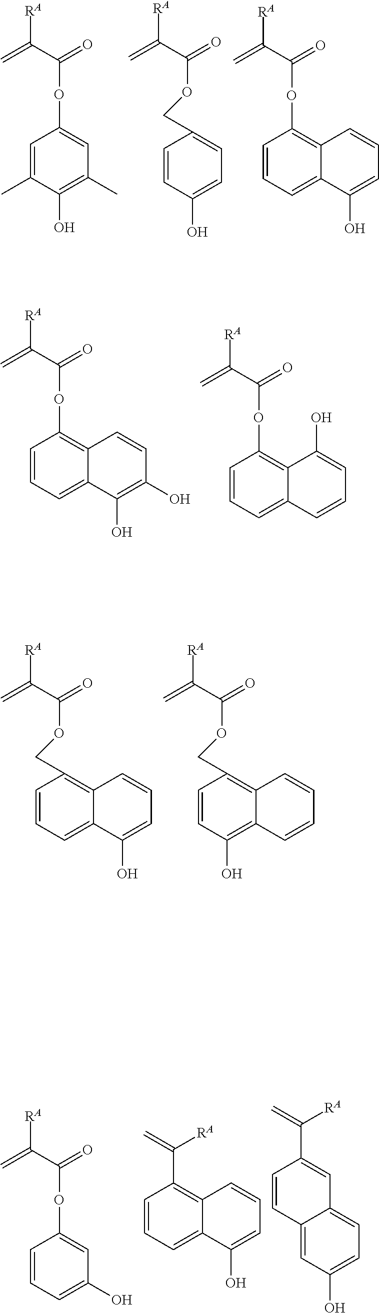

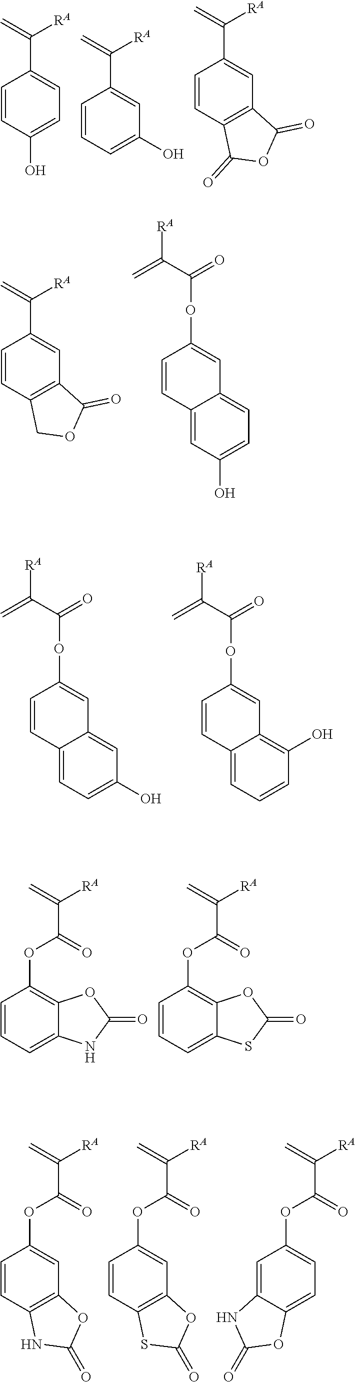

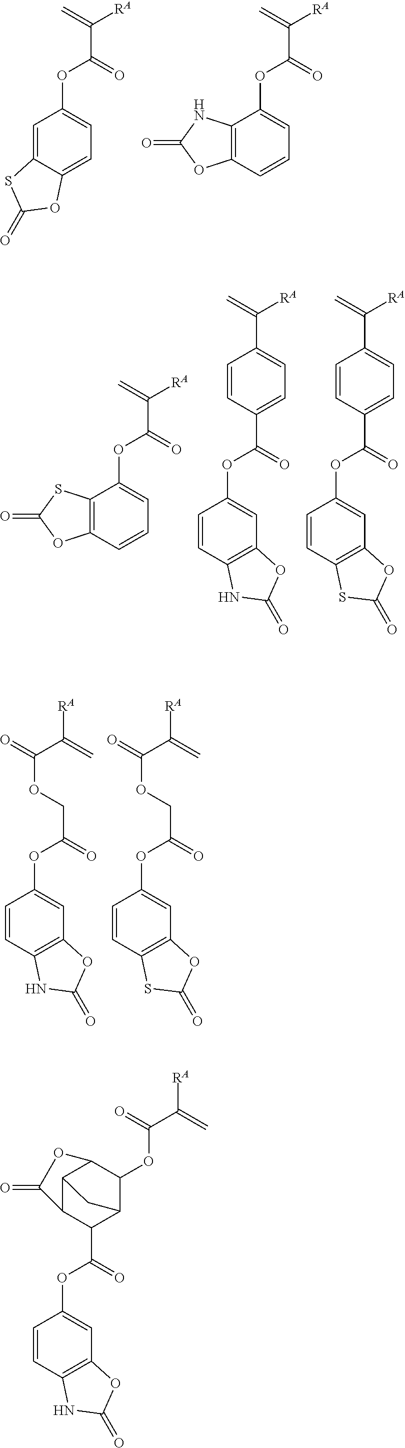

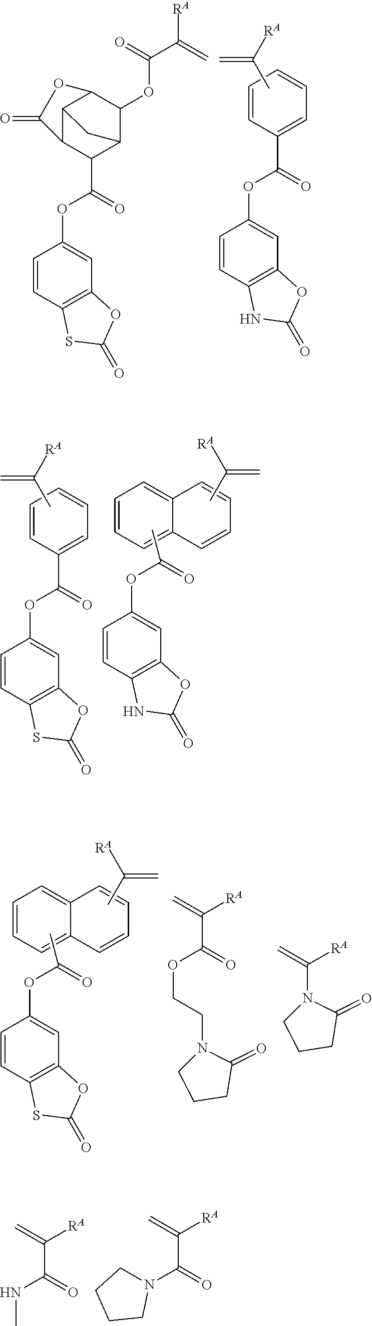

The base polymer may contain a repeating unit-d different from the above-described repeating units. Examples of the repeating unit-d include those derived from styrene, acenaphthylene, indene, coumarin, coumarone, etc.

In the base polymer, the content ratios of the repeating units-a1, -a2, -b1, -b2, -c, and -d are preferably 0≤a1<1.0, 0≤a2<1.0, 0.01≤a1+a2<1.0, 0≤b2≤0.9, 0.1≤b1+b2≤0.9, 0≤c≤9, and 0≤d≤0.5; more preferably 0≤a1≤0.6, 0≤a2<0.6, 0.02≤a1+a2≤0.6, 0≤b1≤0.8, 0≤b2≤0.8, 0.2≤b1+b2≤0.8, 0≤c≤0.8, and 0≤d≤0.4; further preferably 0≤a1≤0.5, 0≤a2<0.5, 0.03≤a1+a2≤0.5, 0≤b1≤0.7, 0≤b2≤0.7, 0.3≤b1+b2≤0.7, 0≤c≤0.7, and 0≤d≤0.3, given that a1+a2+b1+b2+c+d=1.0.

The base polymer may be synthesized, for example, by subjecting the monomers to give the repeating units described above to heat polymerization in an organic solvent to which a radical polymerization initiator has been added.

Examples of the organic solvent used in the polymerization include toluene, benzene, tetrahydrofuran (THF), diethyl ether, dioxane, etc. Examples of the polymerization initiator include 2,2′-azobisisobutyronitrile (AIBN), 2,2′-azobis(2,4-dimethylvaleronitrile), dimethyl-2,2-azobis(2-methylpropionate), benzoyl peroxide, lauroyl peroxide, etc. The temperature during the polymerization is preferably 50 to 80° C. The reaction time is preferably 2 to 100 hours, more preferably 5 to 20 hours.

In the case where the monomer containing a hydroxy group is copolymerized, the process may include: substituting the hydroxy group with an acetal group susceptible to deprotection with acid, such as an ethoxy group, prior to the polymerization; and performing the deprotection with weak acid and water after the polymerization. Alternatively, the process may include: substituting the hydroxy group with an acetyl group, a formyl group, a pivaloyl group, or the like; and performing alkaline hydrolysis after the polymerization.

In a case where hydroxystyrene or hydroxyvinylnaphthalene is copolymerized, at first, acetoxystyrene or acetoxyvinylnaphthalene may be used in place of hydroxystyrene or hydroxyvinylnaphthalene; after the polymerization, the acetoxy group may be deprotected by the alkaline hydrolysis as described above to convert the acetoxystyrene or acetoxyvinylnaphthalene to hydroxystyrene or hydroxyvinylnaphthalene.

In the alkaline hydrolysis, a base such as ammonia water or triethylamine is usable. The reaction temperature is preferably −20 to 100° C., more preferably 0 to 60° C. The reaction time is preferably 0.2 to 100 hours, more preferably 0.5 to 20 hours.

The base polymer has a polystyrene-based weight-average molecular weight (Mw) of preferably 1,000 to 500,000, more preferably 2,000 to 30,000, which is determined by gel permeation chromatography (GPC) using THF as a solvent. When the Mw is 1,000 or more, the resist material has excellent heat resistance. When the Mw is 500,000 or less, the alkali solubility is not decreased, and a footing phenomenon after pattern formation is prevented.

Further, when the base polymer has a molecular weight distribution (Mw/Mn) of 1.0 to 2.0, there is no low-molecular-weight or high-molecular-weight polymer. This can eliminate possibilities that foreign matters are observed on the pattern after the exposure, and that the pattern profile is degraded. The finer the pattern rule, the stronger the influences of Mw and Mw/Mn. Hence, in order to obtain a resist material suitably used for finer pattern dimension, the base polymer preferably has a narrow dispersity Mw/Mn of 1.0 to 2.0, particularly preferably 1.0 to 1.5.

The base polymer may contain two or more kinds of polymers that differ in composition ratio, Mw, and Mw/Mn. Alternatively, a polymer containing the repeating unit(s)-a1 and/or -a2 may be blended with a polymer not containing the repeating unit-a1 or a2 but containing the repeating unit(s)-b1 and/or -b2.

### [Additive-Type Acid Generator]

Other than the sulfonium salt of a sulfonate ion bonded to a polymer main chain described above, the inventive positive resist material may further contain an acid generator that generates a strong acid (hereinafter also referred to as additive-type acid generator). Here, the term strong acid means a compound that has sufficient acidity to cause deprotection reaction of the acid labile group of the base polymer. Examples of this acid generator include compounds that generate acids in response to actinic light or radiation (photo-acid generators). Such photo-acid generator is not particularly limited, as long as the compound generates an acid upon high-energy beam irradiation. Preferably, the photo-acid generator generates a sulfonic acid, imide acid, or methide acid. Suitable photo-acid generators are sulfonium salt, iodonium salt, sulfonyldiazomethane, N-sulfonyloxyimide, oxime-O-sulfonate type acid generators, etc. Specific examples of the photo-acid generator include ones disclosed in paragraphs [0122] to [0142] of JP 2008-111103 A.

Moreover, a sulfonium salt shown by the following general formula (10-1) and an iodonium salt shown by the following general formula (10-2) can also be used suitably as photo-acid generators.

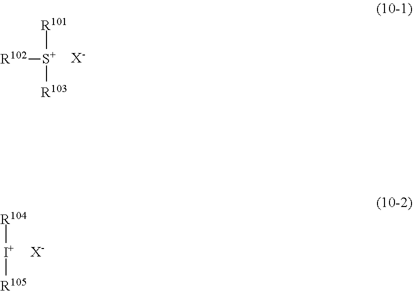

In the general formulae (10-1) and (10-2), R¹⁰¹ to R¹⁰⁵ each independently represent a hydrocarbyl group having 1 to 25 carbon atoms and optionally containing a fluorine atom, a chlorine atom, a bromine atom, an iodine atom, or a heteroatom. X⁻ represents an anion.

The hydrocarbyl group represented by R¹⁰¹ to R¹⁰⁵ may be saturated or unsaturated, and may be linear, branched, or cyclic. Specific examples thereof include alkyl groups having 1 to 20 carbon atoms, such as a methyl group, an ethyl group, an n-propyl group, an isopropyl group, an n-butyl group, an isobutyl group, a sec-butyl group, a tert-butyl group, an n-pentyl group, an n-hexyl group, an n-octyl group, an n-nonyl group, an n-decyl group, an undecyl group, a dodecyl group, a tridecyl group, a tetradecyl group, a pentadecyl group, a heptadecyl group, an octadecyl group, a nonadecyl group, and an eicosyl group; cyclic saturated hydrocarbyl groups having 3 to 20 carbon atoms, such as a cyclopropyl group, a cyclopentyl group, a cyclohexyl group, a cyclopropylmethyl group, a 4-methylcyclohexyl group, a cyclohexylmethyl group, a norbornyl group, and an adamantyl group; alkenyl groups having 2 to 20 carbon atoms, such as a vinyl group, a propenyl group, a butenyl group, and a hexenyl group; cyclic unsaturated aliphatic hydrocarbyl groups having 2 to 20 carbon atoms, such as a cyclohexenyl group and a norbornenyl group; alkynyl groups having 2 to 20 carbon atoms, such as an ethynyl group, a propynyl group, and a butynyl group; aryl groups having 6 to 20 carbon atoms, such as a phenyl group, a methylphenyl group, an ethylphenyl group, an n-propylphenyl group, an isopropylphenyl group, an n-butylphenyl group, an isobutylphenyl group, a sec-butylphenyl group, a tert-butylphenyl group, a naphthyl group, a methylnaphthyl group, an ethylnaphthyl group, an n-propylnaphthyl group, an isopropylnaphthyl group, an n-butylnaphthyl group, an isobutylnaphthyl group, a sec-butylnaphthyl group, and a tert-butylnaphthyl group; aralkyl groups having 7 to 20 carbon atoms, such as a benzyl group and a phenethyl group; etc. Additionally, these groups may have some hydrogen atoms substituted with a group containing a heteroatom, such as an oxygen atom, a sulfur atom, a nitrogen atom, or a halogen atom, while these groups may have some carbon atoms substituted with a group containing a heteroatom, such as an oxygen atom, a sulfur atom, or a nitrogen atom. Thus, the resulting hydrocarbyl group may contain a hydroxy group, a cyano group, a carbonyl group, an ether bond, an ester bond, a sulfonic acid ester group, a carbonate group, a lactone ring, a sultone ring, carboxylic anhydride, a haloalkyl group, etc.

Alternatively, R¹⁰¹ and R¹⁰² may bond with each other to form a ring together with a sulfur atom bonded with R¹⁰¹ and R¹⁰². In this event, the ring preferably has any of the structures shown below.

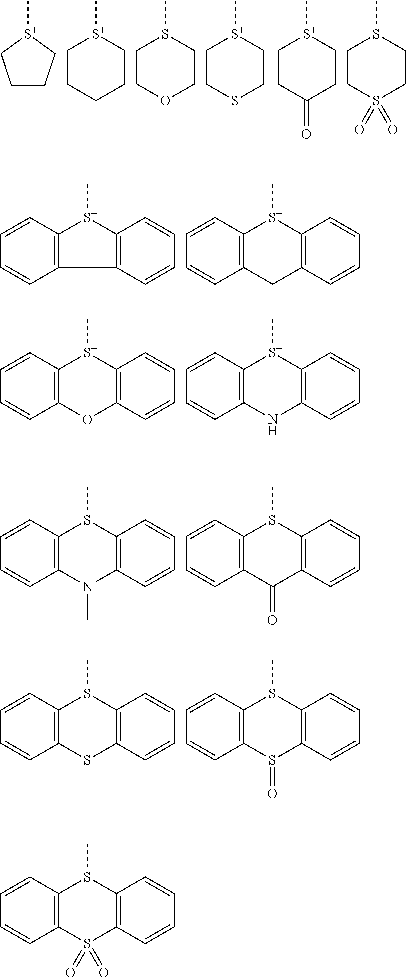

In the formulae, each broken line represents an attachment point to R¹⁰³.

Examples of a cation of the sulfonium salt shown by the general formula (10-1) include those described above, but are not limited thereto.

Examples of a cation of the iodonium salt shown by the general formula (10-2) include ones shown below, but are not limited thereto.

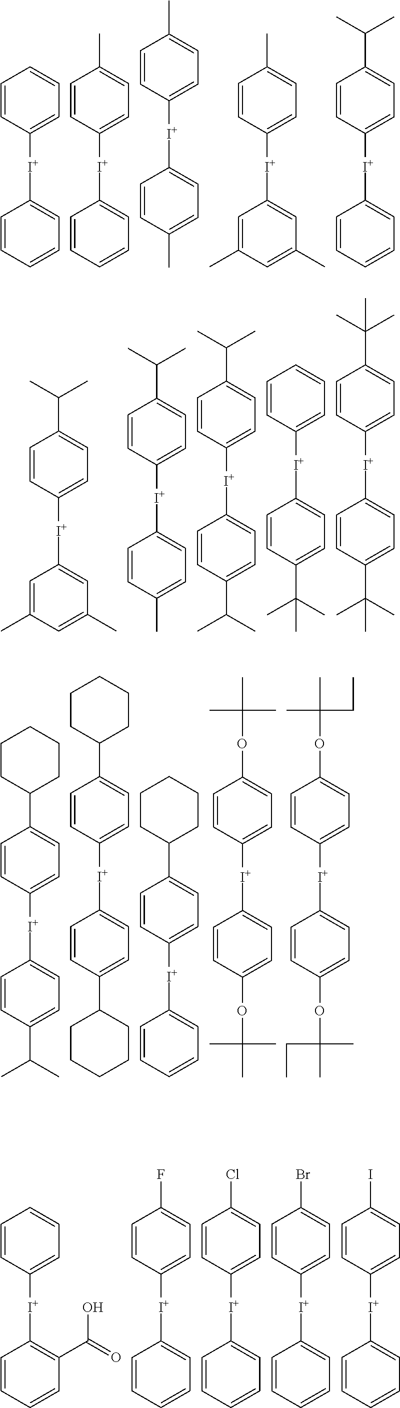

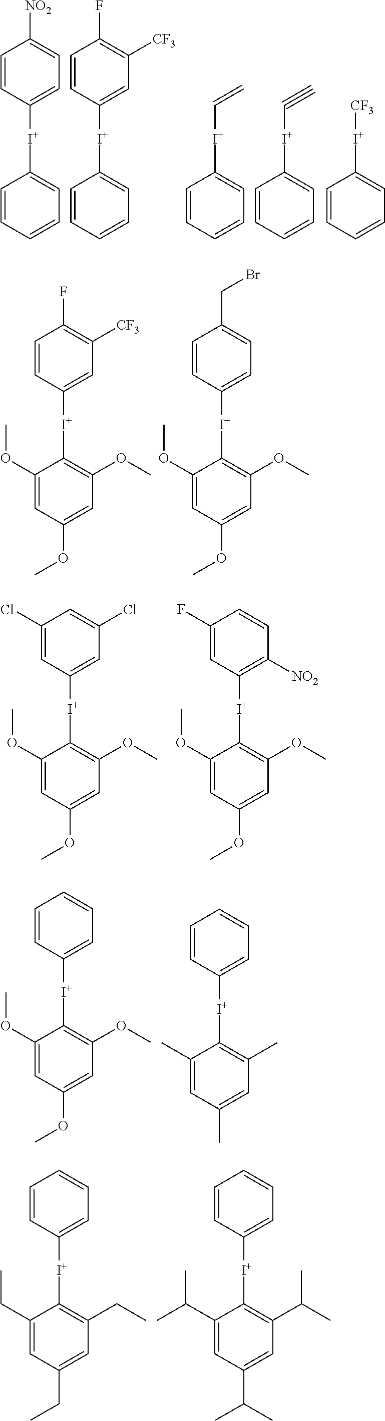

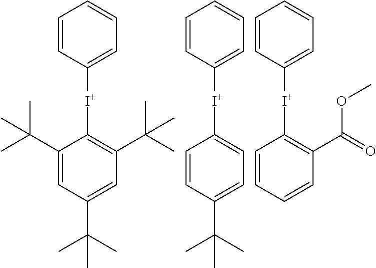

In the general formulae (10-1) and (10-2), X⁻ represents an anion selected from the following general formulae (1A) to (1D).

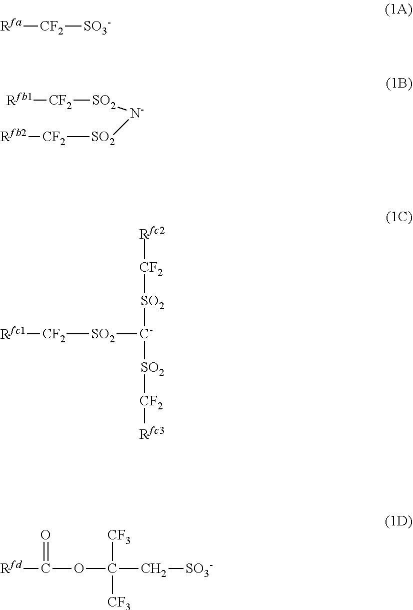

In the general formula (1A), R^{fa} represents a fluorine atom, or a hydrocarbyl group having 1 to 40 carbon atoms and optionally containing a heteroatom. The hydrocarbyl group may be saturated or unsaturated, and may be linear, branched, or cyclic. Specific examples thereof include those to be described below as a hydrocarbyl group which R¹⁰⁷ represents in the following general formula (1A′).

The anion shown by the general formula (1A) is preferably shown by the following general formula (1A′).

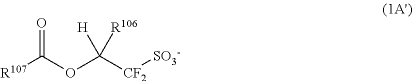

In the general formula (1A′), R¹⁰⁶ represents a hydrogen atom or a trifluoromethyl group, preferably a trifluoromethyl group. R¹⁰⁷ represents a hydrocarbyl group having 1 to 38 carbon atoms and optionally containing a heteroatom. The heteroatom is preferably an oxygen atom, a nitrogen atom, a sulfur atom, a halogen atom, or the like, more preferably an oxygen atom. The hydrocarbyl group particularly preferably has 6 to 30 carbon atoms from the viewpoint of obtaining high resolution in fine pattern formation.

The hydrocarbyl group represented by R¹⁰⁷ may be saturated or unsaturated, and may be linear, branched, or cyclic. Specific examples thereof include alkyl groups, such as a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, a nonyl group, an undecyl group, a tridecyl group, a pentadecyl group, a heptadecyl group, and an icosanyl group; cyclic saturated hydrocarbyl groups, such as a cyclopentyl group, a cyclohexyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group; unsaturated hydrocarbyl groups, such as an allyl group and a 3-cyclohexenyl group; aryl groups, such as a phenyl group, a 1-naphthyl group, and a 2-naphthyl group; aralkyl groups, such as a benzyl group and a diphenylmethyl group; etc.

In addition, these groups may have some or all of hydrogen atoms substituted with a group containing a heteroatom, such as an oxygen atom, a sulfur atom, a nitrogen atom, or a halogen atom, while these groups may have some of carbon atoms substituted with a group containing a heteroatom, such as an oxygen atom, a sulfur atom, or a nitrogen atom. Thus, the resulting hydrocarbyl group may contain a hydroxy group, a cyano group, a carbonyl group, an ether bond, an ester bond, a sulfonic acid ester group, a carbonate group, a lactone ring, a sultone ring, carboxylic anhydride, a haloalkyl group, etc. Examples of the hydrocarbyl group containing a heteroatom include a tetrahydrofuryl group, a methoxymethyl group, an ethoxymethyl group, a methylthiomethyl group, an acetamidomethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, a 3-oxocyclohexyl group, etc.

The synthesis of the sulfonium salt containing the anion shown by the general formula (1A′) is described in detail in JP 2007-145797 A, JP 2008-106045 A, JP 2009-7327 A, JP 2009-258695 A, etc. In addition, sulfonium salts disclosed in JP 2010-215608 A, JP 2012-41320 A, JP 2012-106986 A, JP 2012-153644 A, etc. are also suitably used.

Examples of the anion shown by the general formula (1A) include ones exemplified as an anion shown by formula (1A) in JP 2018-197853 A.

In the general formula (1B), R^{fb1} and R^{fb2} each independently represent a fluorine atom, or a hydrocarbyl group having 1 to 40 carbon atoms and optionally containing a heteroatom. The hydrocarbyl group may be saturated or unsaturated, and may be linear, branched, or cyclic. Specific examples thereof include those exemplified in the description of R¹⁰⁷ in the general formula (1A′). R^{fb1} and R^{fb2} are preferably a fluorine atom or a linear fluorinated alkyl group having 1 to 4 carbon atoms. Alternatively, R^{fb1} and R^{fb2} may bond with each other to form a ring together with a group (—CF₂—SO₂—N⁻—SO₂—CF₂—) bonded with R^{fb1} and R^{fb2}. In this event, the group obtained by bonding R^{fb1} and R^{fb2} with each other is preferably a fluorinated ethylene group or a fluorinated propylene group.

In the general formula (1C), R^{fc1}, R^{fc2}, and R^{fc3} each independently represent a fluorine atom, or a hydrocarbyl group having 1 to 40 carbon atoms and optionally containing a heteroatom. The hydrocarbyl group may be saturated or unsaturated, and may be linear, branched, or cyclic. Specific examples thereof include those exemplified in the description of R¹⁰⁷ in the general formula (1A′). R^{fc1}, R^{fc2}, and R^{fc3} are preferably a fluorine atom or a linear fluorinated alkyl group having 1 to 4 carbon atoms. Alternatively, R^{fc1} and R^{fc2} may bond with each other to form a ring together with a group (—CF₂—SO₂—C⁻—SO₂—CF₂—) bonded with R^{fc1} and R^{fc2}. In this event, the group obtained by bonding R^{fc1} and R^{fc2} with each other is preferably a fluorinated ethylene group or a fluorinated propylene group.

In the general formula (1D), R^{fd} represents a hydrocarbyl group having 1 to 40 carbon atoms and optionally containing a heteroatom. The hydrocarbyl group may be saturated or unsaturated, and may be linear, branched, or cyclic. Specific examples thereof include those exemplified in the description of R¹⁰⁷ in the general formula (1A′).

The synthesis of the sulfonium salt containing the anion shown by the general formula (1D) is described in detail in JP 2010-215608 A and JP 2014-133723 A.

Examples of the anion shown by the general formula (1D) include ones exemplified as an anion shown by formula (1D) in JP 2018-197853 A.

Note that the photo-acid generator containing the anion shown by the formula (1D) does not have fluorine at a position of the sulfo group, but has two trifluoromethyl groups at β position, thereby providing sufficient acidity to cut the acid labile group in the base polymer. Thus, this photo-acid generator is utilizable.

Furthermore, one shown by the following general formula (2) can also be used suitably as a photo-acid generator.

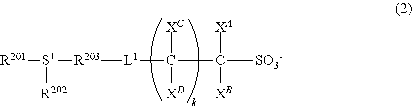

In the general formula (2), R²⁰¹ and R²⁰² each independently represent a hydrocarbyl group having 1 to 30 carbon atoms and optionally containing a heteroatom. R²⁰³ represents a hydrocarbylene group having 1 to 30 carbon atoms and optionally containing a heteroatom. Alternatively, R²⁰¹ and R²⁰², or R²⁰¹ and R²⁰³, may bond with each other to form a ring together with a sulfur atom bonded with R²⁰¹ and R²⁰², or R²⁰¹ and R²⁰³. In this event, examples of the ring include those exemplified as the ring which can be formed by bonding R¹⁰¹ and R¹⁰² together with the sulfur atom in the description of the general formula (10-1).

The hydrocarbyl group represented by R²⁰¹ and R²⁰² may be saturated or unsaturated, and may be linear, branched, or cyclic. Specific examples thereof include: alkyl groups, such as a methyl group, an ethyl group, a propyl group, an isopropyl group, an n-butyl group, a sec-butyl group, a tert-butyl group, an n-pentyl group, a tert-pentyl group, an n-hexyl group, an n-octyl group, a 2-ethylhexyl group, an n-nonyl group, and an n-decyl group; cyclic saturated hydrocarbyl groups, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, and an adamantyl group; aryl groups, such as a phenyl group, a methylphenyl group, an ethylphenyl group, an n-propylphenyl group, an isopropylphenyl group, an n-butylphenyl group, an isobutylphenyl group, a sec-butylphenyl group, a tert-butylphenyl group, a naphthyl group, a methylnaphthyl group, an ethylnaphthyl group, an n-propylnaphthyl group, an isopropylnaphthyl group, an n-butylnaphthyl group, an isobutylnaphthyl group, a sec-butylnaphthyl group, a tert-butylnaphthyl group, and an anthracenyl group; etc. Additionally, these groups may have some or all of hydrogen atoms substituted with a group containing a heteroatom, such as an oxygen atom, a sulfur atom, a nitrogen atom, or a halogen atom, while these groups may have some of carbon atoms substituted with a group containing a heteroatom, such as an oxygen atom, a sulfur atom, or a nitrogen atom. Thus, the resulting hydrocarbyl group may contain a hydroxy group, a cyano group, a carbonyl group, an ether bond, an ester bond, a sulfonic acid ester group, a carbonate group, a lactone ring, a sultone ring, carboxylic anhydride, a haloalkyl group, etc.

The hydrocarbylene group represented by R²⁰³ may be saturated or unsaturated, and may be linear, branched, or cyclic. Specific examples thereof include alkanediyl groups, such as a methylene group, an ethylene group, a propane-1,3-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, an undecane-1,11-diyl group, a dodecane-1,12-diyl group, a tridecane-1,13-diyl group, a tetradecane-1,14-diyl group, a pentadecane-1,15-diyl group, a hexadecane-1,16-diyl group, and a heptadecane-1,17-diyl group; cyclic saturated hydrocarbylene groups, such as a cyclopentanediyl group, a cyclohexanediyl group, a norbornanediyl group, and an adamantanediyl group; arylene groups, such as a phenylene group, a methylphenylene group, an ethylphenylene group, an n-propylphenylene group, an isopropylphenylene group, an n-butylphenylene group, an isobutylphenylene group, a sec-butylphenylene group, a tert-butylphenylene group, a naphthylene group, a methylnaphthylene group, an ethylnaphthylene group, an n-propylnaphthylene group, an isopropylnaphthylene group, an n-butylnaphthylene group, an isobutylnaphthylene group, a sec-butylnaphthylene group, and a tert-butylnaphthylene group; etc. Additionally, these groups may have some or all of hydrogen atoms substituted with a group containing a heteroatom, such as an oxygen atom, a sulfur atom, a nitrogen atom, or a halogen atom, while these groups may have some of carbon atoms substituted with a group containing a heteroatom, such as an oxygen atom, a sulfur atom, or a nitrogen atom. Thus, the resulting hydrocarbylene group may contain a hydroxy group, a cyano group, a carbonyl group, an ether bond, an ester bond, a sulfonic acid ester group, a carbonate group, a lactone ring, a sultone ring, carboxylic anhydride, a haloalkyl group, etc. The heteroatom is preferably an oxygen atom.

In the general formula (2), L¹ represents a single bond, an ether bond, or a hydrocarbylene group having 1 to 20 carbon atoms and optionally containing a heteroatom. The hydrocarbylene group may be saturated or unsaturated, and may be linear, branched, or cyclic. Specific examples thereof include those exemplified as the hydrocarbylene group represented by R²⁰³.

In the general formula (2), X^{A}, X^{B}, X^{C}, and X^{D} each independently represent a hydrogen atom, a fluorine atom, or a trifluoromethyl group. Nevertheless, at least one of X^{A}, X^{B}, X^{C}, and X^{D} is a fluorine atom or a trifluoromethyl group.

In the general formula (2), “k” represents an integer of 0 to 3.

The photo-acid generator shown by the general formula (2) is preferably shown by the following general formula (2′).

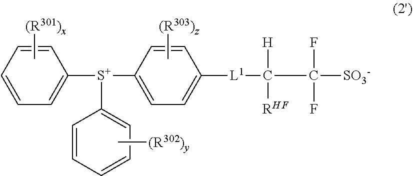

In the general formula (2′), L¹ is as defined above. R^{HF} represents a hydrogen atom or a trifluoromethyl group, preferably a trifluoromethyl group. R³⁰¹, R³⁰², and R³⁰³ each independently represent a hydrogen atom, or a hydrocarbyl group having 1 to 20 carbon atoms and optionally containing a heteroatom. The hydrocarbyl group may be saturated or unsaturated, and may be linear, branched, or cyclic. Specific examples thereof include those exemplified in the description of R¹⁰⁷ in the general formula (1A′). “x” and “y” each independently represent an integer of 0 to 5. “z” represents an integer of 0 to 4.

Examples of the photo-acid generator shown by the general formula (2) include ones exemplified as a photo-acid generator shown by formula (2) in JP 2017-026980 A.

The photo-acid generators containing the anion shown by the general formula (1A′) or (1D) are particularly preferable because of small acid diffusion and excellent solubility to a resist solvent. One shown by the general formula (2′) is also particularly preferable because the acid diffusion is quite small.

Furthermore, a sulfonium salt or an iodonium salt each having an anion containing an iodine atom- or bromine atom-substituted aromatic ring can also be used as the photo-acid generator. Examples of such salts include ones shown by the following general formula (3-1) or (3-2).

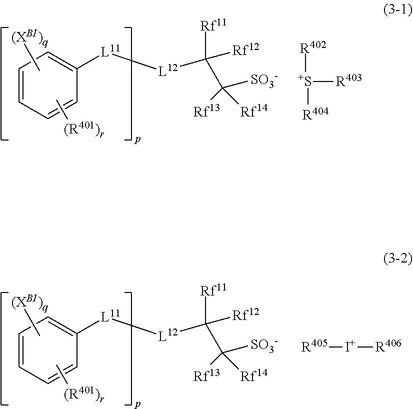

In the general formulae (3-1) and (3-2), “p” represents an integer satisfying 1≤p≤3. “q” and “r” represent integers satisfying 1≤q≤5, 0≤r≤3, and 1≤q+r≤5. “q” is preferably an integer satisfying 1≤q≤3, more preferably 2 or 3. “r” is preferably an integer satisfying 0≤r≤2.

In the general formulae (3-1) and (3-2), X^{BI} represents an iodine atom or a bromine atom. When “q” is 2 or more, X^{BI}'s may be identical to or different from one another.

In the general formulae (3-1) and (3-2), L¹¹ represents a single bond, an ether bond, an ester bond, or a saturated hydrocarbylene group having 1 to 6 carbon atoms and optionally containing an ether bond or an ester bond. The saturated hydrocarbylene group may be linear, branched, or cyclic.

In the general formulae (3-1) and (3-2), L¹² represents a single bond or a divalent linking group having 1 to 20 carbon atoms when “p” is 1. When “p” is 2 or 3, L¹² represents a trivalent or tetravalent linking group having 1 to 20 carbon atoms. This linking group optionally contains an oxygen atom, a sulfur atom, a nitrogen atom, a chlorine atom, a bromine atom, or an iodine atom.

In the general formulae (3-1) and (3-2), R⁴⁰¹ represents: a hydroxy group, a carboxy group, a fluorine atom, a chlorine atom, a bromine atom, or an amino group; a saturated hydrocarbyl group having 1 to 20 carbon atoms, a saturated hydrocarbyloxy group having 1 to 20 carbon atoms, a saturated hydrocarbyloxycarbonyl group having 2 to 10 carbon atoms, a saturated hydrocarbylcarbonyloxy group having 2 to 20 carbon atoms, or a saturated hydrocarbylsulfonyloxy group having 1 to 20 carbon atoms, each of which optionally contains a fluorine atom, a chlorine atom, a bromine atom, a hydroxy group, an amino group, or an ether bond; or —NR^{401A}—C(═O)—R^{401B} or —NR^{401A}—C(═O)—O—R^{401B}. R^{401A} represents a hydrogen atom or a saturated hydrocarbyl group having 1 to 6 carbon atoms, and optionally contains a halogen atom, a hydroxy group, an alkoxy group having 1 to 6 carbon atoms, a saturated hydrocarbylcarbonyl group having 2 to 6 carbon atoms, or a saturated hydrocarbylcarbonyloxy group having 2 to 6 carbon atoms. R^{401B} represents an aliphatic hydrocarbyl group having 1 to 16 carbon atoms or an aryl group having 6 to 12 carbon atoms, and optionally contains a halogen atom, a hydroxy group, a saturated hydrocarbyloxy group having 1 to 6 carbon atoms, a saturated hydrocarbylcarbonyl group having 2 to 6 carbon atoms, or a saturated hydrocarbylcarbonyloxy group having 2 to 6 carbon atoms. The aliphatic hydrocarbyl group may be saturated or unsaturated, and may be linear, branched, or cyclic. The saturated hydrocarbyl groups, saturated hydrocarbyloxy groups, saturated hydrocarbyloxycarbonyl groups, saturated hydrocarbylcarbonyl groups, and saturated hydrocarbylcarbonyloxy groups may be linear, branched, or cyclic. When “p” and/or “r” are 2 or more, R⁴⁰¹'s may be identical to or different from one another.

Above all, R⁴⁰¹ is preferably a hydroxy group, —NR^{401A}—C(═O)—R^{401B}, —NR^{401A}—C(═O)—O—R^{401B}, a fluorine atom, a chlorine atom, a bromine atom, a methyl group, a methoxy group, or the like.

In the general formulae (3-1) and (3-2), Rf¹¹ to Rf¹⁴ each independently represent a hydrogen atom, a fluorine atom, or a trifluoromethyl group. At least one of Rf¹¹ to Rf¹⁴ is a fluorine atom or a trifluoromethyl group. Alternatively, Rf¹¹ and Rf¹² may bond with each other to form a carbonyl group. Particularly preferably, both Rf¹³ and Rf¹⁴ are fluorine atoms.

In the general formulae (3-1) and (3-2), R⁴⁰², R⁴⁰³, R⁴⁰⁴, R⁴⁰⁵, and R⁴⁰⁶ each independently represent a hydrocarbyl group having 1 to 20 carbon atoms and optionally containing a fluorine atom, a chlorine atom, a bromine atom, an iodine atom, or a heteroatom. The hydrocarbyl group may be saturated or unsaturated, and may be linear, branched, or cyclic. Specific examples thereof include those exemplified as hydrocarbyl groups represented by R¹⁰¹ to R¹⁰⁵ in the description of the general formulae (10-1) and (10-2). Additionally, these groups may have some or all of hydrogen atoms substituted with a group containing a hydroxy group, a carboxy group, a halogen atom, a cyano group, a nitro group, a mercapto group, a sultone group, a sulfone group, or a sulfonium salt, while these groups may have some of carbon atoms substituted with an ether bond, an ester bond, a carbonyl group, an amide bond, a carbonate group, or a sulfonic acid ester group. Alternatively, R⁴⁰² and R⁴⁰³ may bond with each other to form a ring together with a sulfur atom bonded with R⁴⁰² and R⁴⁰³. In this event, examples of the ring include those exemplified as the ring which can be formed by bonding R¹⁰¹ and R¹⁰² together with the sulfur atom in the description of the general formula (10-1).

Examples of the cation of the sulfonium salt shown by the general formula (3-1) include those exemplified as cations of the sulfonium salt shown by the general formula (10-1). Meanwhile, examples of the cation of the iodonium salt shown by the general formula (3-2) include those exemplified as cations of the iodonium salt shown by the general formula (10-2).

Examples of the anion of the onium salt shown by the general formula (3-1) or (3-2) include ones shown below, but are not limited thereto. Note that, in the following formulae, X^{BI} is as defined above.

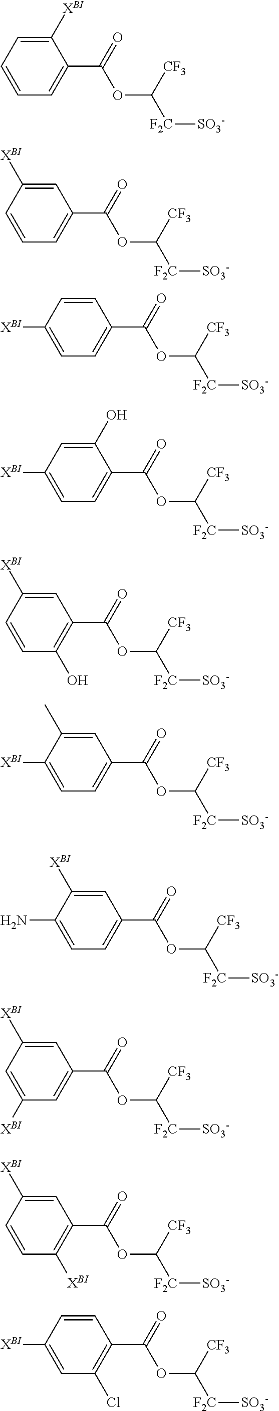

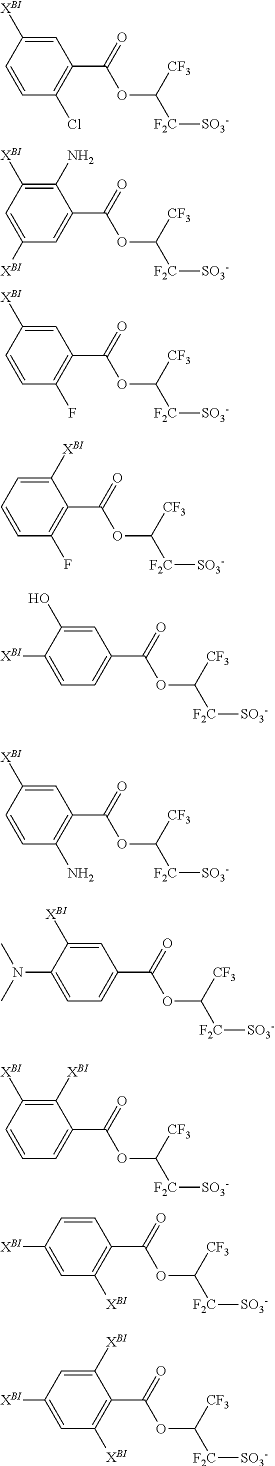

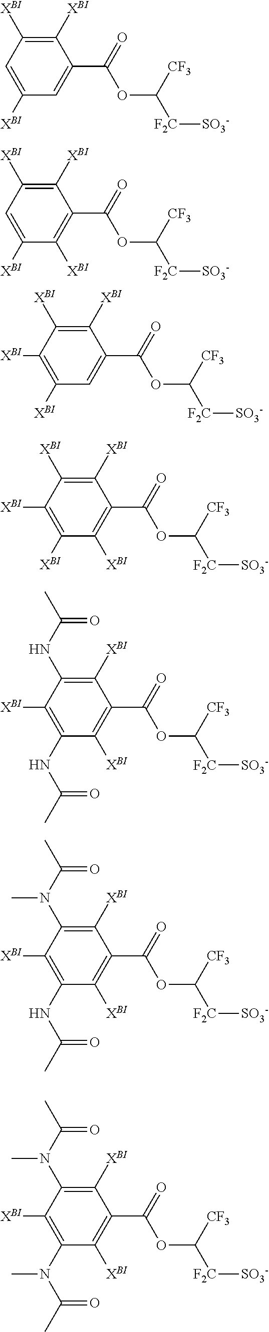

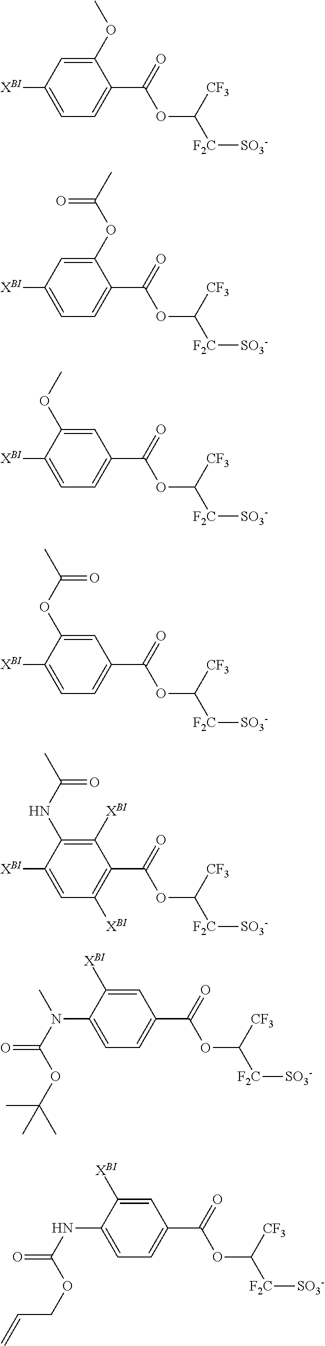

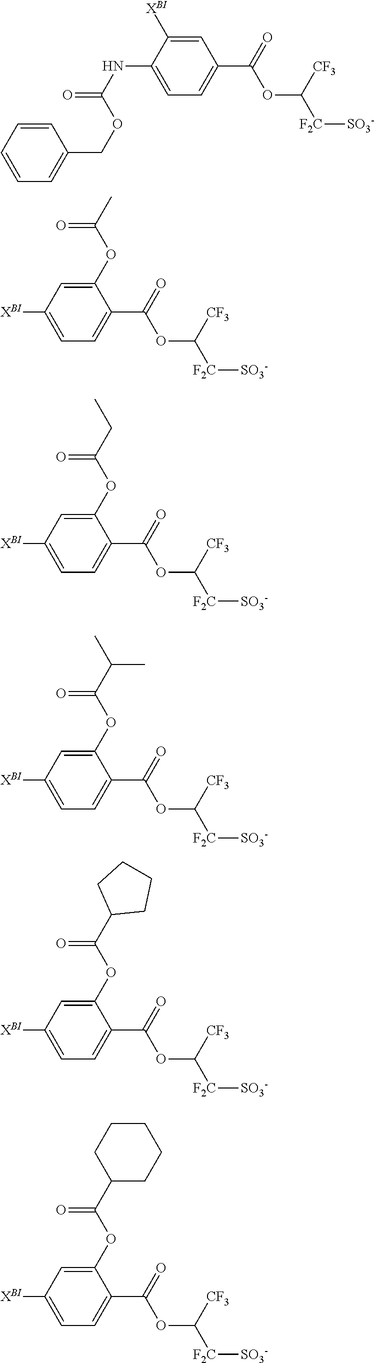

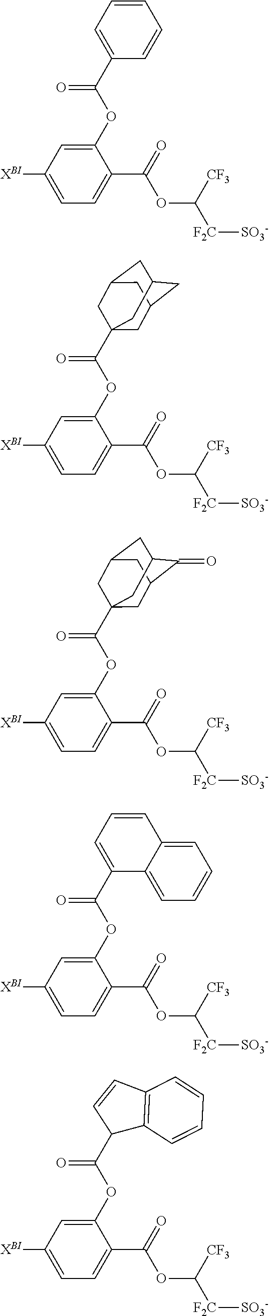

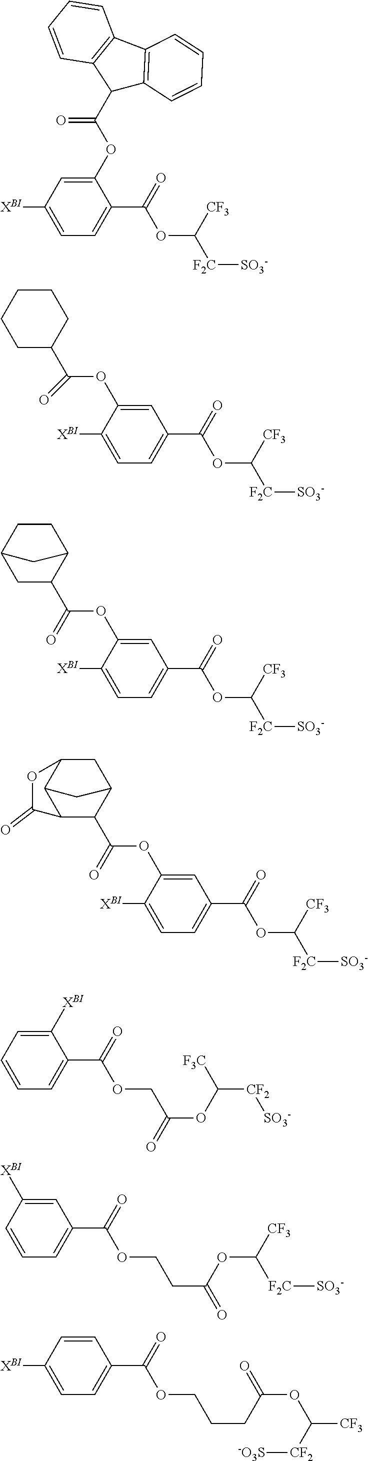

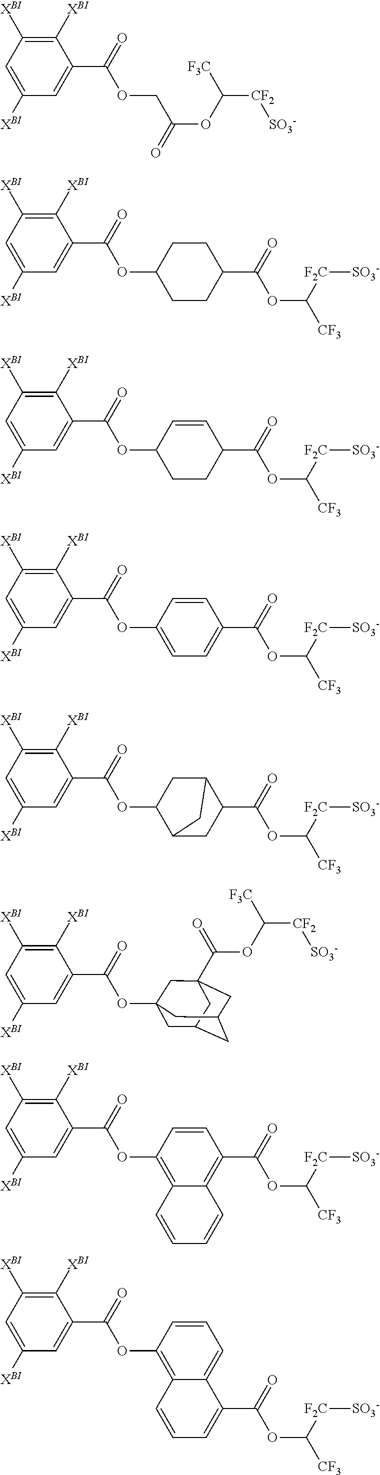

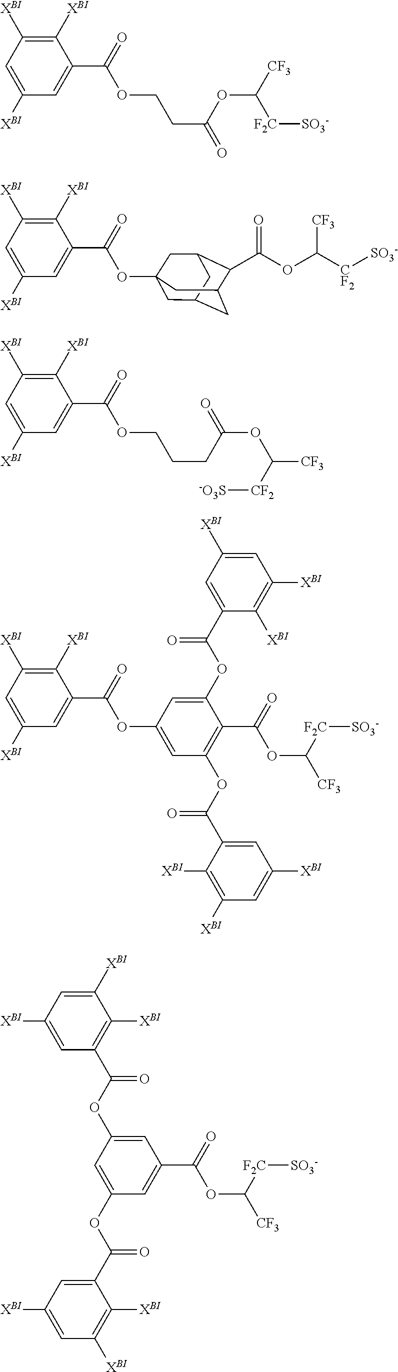

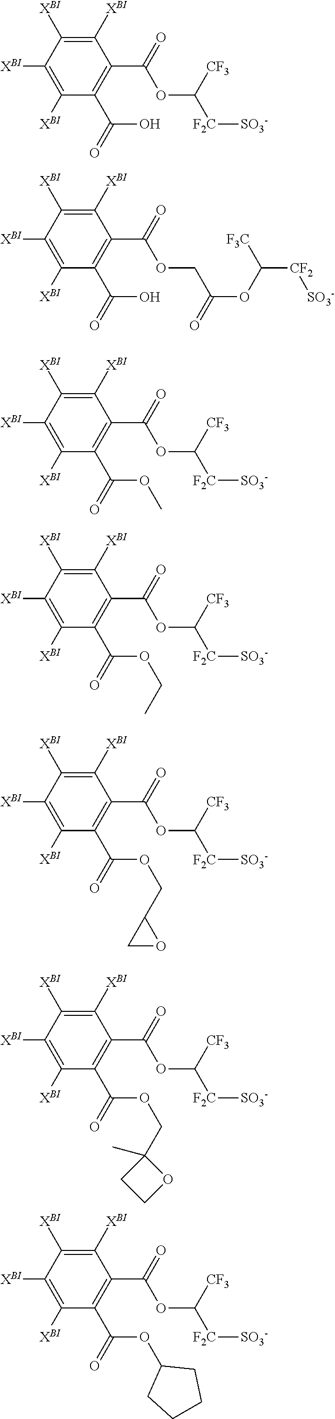

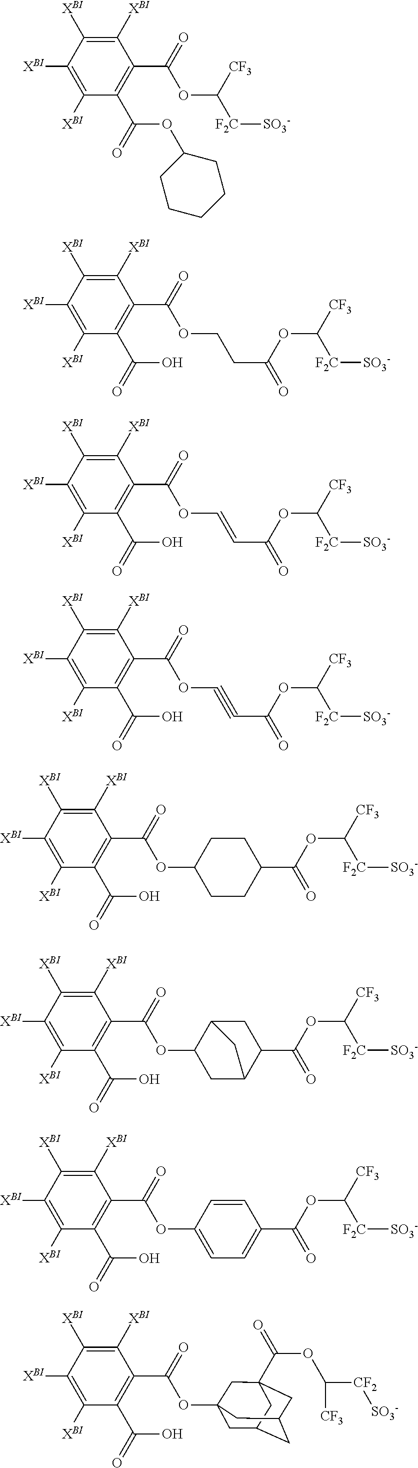

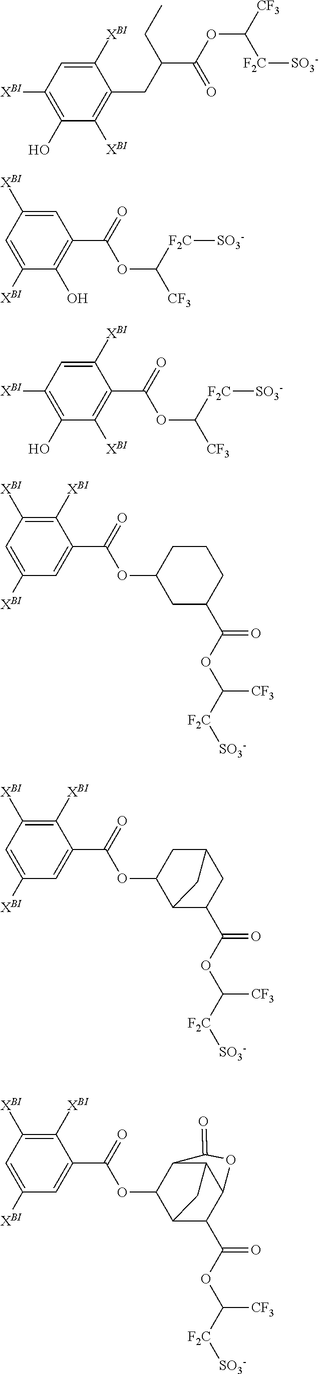

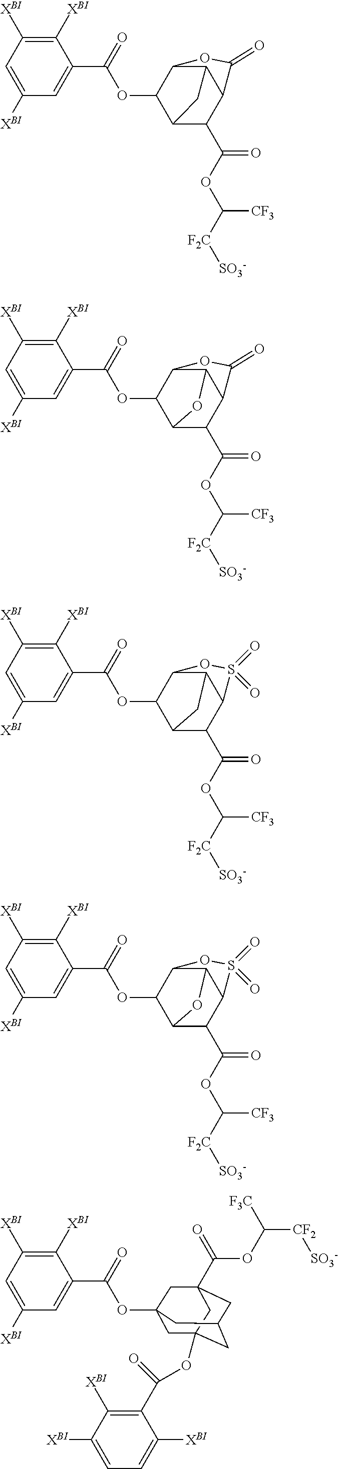

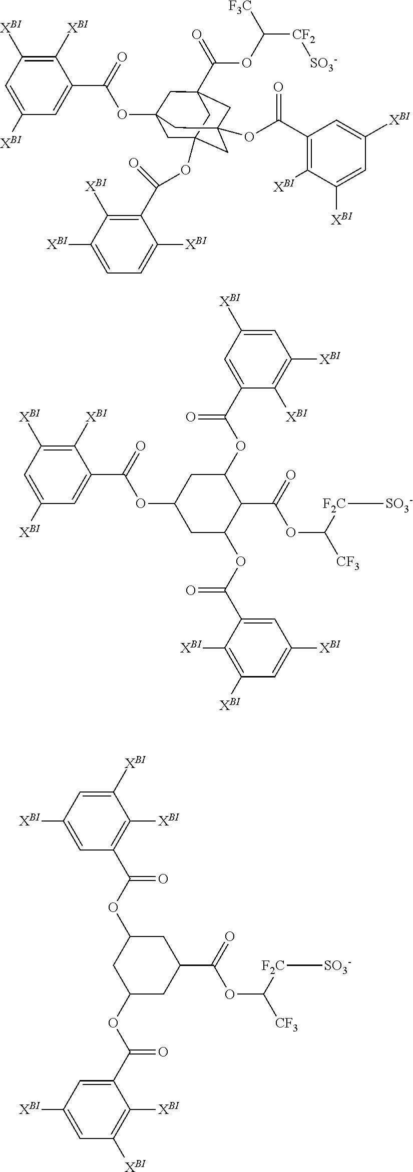

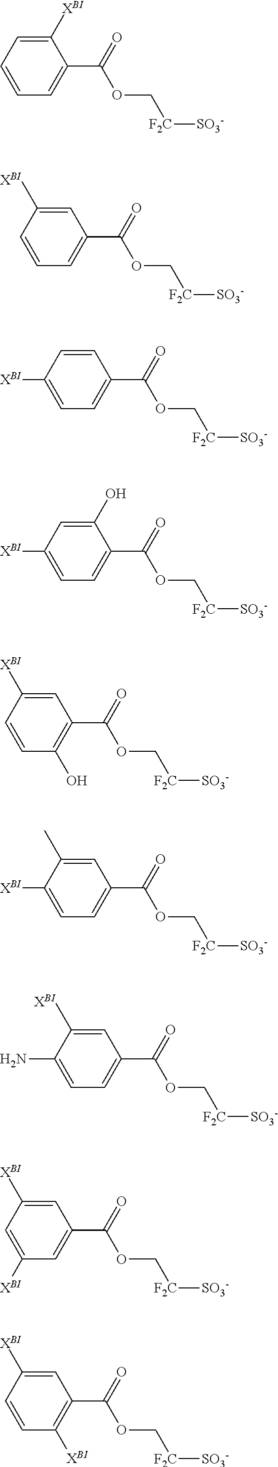

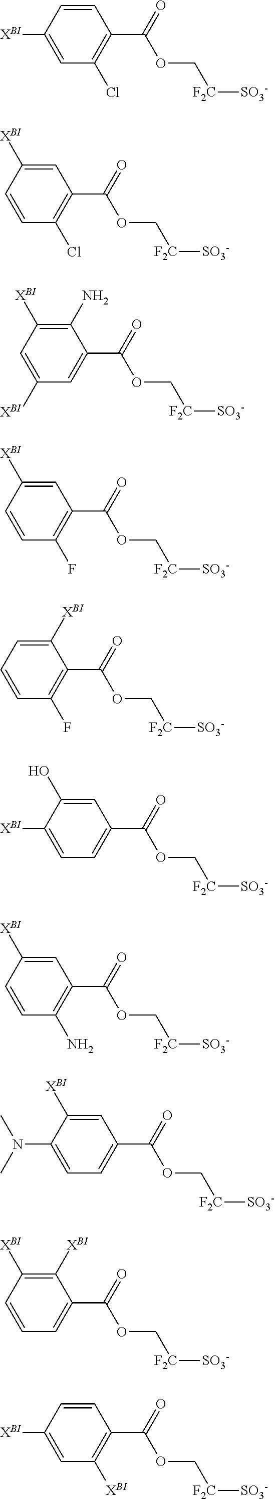

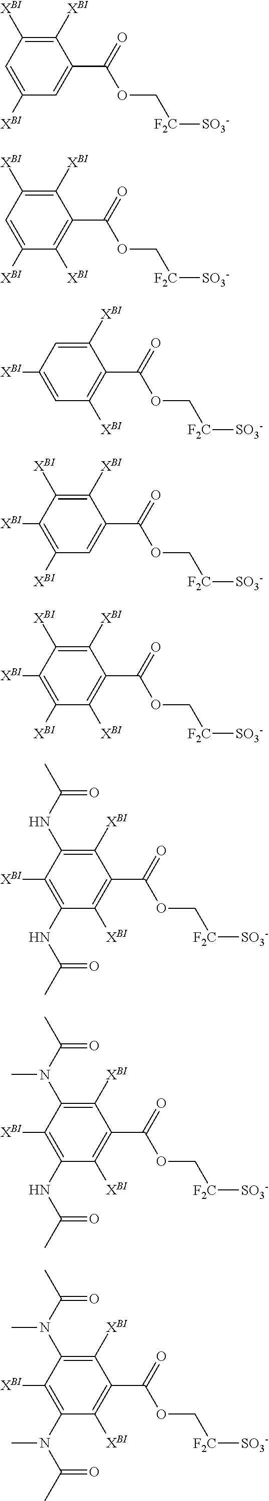

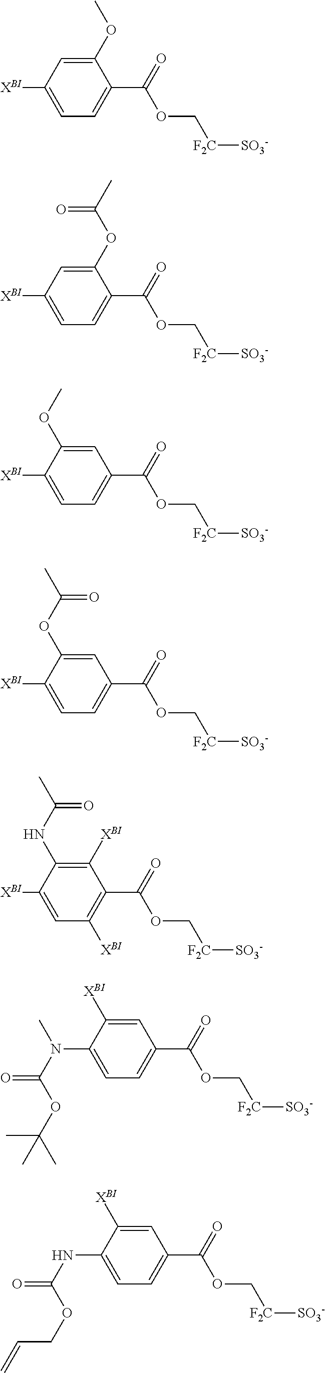

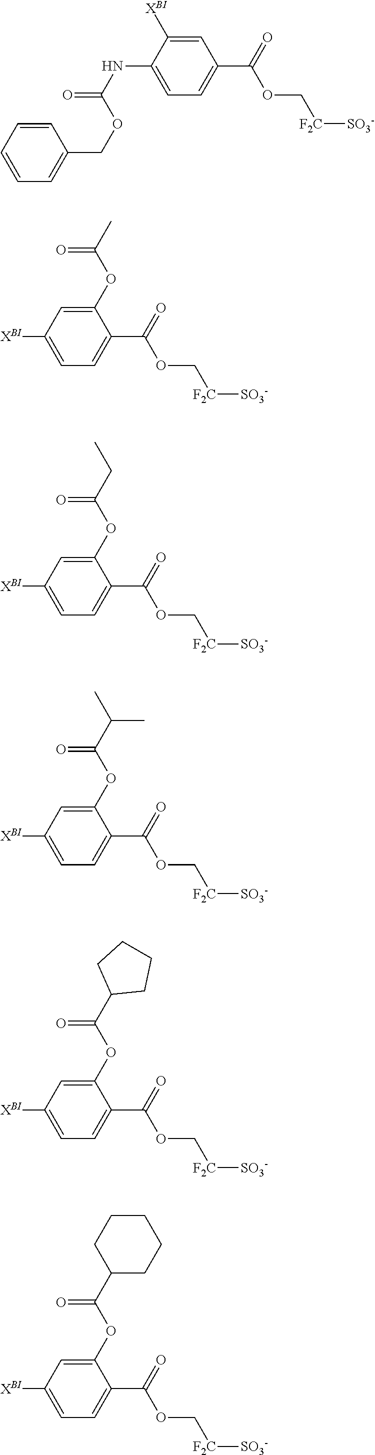

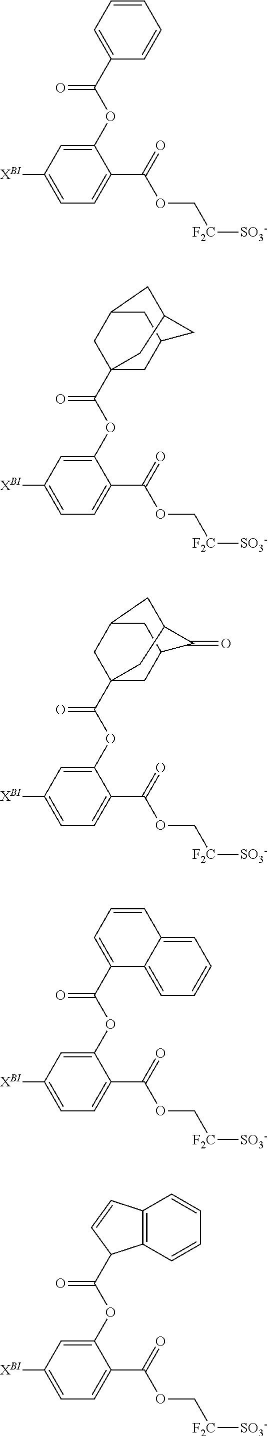

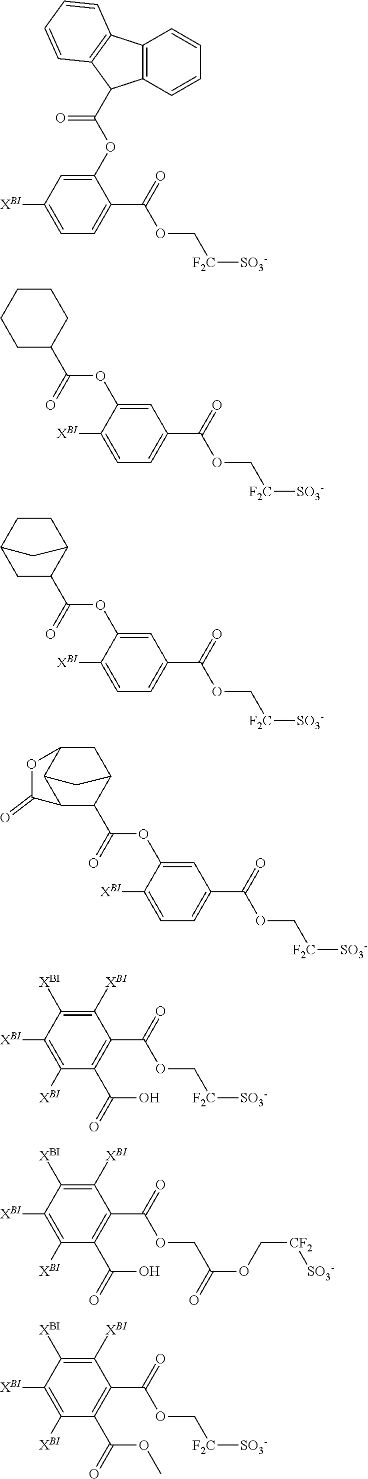

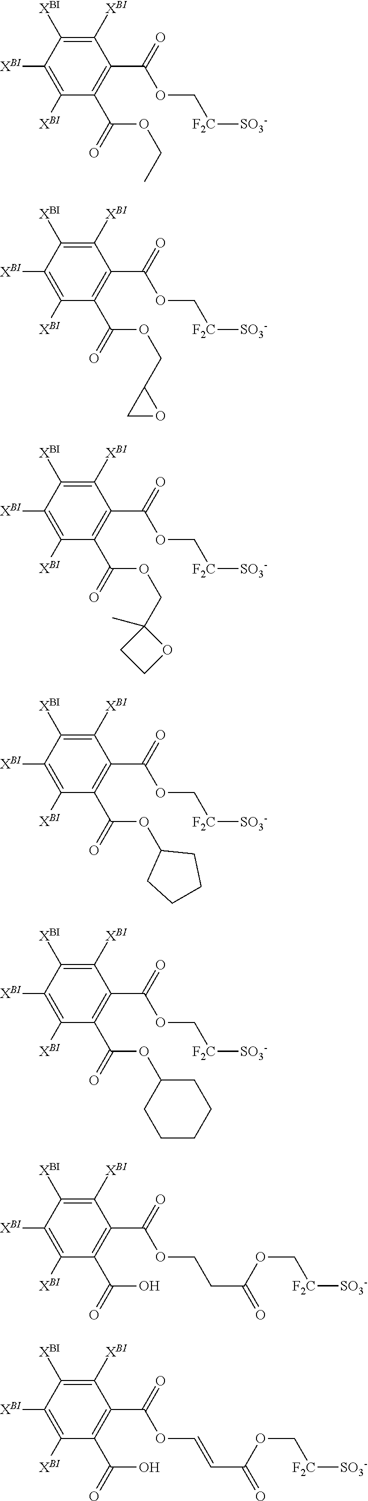

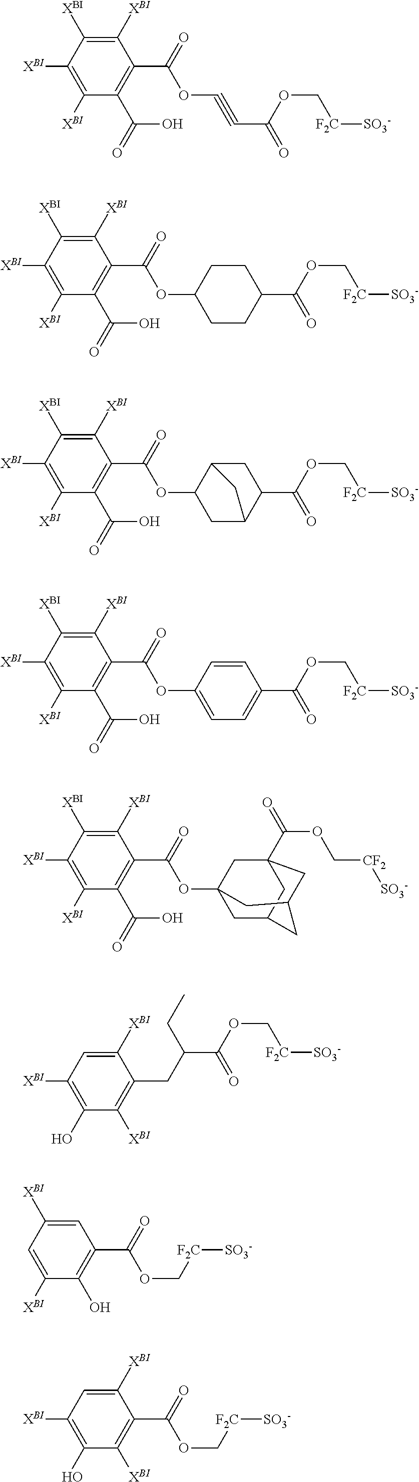

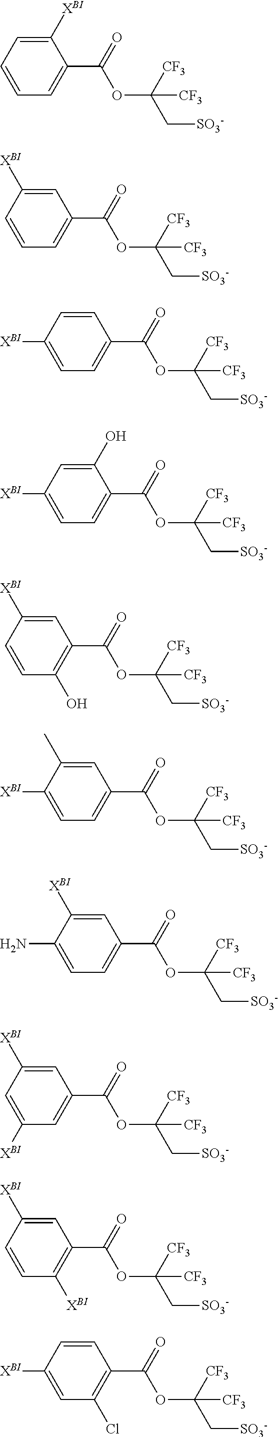

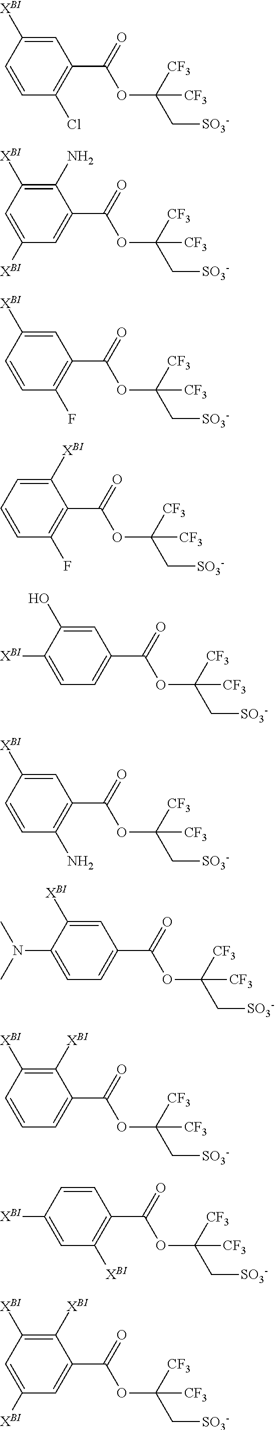

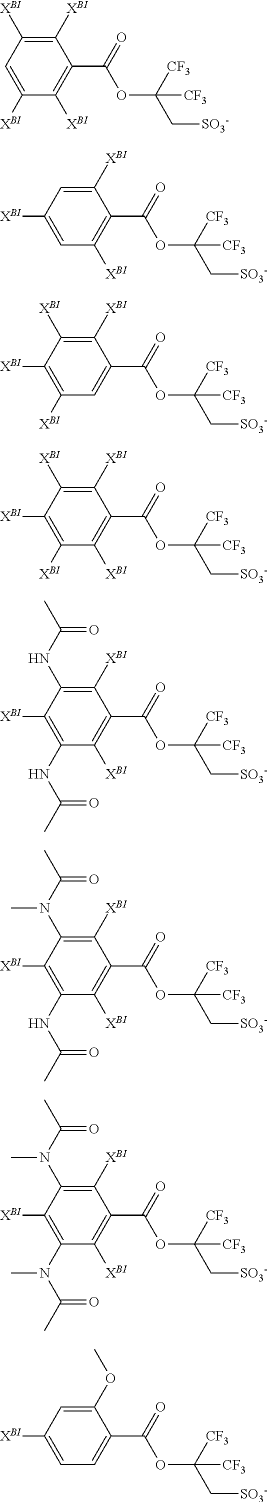

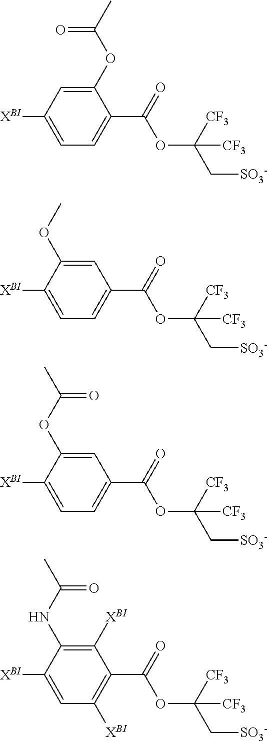

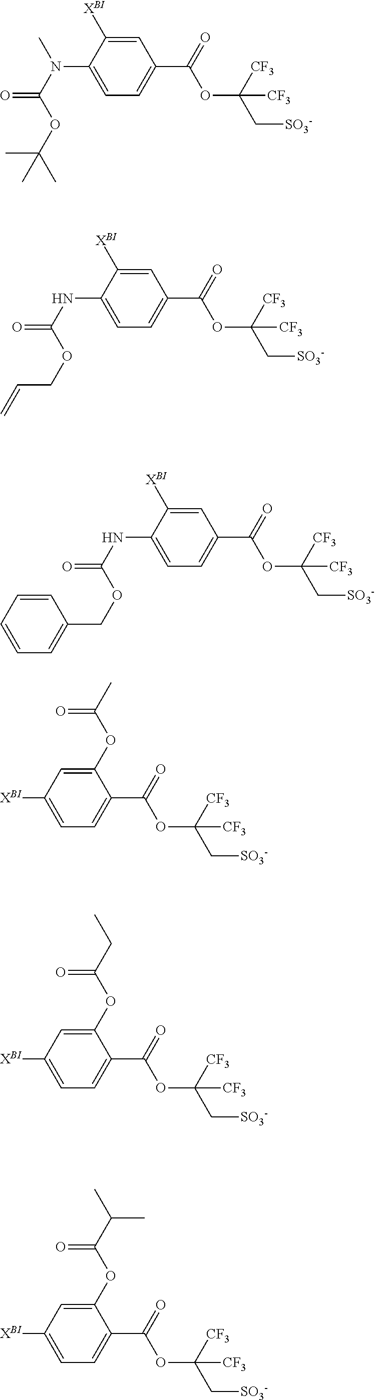

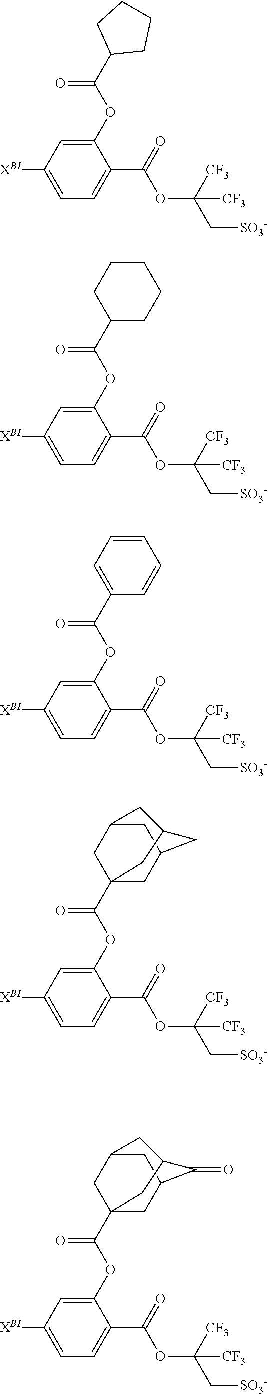

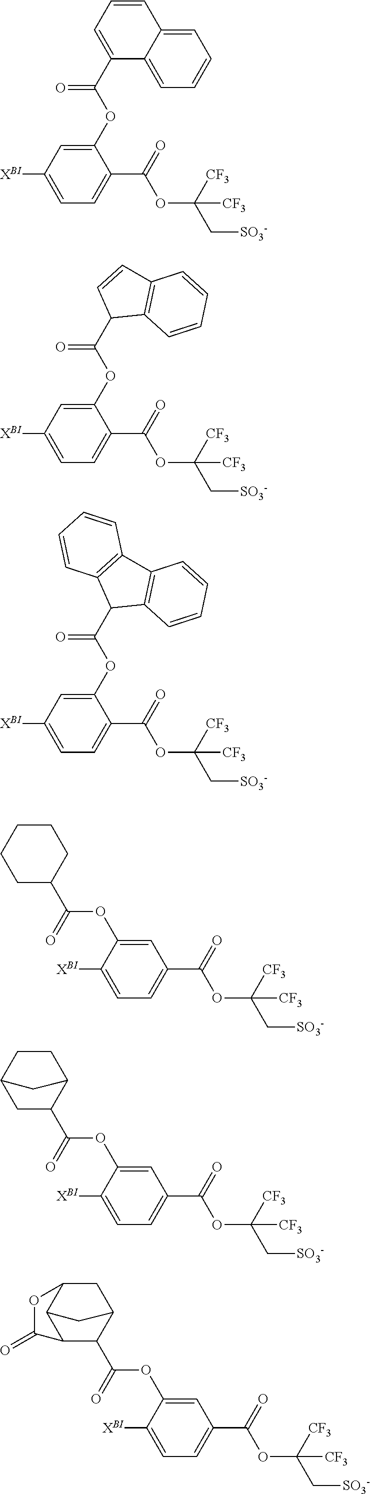

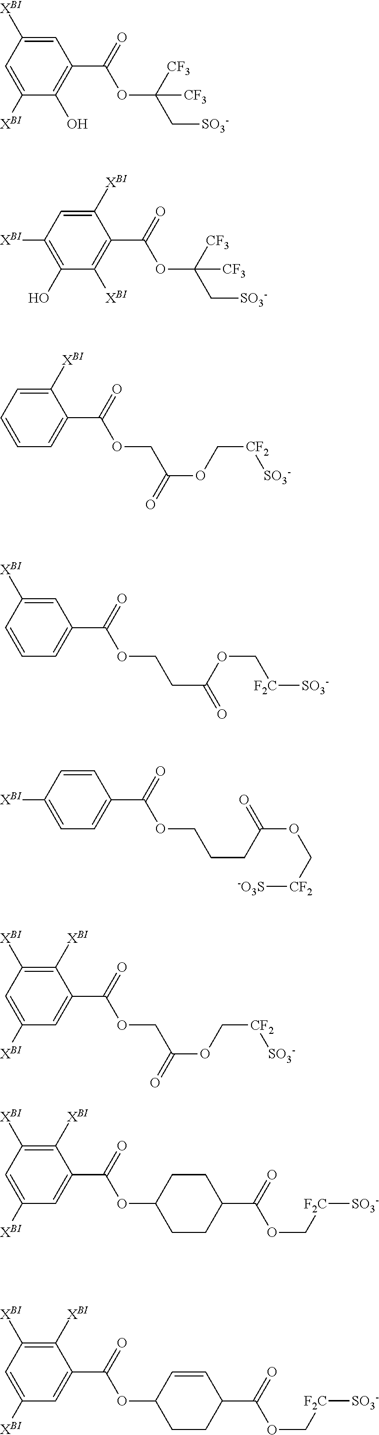

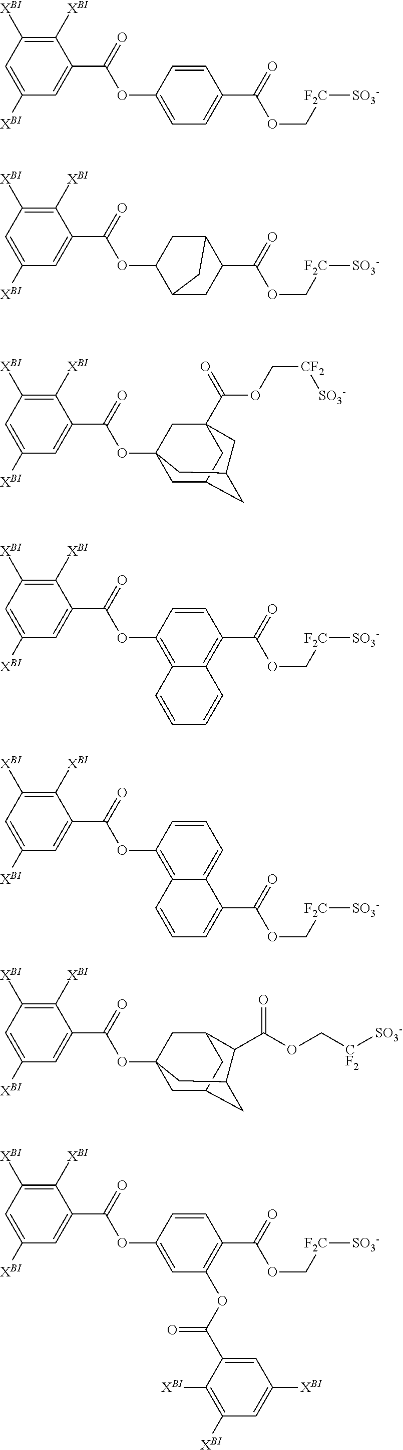

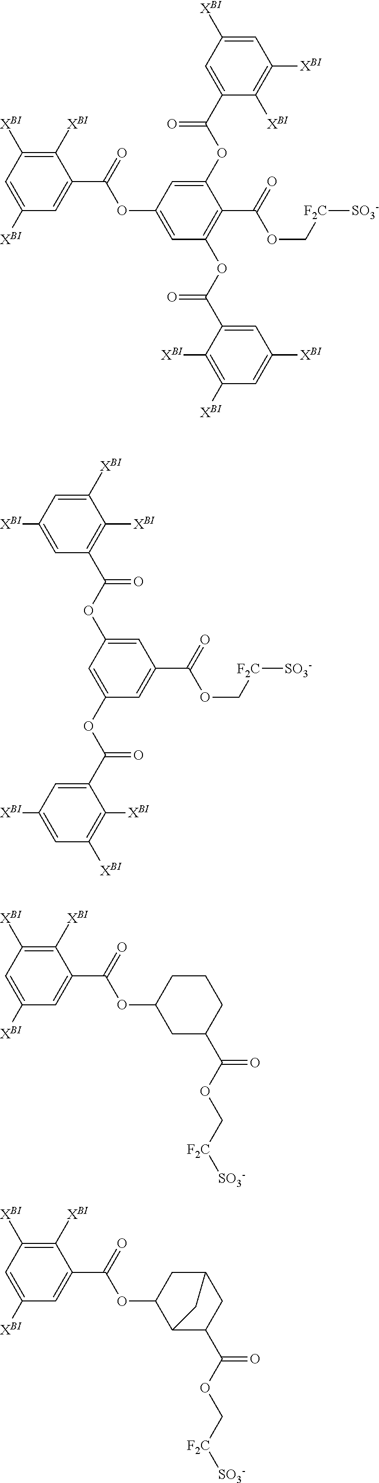

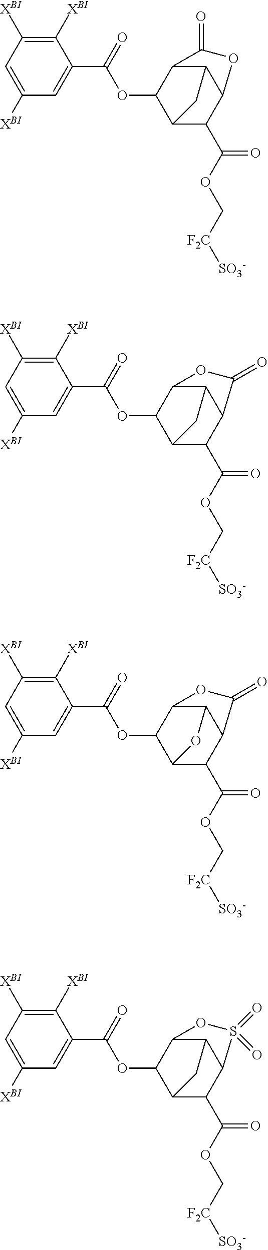

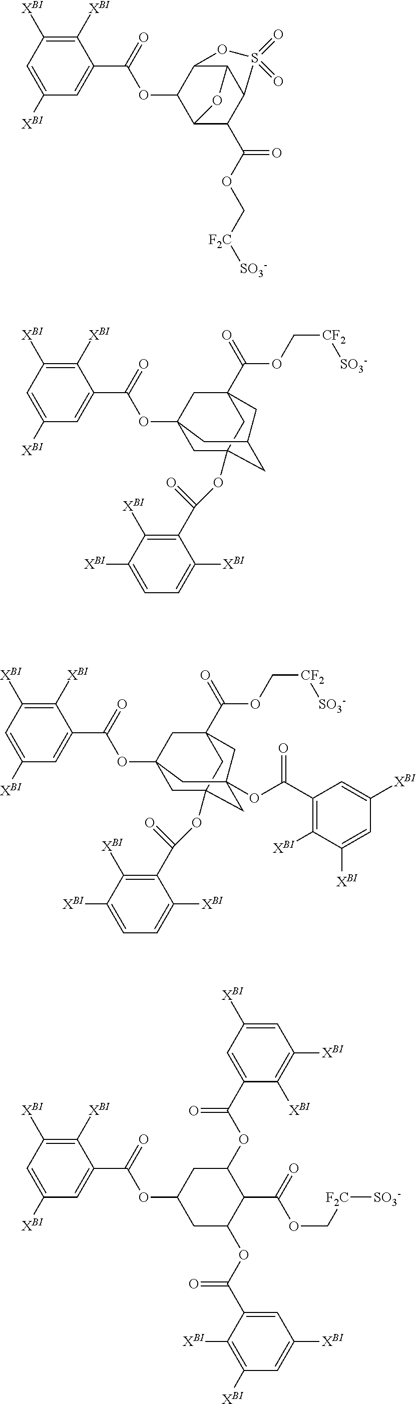

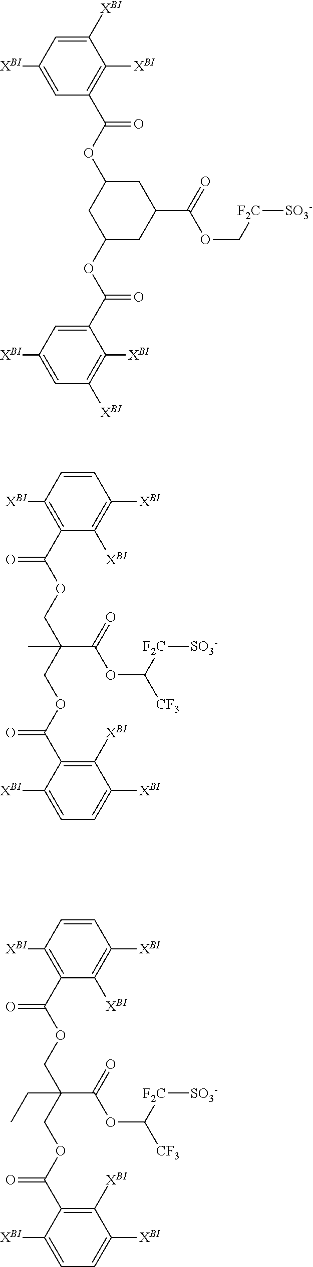

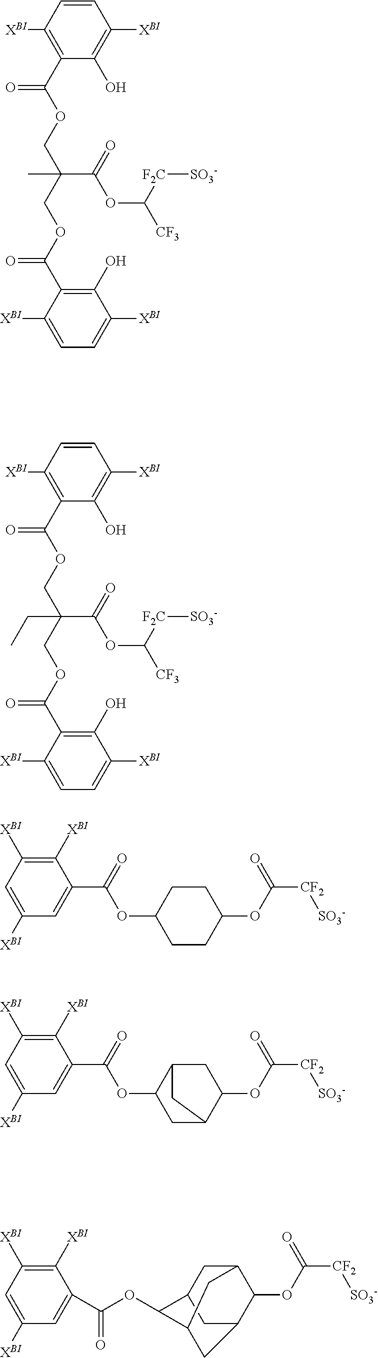

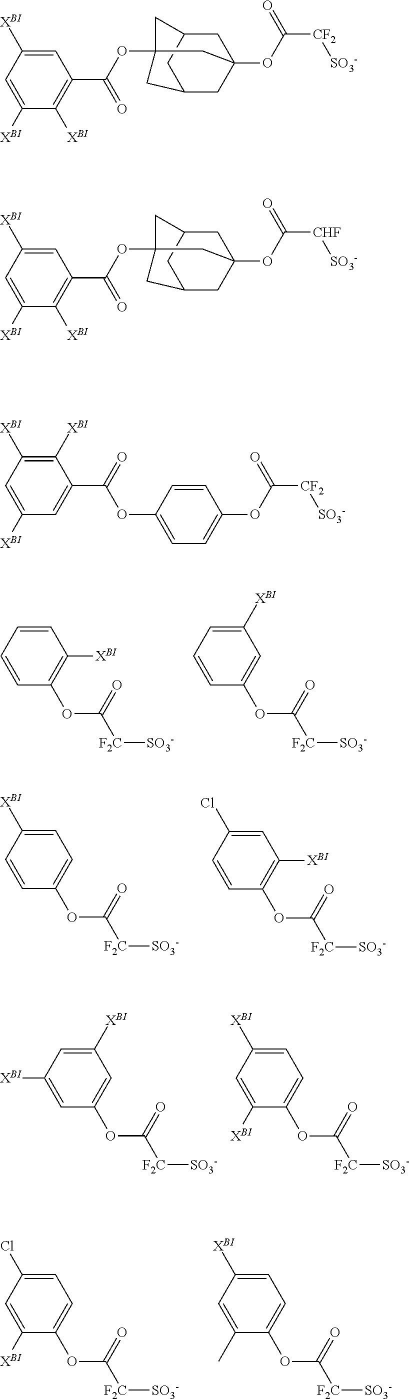

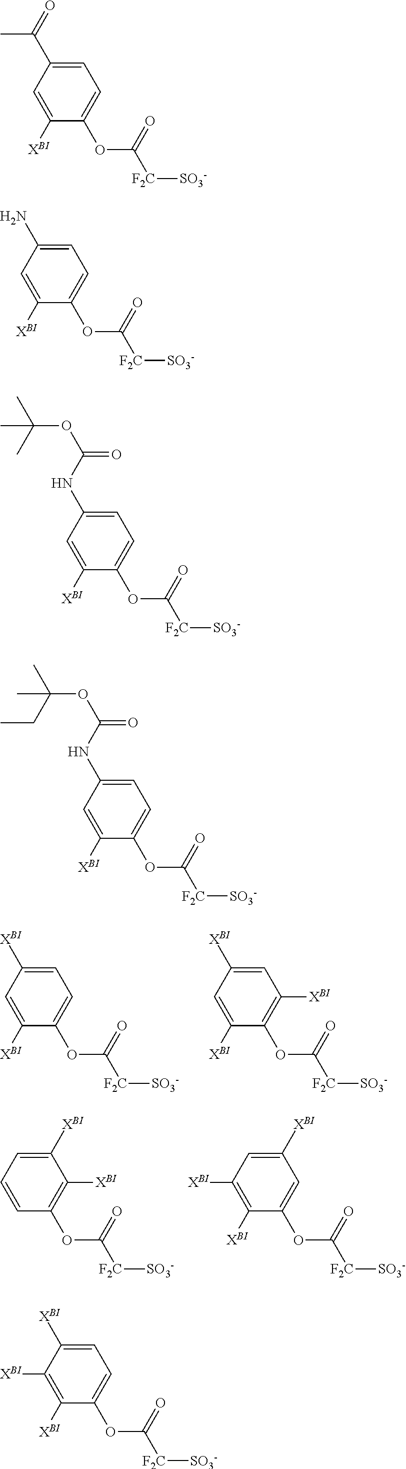

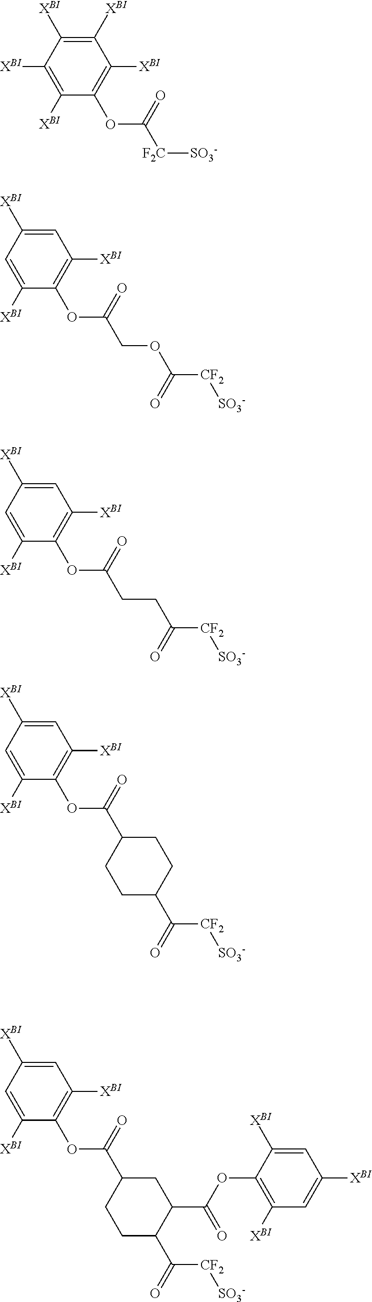

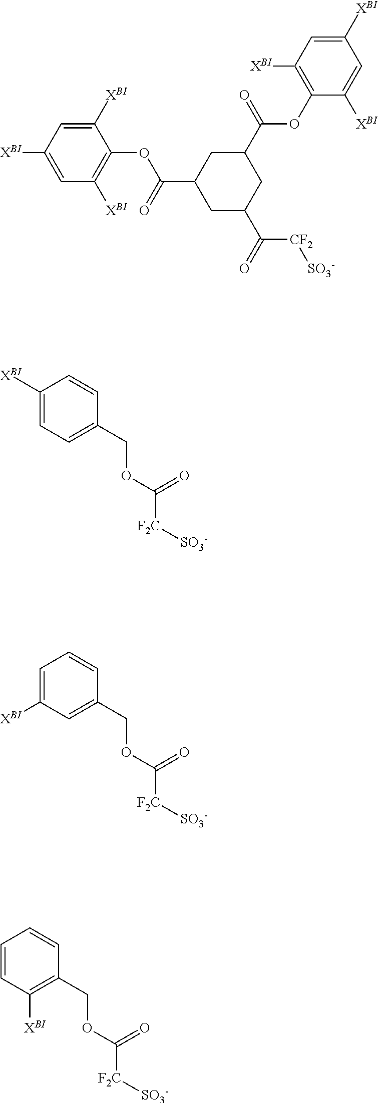

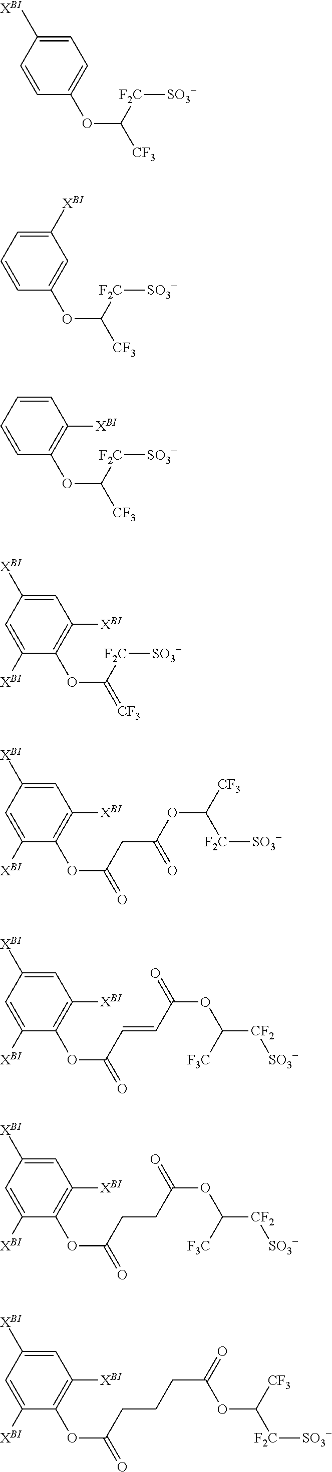

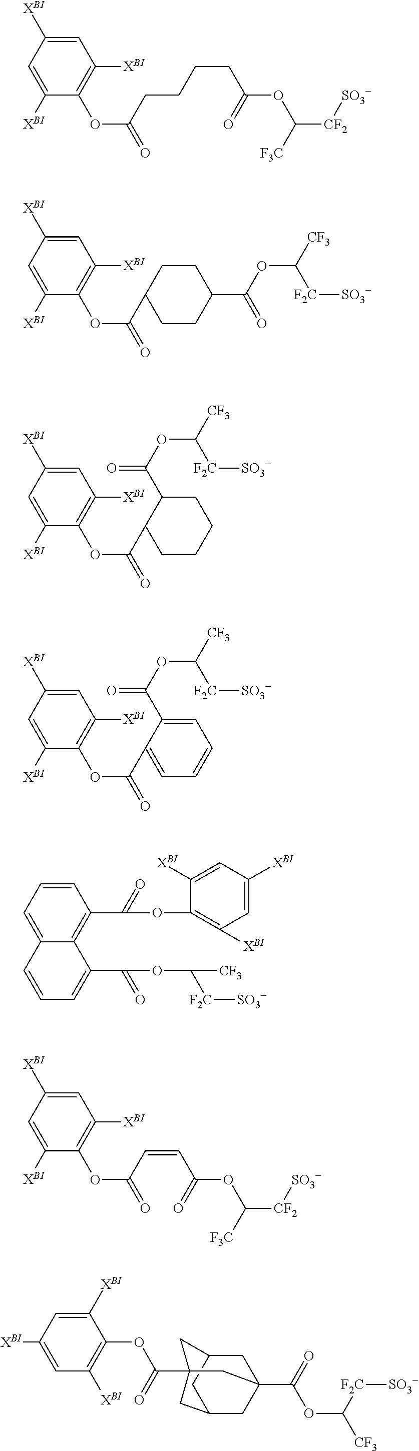

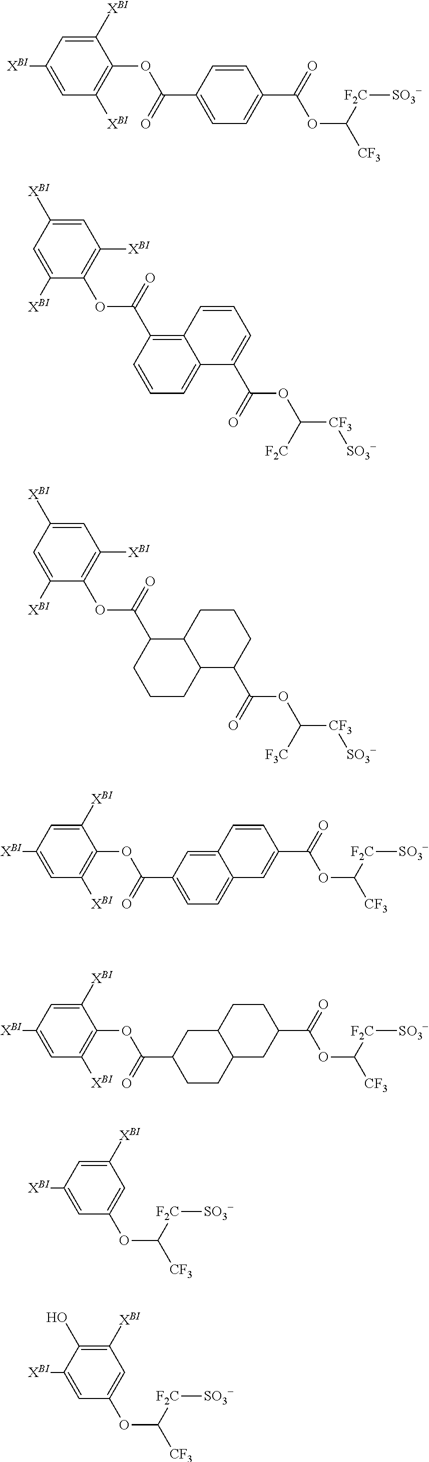

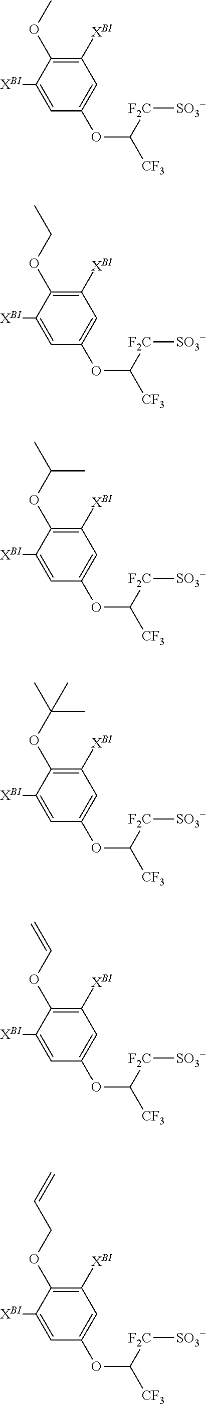

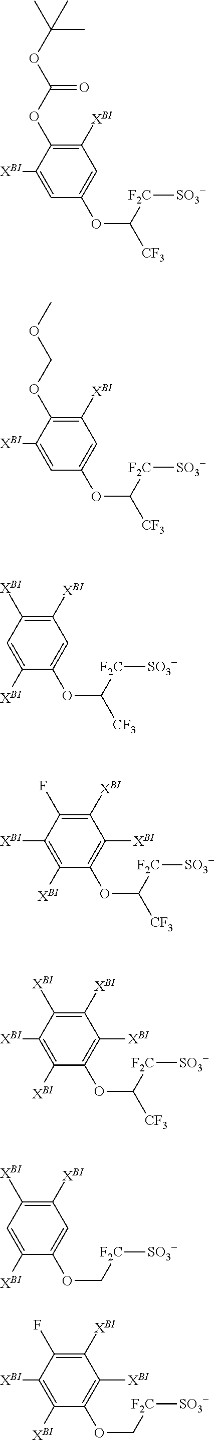

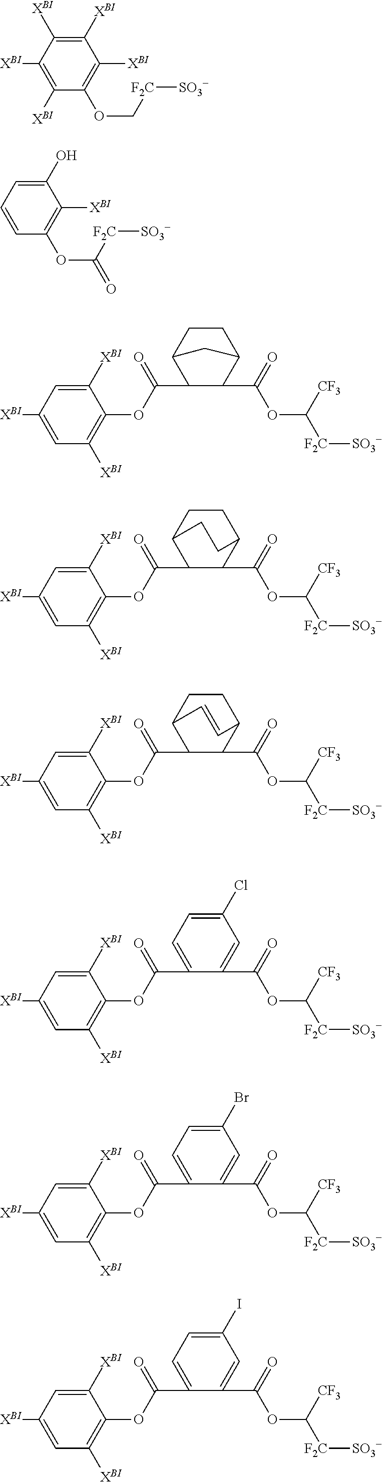

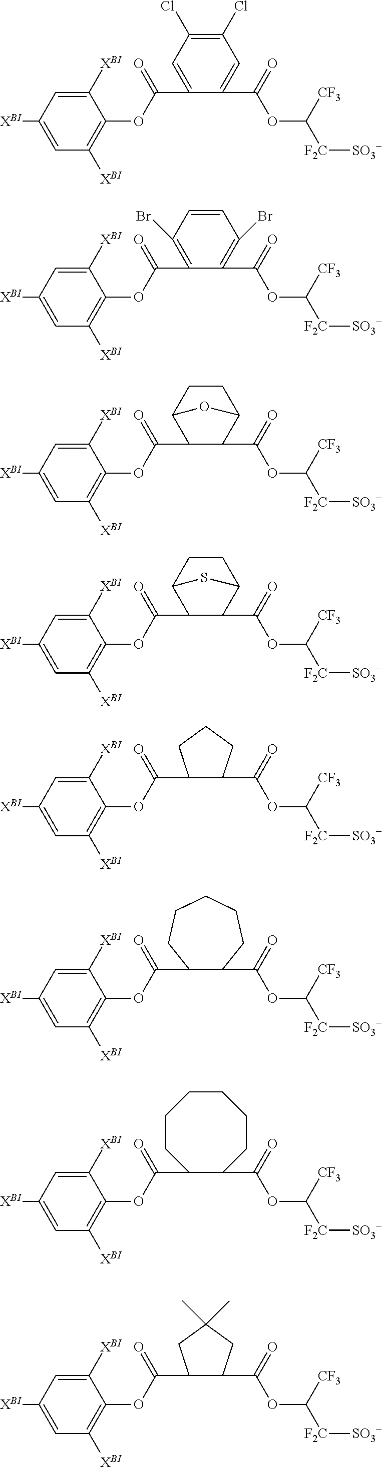

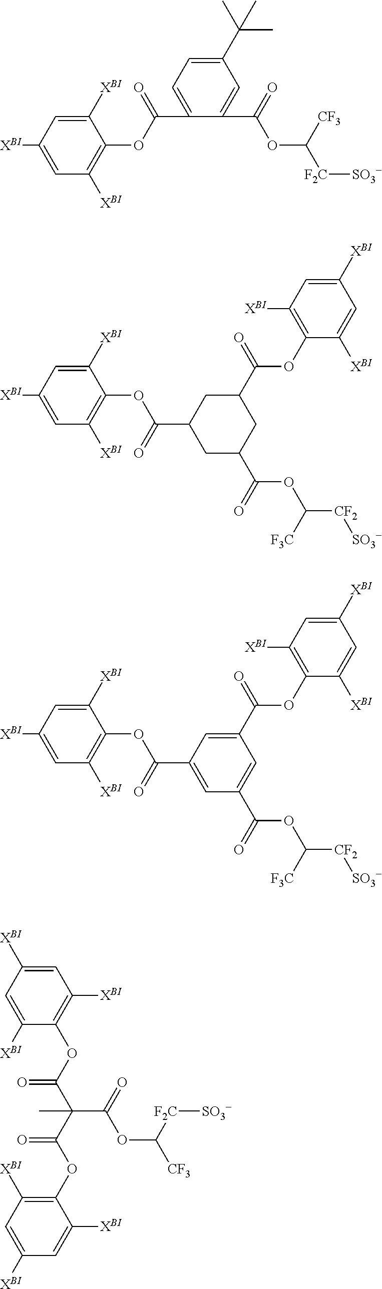

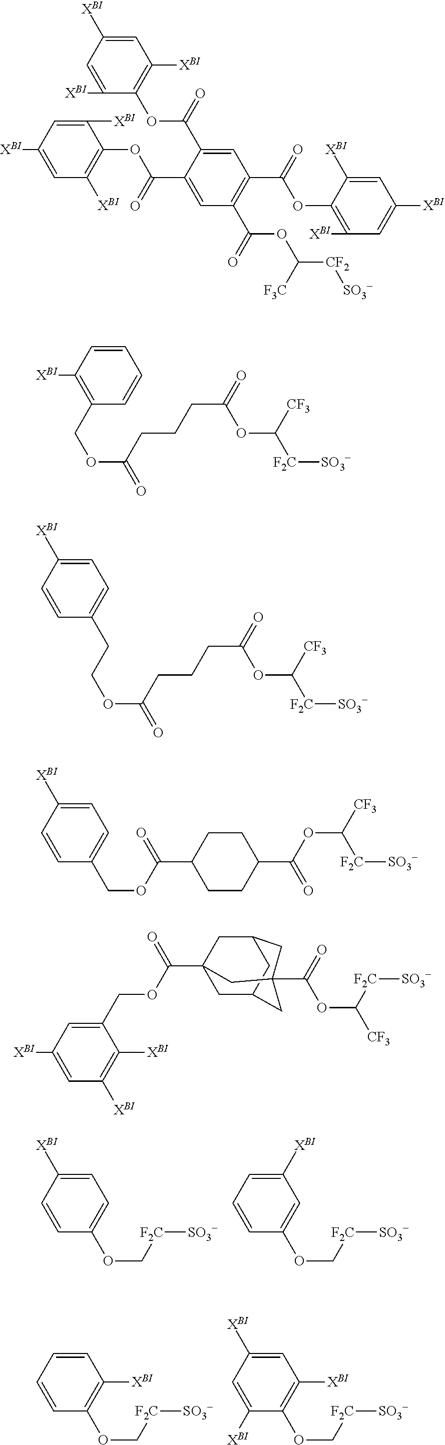

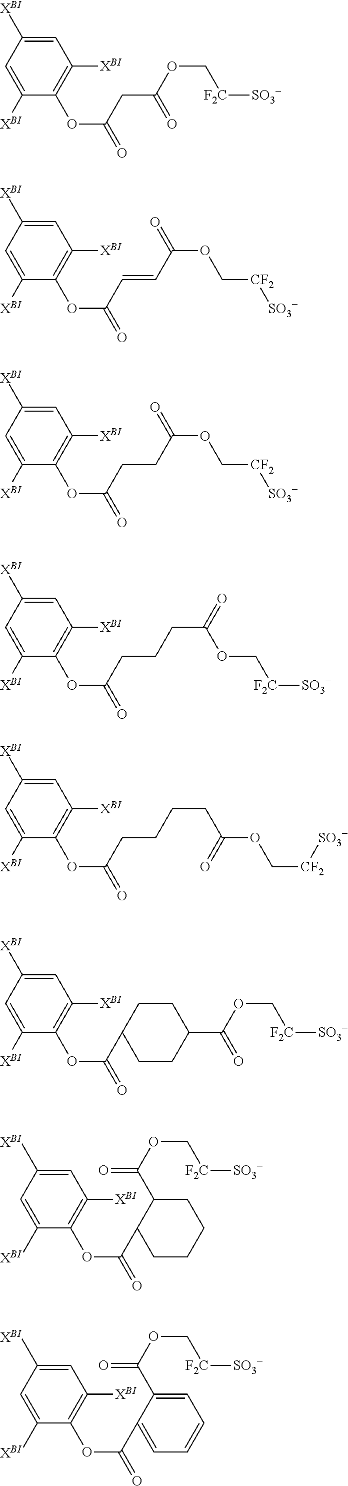

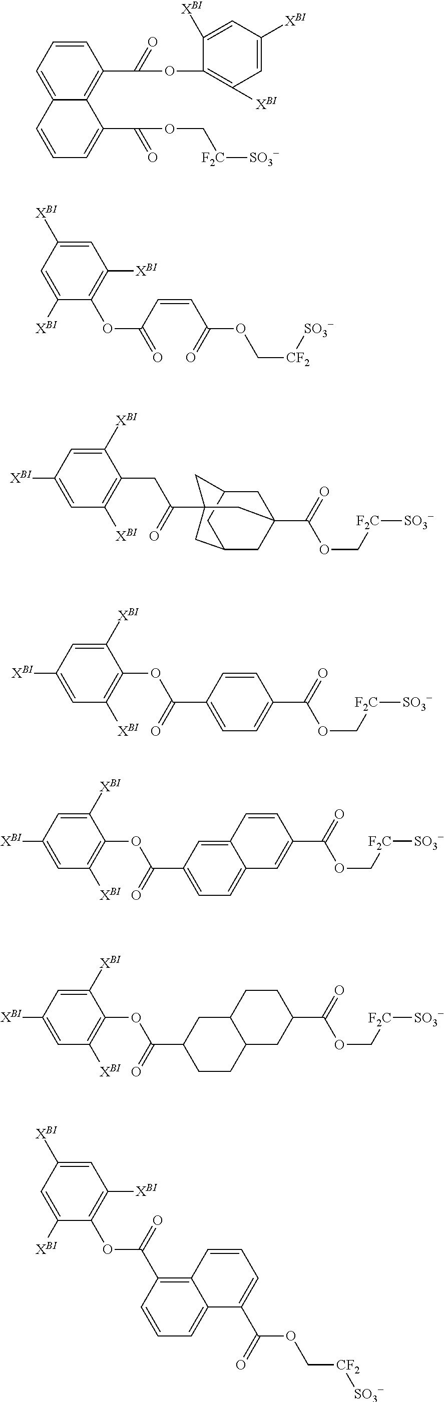

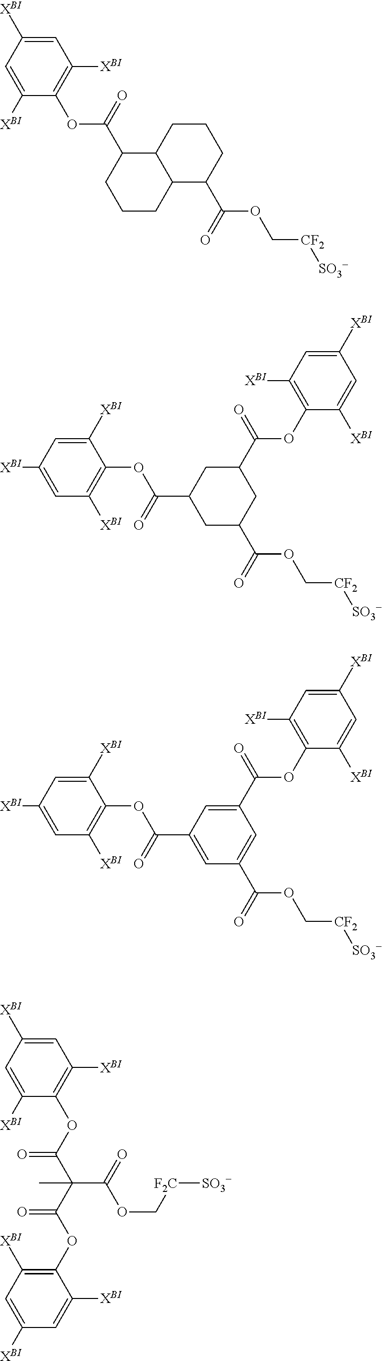

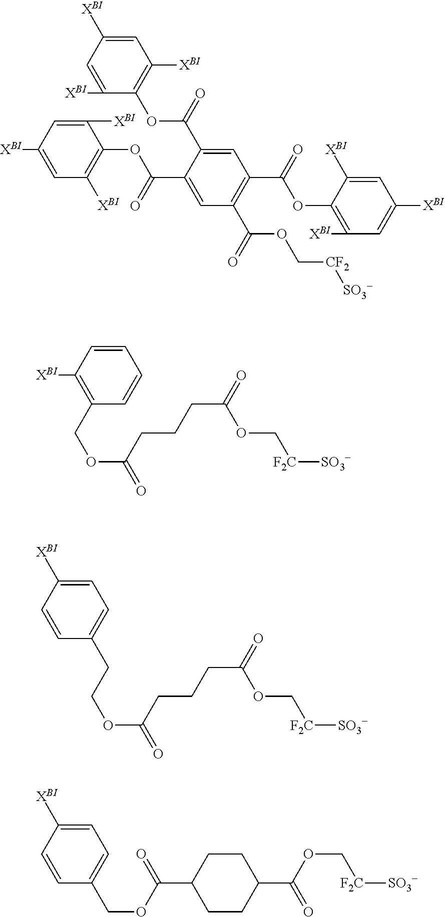

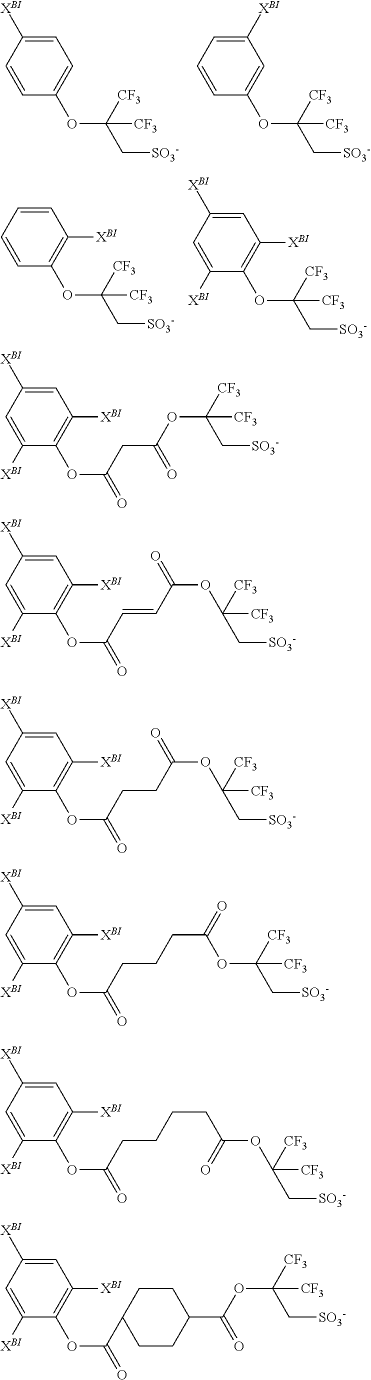

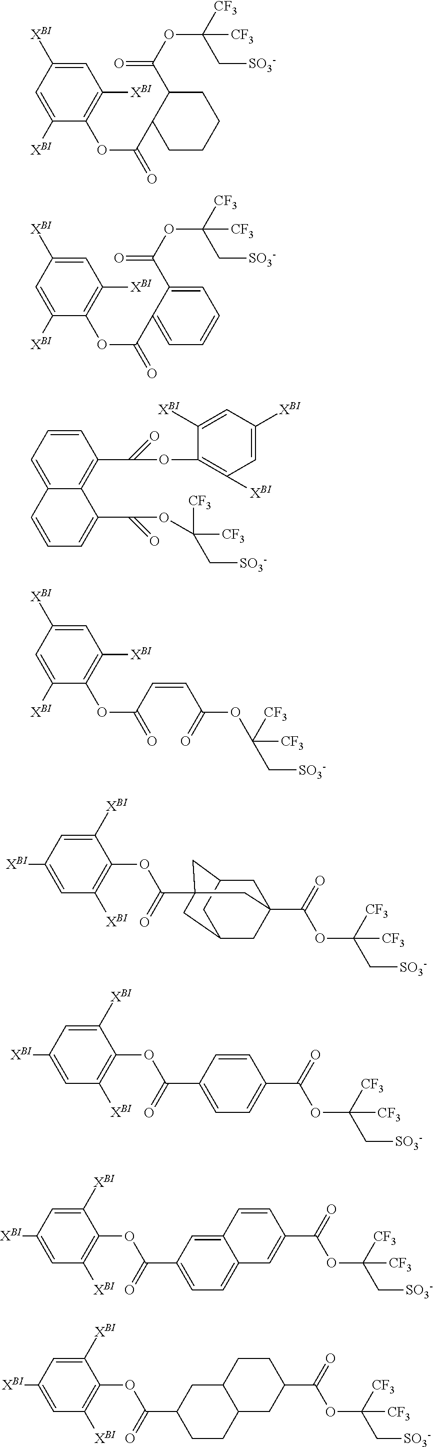

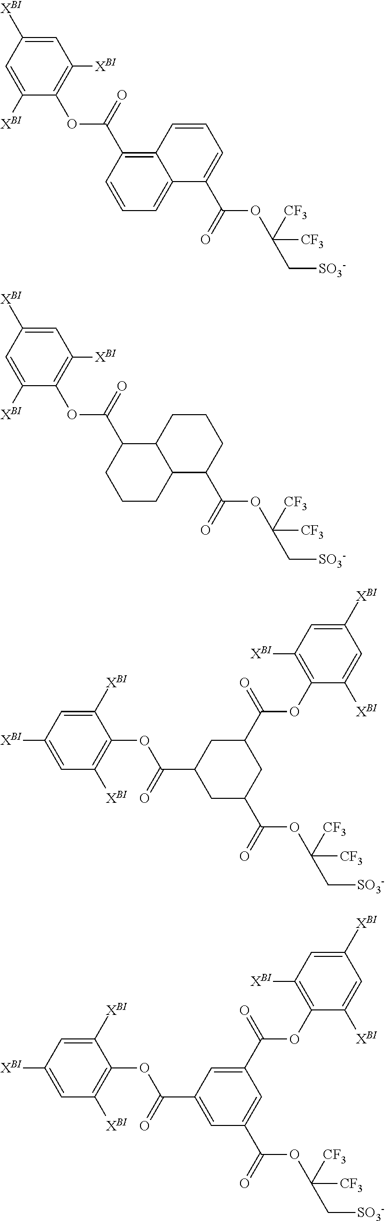

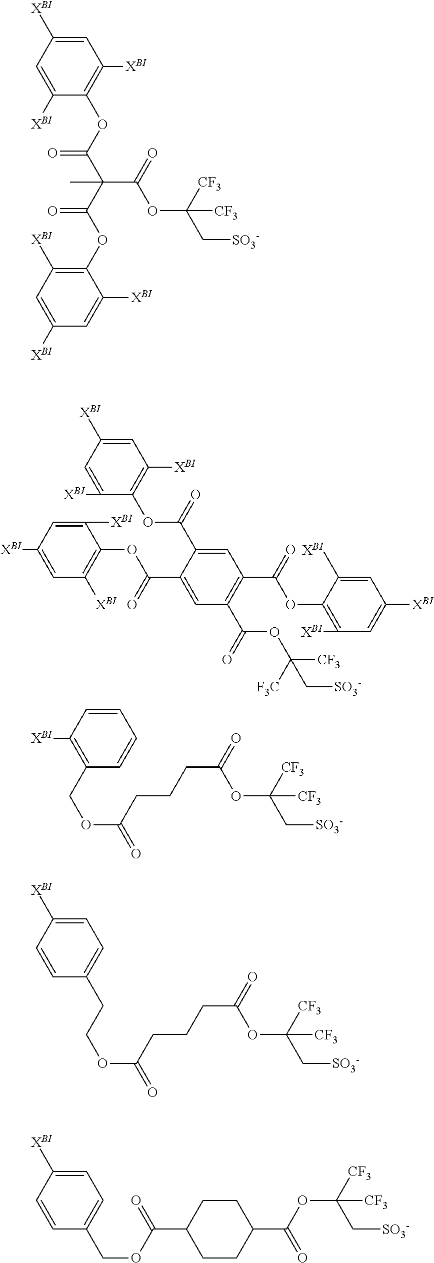

The inventive positive resist material contains the additive-type acid generator in an amount of preferably 0.1 to 50 parts by mass, more preferably 1 to 40 parts by mass, based on 100 parts by mass of the base polymer. Incorporating the repeating unit(s)-a1 and/or -a2 into the base polymer and optionally the additive-type acid generator enables the inventive positive resist material to function as a chemically amplified positive resist material.

### [Organic Solvent]

The inventive positive resist material may be blended with an organic solvent. This organic solvent is not particularly limited, as long as it is capable of dissolving the above-described base polymer and sulfonium salt quencher, as well as the additive-type acid generator and components described below, if contained. Examples of such an organic solvent include ones disclosed in paragraphs [0144] to [0145] of JP 2008-111103 A: ketones, such as cyclohexanone, cyclopentanone, methyl-2-n-pentyl ketone, and 2-heptanone; alcohols, such as 3-methoxybutanol, 3-methyl-3-methoxybutanol, 1-methoxy-2-propanol, 1-ethoxy-2-propanol, and diacetone alcohol; ethers, such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters, such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; lactones, such as γ-butyrolactone; mixed solvents thereof; etc.

The inventive positive resist material contains the organic solvent in an amount of preferably 100 to 10,000 parts by mass, more preferably 200 to 8,000 parts by mass, based on 100 parts by mass of the base polymer.

### [Quencher]

Other than the quencher which is a sulfonium salt of a fluoroalcohol, the inventive positive resist material may be blended with another type of quencher. Examples of this quencher include conventional basic compounds. Examples of the conventional basic compounds include primary, secondary, and tertiary aliphatic amines, mixed amines, aromatic amines, heterocyclic amines, nitrogen-containing compounds having a carboxy group, nitrogen-containing compounds having a sulfonyl group, nitrogen-containing compounds having a hydroxy group, nitrogen-containing compounds having a hydroxyphenyl group, alcoholic nitrogen-containing compounds, amides, imides, carbamates, etc. Particularly preferable are primary, secondary, and tertiary amine compounds disclosed in paragraphs [0146] to [0164] of JP 2008-111103 A; especially, amine compounds having a hydroxy group, an ether bond, an ester bond, a lactone ring, a cyano group, or a sulfonic acid ester group; compounds having a carbamate group disclosed in JP 3790649 B; etc. Adding such a basic compound can, for example, further suppress the acid diffusion rate in the resist film and correct the shape.

Other examples of the quencher include onium salts such as sulfonium salts, iodonium salts, and ammonium salts of carboxylic acids and sulfonic acids which are not fluorinated at α position as disclosed in JP 2008-158339 A. While α-fluorinated sulfonic acid, imide acid, or methide acid is necessary to deprotect the acid labile group of carboxylic acid ester, a carboxylic acid or sulfonic acid not fluorinated at a position is released by salt exchange with the onium salt not fluorinated at a position. Such carboxylic acid and sulfonic acid not fluorinated at a position hardly induce deprotection reaction, and thus function as quenchers.

Examples of such quenchers include a compound shown by the following general formula (4) (onium salt of sulfonic acid not fluorinated at a position) and a compound shown by the following general formula (5) (onium salt of carboxylic acid).

R⁵⁰¹—SO₃⁻Mq⁺ (4)

R⁵⁰²—CO₂⁻Mq⁺ (5)

In the general formula (4), R⁵⁰¹ represents a hydrogen atom or a hydrocarbyl group having 1 to 40 carbon atoms and optionally containing a heteroatom, but excludes groups in which a hydrogen atom bonded to the carbon atom at a position of the sulfo group is substituted with a fluorine atom or a fluoroalkyl group.

The hydrocarbyl group may be saturated or unsaturated, and may be linear, branched, or cyclic. Specific examples thereof include: alkyl groups, such as a methyl group, an ethyl group, a propyl group, an isopropyl group, an n-butyl group, a sec-butyl group, a tert-butyl group, a tert-pentyl group, an n-pentyl group, an n-hexyl group, an n-octyl group, a 2-ethylhexyl group, an n-nonyl group, and an n-decyl group; cyclic saturated hydrocarbyl groups, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group, and an adamantylmethyl group; alkenyl groups, such as a vinyl group, an allyl group, a propenyl group, a butenyl group, and a hexenyl group; cyclic unsaturated aliphatic hydrocarbyl groups, such as a cyclohexenyl group; aryl groups, such as a phenyl group, a naphthyl group, alkylphenyl groups (such as a 2-methylphenyl group, a 3-methylphenyl group, a 4-methylphenyl group, a 4-ethylphenyl group, a 4-tert-butylphenyl group, and a 4-n-butylphenyl group), dialkylphenyl groups (such as a 2,4-dimethylphenyl group and a 2,4,6-triisopropylphenyl group), alkylnaphthyl groups (such as a methylnaphthyl group and an ethylnaphthyl group), and dialkylnaphthyl groups (such as a dimethylnaphthyl group and a diethylnaphthyl group); heteroaryl groups, such as a thienyl group; aralkyl groups, such as a benzyl group, a 1-phenylethyl group, and a 2-phenylethyl group; etc.

Moreover, these groups may have some of hydrogen atoms substituted with a group containing a heteroatom, such as an oxygen atom, a sulfur atom, a nitrogen atom, or a halogen atom, while these groups may have some of carbon atoms substituted with a group containing a heteroatom, such as an oxygen atom, a sulfur atom, or a nitrogen atom. Thus, the resulting hydrocarbyl group may contain a hydroxy group, a cyano group, a carbonyl group, an ether bond, an ester bond, a sulfonic acid ester group, a carbonate bond, a lactone ring, a sultone ring, carboxylic anhydride, a haloalkyl group, etc. Examples of the hydrocarbyl group containing a heteroatom include: alkoxyphenyl groups, such as a 4-hydroxyphenyl group, a 4-methoxyphenyl group, a 3-methoxyphenyl group, a 2-methoxyphenyl group, a 4-ethoxyphenyl group, a 4-tert-butoxyphenyl group, and a 3-tert-butoxyphenyl group; alkoxynaphthyl groups, such as a methoxynaphthyl group, an ethoxynaphthyl group, an n-propoxynaphthyl group, and an n-butoxynaphthyl group; dialkoxynaphthyl groups, such as a dimethoxynaphthyl group and a diethoxynaphthyl group; aryloxoalkyl groups, such as 2-aryl-2-oxoethyl groups including a 2-phenyl-2-oxoethyl group, a 2-(1-naphthyl)-2-oxoethyl group, and a 2-(2-naphthyl)-2-oxoethyl group; etc.

In the general formula (5), R⁵⁰² represents a hydrocarbyl group having 1 to 40 carbon atoms and optionally containing a heteroatom. Examples of the hydrocarbyl group represented by R⁵⁰² include those exemplified as the hydrocarbyl group represented by R⁵⁰¹. Other specific examples thereof include fluorine-containing alkyl groups, such as a trifluoromethyl group, a trifluoroethyl group, a 2,2,2-trifluoro-1-methyl-1-hydroxyethyl group, and a 2,2,2-trifluoro-1-(trifluoromethyl)-1-hydroxyethyl group; fluorine-containing aryl groups, such as a pentafluorophenyl group and a 4-trifluoromethylphenyl group; etc. Mq⁺ represents an onium cation.

A sulfonium salt of a carboxylic acid containing an iodized benzene ring shown by the following general formula (6) can also be used suitably as a quencher.

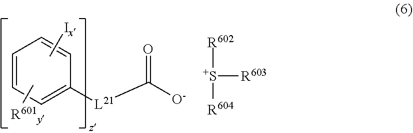

In the general formula (6), R⁶⁰¹ represents: a hydroxy group, a fluorine atom, a chlorine atom, a bromine atom, an amino group, a nitro group, or a cyano group; a saturated hydrocarbyl group having 1 to 6 carbon atoms, a saturated hydrocarbyloxy group having 1 to 6 carbon atoms, a saturated hydrocarbylcarbonyloxy group having 2 to 6 carbon atoms, or a saturated hydrocarbylsulfonyloxy group having 1 to 4 carbon atoms, in each of which some or all of hydrogen atoms may be substituted with a halogen atom; or —NR^{601A}—C(═O)—R^{601B} or —NR^{601A}—C(═O)—O—R^{601B}. R^{601A} represents a hydrogen atom or a saturated hydrocarbyl group having 1 to 6 carbon atoms. R^{601B} represents a saturated hydrocarbyl group having 1 to 6 carbon atoms or an unsaturated aliphatic hydrocarbyl group having 2 to 8 carbon atoms.

In the general formula (6), x′ represents an integer of 1 to 5. y′ represents an integer of 0 to 3. z′ represents an integer of 1 to 3. L²¹ represents a single bond or a linking group having a valency of (z′+1) with 1 to 20 carbon atoms, and optionally contains at least one selected from the group consisting of an ether bond, a carbonyl group, an ester bond, an amide bond, a sultone ring, a lactam ring, a carbonate group, a halogen atom, a hydroxy group, and a carboxy group. The saturated hydrocarbyl groups, saturated hydrocarbyloxy group, saturated hydrocarbylcarbonyloxy group, and saturated hydrocarbylsulfonyloxy group may be linear, branched, or cyclic. When y′ is 2 or more, R⁶⁰¹'s may be identical to or different from one another.

In the general formula (6), R⁶⁰², R⁶⁰³, and R⁶⁰⁴ each independently represent a hydrocarbyl group having 1 to 20 carbon atoms and optionally containing a fluorine atom, a chlorine atom, a bromine atom, an iodine atom, or a heteroatom. The hydrocarbyl group may be saturated or unsaturated, and may be linear, branched, or cyclic. Specific examples thereof include alkyl groups having 1 to 20 carbon atoms, alkenyl groups having 2 to 20 carbon atoms, aryl groups having 6 to 20 carbon atoms, aralkyl groups having 7 to 20 carbon atoms, etc. Additionally, these groups may have some or all of hydrogen atoms substituted with a hydroxy group, a carboxy group, a halogen atom, an oxo group, a cyano group, a nitro group, a sultone group, a sulfone group, or a group containing a sulfonium salt, while these groups may have some of carbon atoms substituted with an ether bond, an ester bond, a carbonyl group, an amide bond, a carbonate group, or a sulfonic acid ester group. Alternatively, R⁶⁰² and R⁶⁰³ may bond with each other to form a ring together with a sulfur atom bonded with R⁶⁰² and R⁶⁰³.

Specific examples of the compound shown by the general formula (6) include ones disclosed in JP 2017-219836 A. Since an iodine atom considerably absorbs EUV with a wavelength of 13.5 nm, secondary electrons are generated therefrom during exposure, so that the energy of the secondary electrons is transferred to the acid generator and promotes the decomposition of the quencher. Thereby, the sensitivity can be enhanced.

As the quencher, it is also possible to use a polymeric quencher disclosed in JP 2008-239918 A. This quencher is oriented on the resist surface after coating, and enhances the rectangularity of the resist after patterning. The polymeric quencher also has effects of preventing rounding of pattern top and film thickness loss of pattern when a top coat for immersion exposure is applied.

The inventive positive resist material contains the quencher in an amount of preferably 0 to 5 parts by mass, more preferably 0 to 4 parts by mass, based on 100 parts by mass of the base polymer. One kind of the quencher can be used alone, or two or more kinds thereof can be used in combination.

### [Other Components]

In addition to the above-described components, a surfactant, a dissolution inhibitor, and so forth can be blended in appropriate combination depending on the purpose to formulate a positive resist material. Thereby, in an exposed area of the base polymer, the dissolution rate to a developer is accelerated by the catalytic reaction, so that the positive resist material has quite high sensitivity. In this case, the resist film has high dissolution contrast and resolution, exposure latitude, excellent process adaptability, and favorable pattern profile after exposure. Particularly, the positive resist material is capable of suppressing acid diffusion, resulting in a small difference in profile between isolated and nested. Because of these advantages, the inventive positive resist material is highly practical and very effective resist material for VLSI.

Examples of the surfactant include ones disclosed in paragraphs [0165] to [0166] of JP 2008-111103 A. Adding a surfactant can further enhance or control the coatability of the resist material. The inventive positive resist material contains the surfactant in an amount of preferably 0.0001 to 10 parts by mass based on 100 parts by mass of the base polymer. One kind of the surfactant can be used alone, or two or more kinds thereof can be used in combination.

Blending a dissolution inhibitor can further increase the difference in dissolution rate between exposed and unexposed areas, and further enhance the resolution. Examples of the dissolution inhibitor include a compound which has a molecular weight of preferably 100 to 1,000, more preferably 150 to 800, and contains two or more phenolic hydroxy groups per molecule, and in which 0 to 100 mol % of all the hydrogen atoms of such phenolic hydroxy groups are substituted with acid labile groups; or a compound which contains a carboxy group in a molecule, and in which 50 to 100 mol % of all the hydrogen atoms of such carboxyl groups are substituted with acid labile groups on average. Specific examples include compounds obtained by substituting acid labile groups for hydrogen atoms of hydroxy groups or carboxy groups of bisphenol A, trisphenol, phenolphthalein, cresol novolak, naphthalenecarboxylic acid, adamantanecarboxylic acid, or cholic acid; etc. Examples of such compounds are disclosed in paragraphs [0155] to [0178] of JP 2008-122932 A.

The dissolution inhibitor is contained in an amount of preferably 0 to 50 parts by mass, more preferably 5 to 40 parts by mass, based on 100 parts by mass of the base polymer. One kind of the dissolution inhibitor can be used alone, or two or more kinds thereof can be used in combination.

The inventive positive resist material may be blended with a water-repellency enhancer for enhancing the water repellency on the resist surface after spin coating. The water-repellency enhancer can be employed in immersion lithography with no top coat. The water-repellency enhancer is preferably a polymer compound containing a fluorinated alkyl group, a polymer compound containing a 1,1,1,3,3,3-hexafluoro-2-propanol residue with a particular structure, etc., more preferably ones exemplified in JP 2007-297590 A, JP 2008-111103 A, etc. The water-repellency enhancer needs to be dissolved in an alkali developer or an organic solvent developer. The water-repellency enhancer having a particular 1,1,1,3,3,3-hexafluoro-2-propanol residue mentioned above has favorable solubility to developers. A polymer compound containing a repeating unit with an amino group or amine salt as a water-repellency enhancer exhibits high effects of preventing acid evaporation during PEB and opening failure of a hole pattern after development.

The inventive positive resist material contains the water-repellency enhancer in an amount of preferably 0 to 20 parts by mass, more preferably 0.5 to 10 parts by mass, based on 100 parts by mass of the base polymer. One kind of the water-repellency enhancer can be used alone, or two or more kinds thereof can be used in combination.

The inventive positive resist material may be blended with an acetylene alcohol. Examples of the acetylene alcohol include ones disclosed in paragraphs [0179] to [0182] of JP 2008-122932 A. The inventive positive resist material contains the acetylene alcohol in an amount of preferably 0 to 5 parts by mass based on 100 parts by mass of the base polymer.

### [Patterning Process]

When the inventive positive resist material is used for manufacturing various integrated circuits, known lithography techniques are applicable. An exemplary patterning process includes steps of:

forming a resist film on a substrate by using the above-described resist material;

exposing the resist film to a high-energy beam; and

developing the exposed resist film by using a developer.

First, the inventive positive resist material is applied onto a substrate (such as Si, SiO₂, SiN, SiON, TiN, WSi, BPSG, SOG, organic antireflective film) for manufacturing an integrated circuit or a substrate (such as Cr, CrO, CrON, MoSi₂, SiO₂) for manufacturing a mask circuit by an appropriate coating process such as spin coating, roll coating, flow coating, dip coating, spray coating, or doctor coating so that the coating film can have a thickness of 0.01 to 2 μm. The resultant is prebaked on a hot plate preferably at 60 to 150° C. for 10 seconds to 30 minutes, more preferably at 80 to 120° C. for 30 seconds to 20 minutes. In this manner, a resist film is formed.

Then, the resist film is exposed using a high-energy beam. Examples of the high-energy beam include ultraviolet ray, deep ultraviolet ray, EB, EUV, X-ray, soft X-ray, excimer laser beam, γ-ray, synchrotron radiation, etc. When ultraviolet ray, deep ultraviolet ray, EUV, X-ray, soft X-ray, excimer laser beam, γ-ray, synchrotron radiation, or the like is employed as the high-energy beam, the irradiation is performed directly or using a mask for forming a target pattern, at an exposure dose of preferably about 1 to 200 mJ/cm², more preferably about 10 to 100 mJ/cm². When EB is employed as the high-energy beam, the exposure dose is preferably about 0.1 to 100 μC/cm², more preferably about 0.5 to 50 μC/cm², and the writing is performed directly or using a mask for forming a target pattern. Note that the inventive positive resist material is particularly suitable for fine patterning with an i-line beam having a wavelength of 365 nm, a KrF excimer laser beam, an ArF excimer laser beam, an EB, an EUV having a wavelength of 3 to 15 nm, X-ray, soft X-ray, γ-ray, or synchrotron radiation among the high-energy beams, and is especially suitable for fine patterning with EB or EUV.

The exposure may be followed by PEB on a hot plate or in an oven preferably at 50 to 150° C. for 10 seconds to 30 minutes, more preferably at 60 to 120° C. for 30 seconds to 20 minutes.

After the exposure or PEB, development is performed using a developer of 0.1 to 10 mass %, preferably 2 to 5 mass % alkaline aqueous solution, such as tetramethylammonium hydroxide (TMAH), tetraethylammonium hydroxide (TEAR), tetrapropylammonium hydroxide (TPAH), or tetrabutylammonium hydroxide (TBAH), for 3 seconds to 3 minutes, preferably 5 seconds to 2 minutes, by a conventional technique, such as dip, puddle, or spray method. Thereby, the portion irradiated with the light is dissolved by the developer, while the unexposed portion remains undissolved. In this way, the target positive pattern is formed on the substrate.

The positive resist material can also be used to perform negative development for obtaining a negative pattern by organic solvent development. Examples of the developer used in this event include 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, phenylmethyl acetate, benzyl formate, phenylethyl formate, methyl 3-phenylpropionate, benzyl propionate, phenylethyl acetate, 2-phenylethyl acetate, etc. One of these organic solvents can be used alone, or two or more thereof can be used in mixture.

When the development is completed, rinsing can be performed. The rinsing liquid is preferably a solvent that is miscible with the developer but does not dissolve the resist film. As such a solvent, it is preferable to use an alcohol having 3 to 10 carbon atoms, an ether compound having 8 to 12 carbon atoms, and an alkane, alkene, alkyne and aromatic solvent, each having 6 to 12 carbon atoms.

Specific examples of the alcohol having 3 to 10 carbon atoms include n-propyl alcohol, isopropyl alcohol, 1-butyl alcohol, 2-butyl alcohol, isobutyl alcohol, tert-butyl alcohol, 1-pentanol, 2-pentanol, 3-pentanol, tert-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, 1-octanol, etc.

Examples of the ether compound having 8 to 12 carbon atoms include di-n-butyl ether, diisobutyl ether, di-sec-butyl ether, di-n-pentyl ether, diisopentyl ether, di-sec-pentyl ether, di-tert-pentyl ether, di-n-hexyl ether, etc.

Examples of the alkane having 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, cyclononane, etc. Examples of the alkene having 6 to 12 carbon atoms include hexene, heptene, octene, cyclohexene, methylcyclohexene, dimethylcyclohexene, cycloheptene, cyclooctene, etc. Examples of the alkyne having 6 to 12 carbon atoms include hexyne, heptyne, octyne, etc.

Examples of the aromatic solvent include toluene, xylene, ethylbenzene, isopropylbenzene, tert-butylbenzene, mesitylene, etc.

The rinsing can reduce resist pattern collapse and defect formation. Meanwhile, the rinsing is not necessarily essential, and the amount of the solvent used can be reduced by not performing the rinsing.

After the development, a hole pattern or trench pattern can be shrunk by thermal flow, RELACS process, or DSA process. A shrink agent is applied onto the hole pattern, and the shrink agent undergoes crosslinking on the resist surface by diffusion of the acid catalyst from the resist layer during baking, so that the shrink agent is attached to sidewalls of the hole pattern. The baking temperature is preferably 70 to 180° C., more preferably 80 to 170° C. The baking time is preferably 10 to 300 seconds. The extra shrink agent is removed, and the hole pattern is shrunk.

### EXAMPLE

Hereinafter, the present invention will be specifically described with reference to Synthesis Examples, Comparative Synthesis Examples, Examples, and Comparative Examples. However, the present invention is not limited to the following Examples.

### [Synthesis Example 1-1] Synthesis of Quencher Q-1

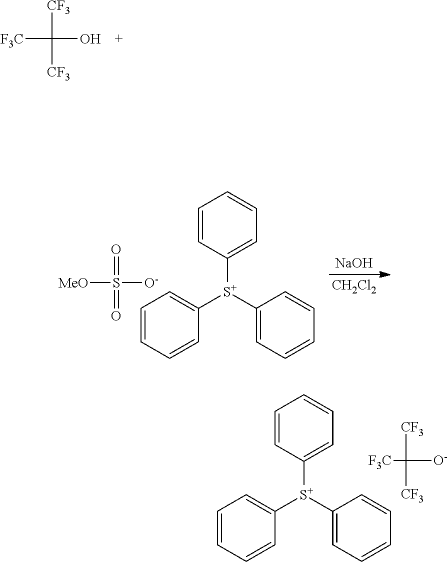

After 9.4 g of nonafluoro-tert-butoxy alcohol and 10 g of pure water were mixed, 6.4 g of a 25% sodium hydroxide aqueous solution was added dropwise under ice-cooling condition. The mixture was stirred under ice-cooling condition for 1 hour. Then, 11.2 g of triphenylsulfonium methylsulfate and 85 g of methylene chloride were added thereto and stirred for 15 minutes. The organic layer was separated and subsequently washed with 20 g of pure water seven times. The resulting organic layer was concentrated to 9.3 g under reduced pressure at 35° C., and 50 g of tert-butylmethyl ether was added thereto and stirred for 20 minutes. The precipitated solid was collected by filtration and washed with tert-butyl methyl ether. Thereafter, the powder was dried at 20° C. under reduced pressure. Thus, 4.7 g of target triphenylsulfonium nonafluoro-tert-butoxide was obtained (yield: 31%).

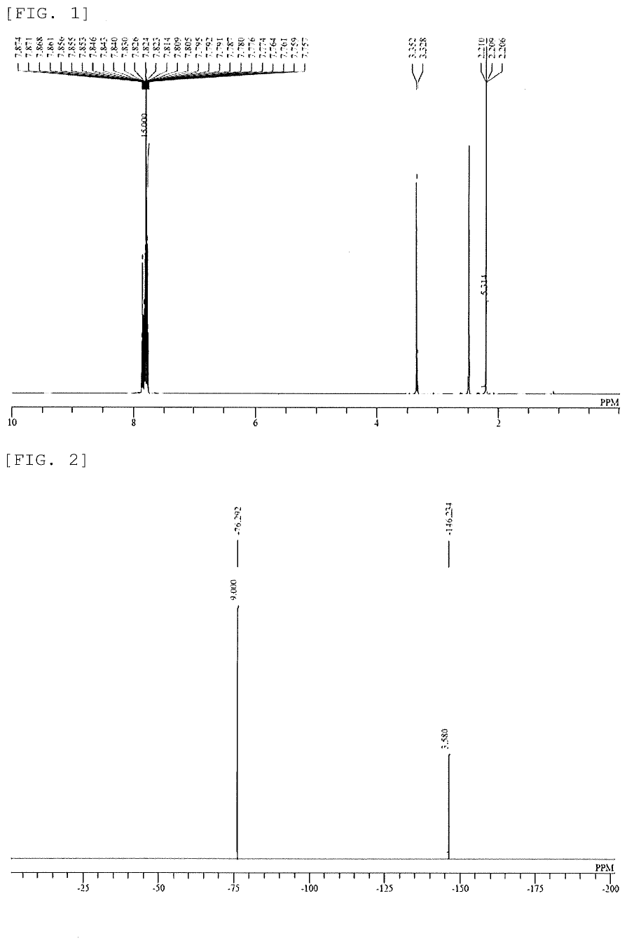

The spectrum data on the obtained target product are shown below. FIGS. 1 and 2 show the results of nuclear magnetic resonance spectra (¹H-NMR, ¹⁹F-NMR/DMSO-d₆). Note that a small amount of the residual solvent (water) and the added internal standard substance (2,3,5,6-tetrafluoro-p-xylene) were observed in ¹H-NMR, and the added internal standard substance (2,3,5,6-tetrafluoro-p-xylene) was also observed in ¹⁹F-NMR.

IR (D-ATR): ν=3351, 3224, 3101, 3064, 3045, 3004, 1664, 1581, 1480, 1448, 1250, 1193, 1126, 1066, 997, 952, 754, 720, 686, 530, 507, 492 cm⁻¹

Time-of-flight mass spectrometry (TOFMS; MALDI)
POSITIVE M⁺ 263.1 (corresponding to C₁₉H₁₅S⁺)
NEGATIVE M⁻ 235.0 (corresponding to C₄F₉O⁻)

### Synthesis Examples 1-2 to 1-19, Comparative Synthesis Examples 1-1 to 1-3

By similar ion-exchange methods, quenchers Q-2 to Q-19 and comparative quenchers cQ-1 to cQ-3 were synthesized.

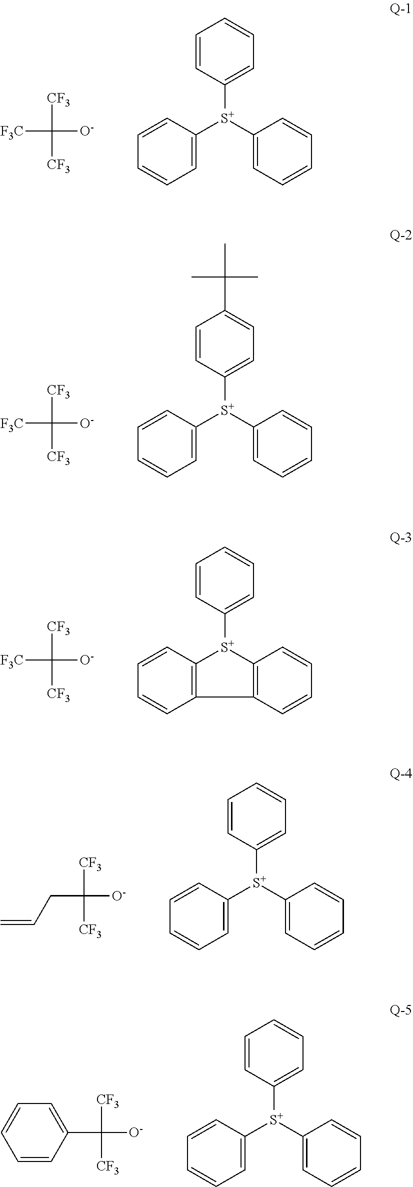

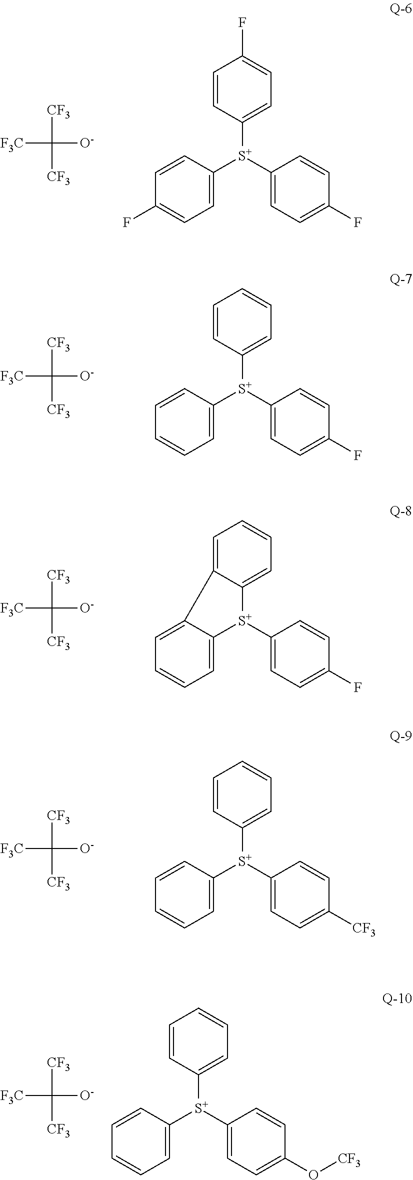

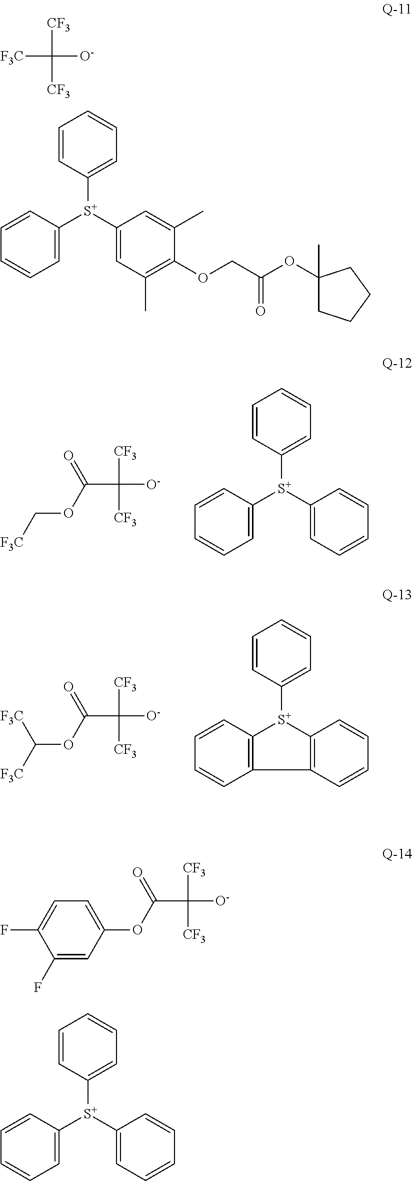

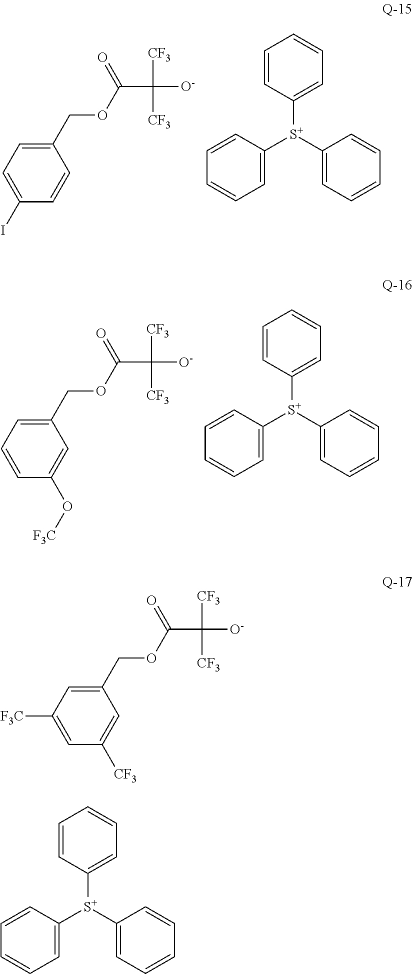 [SMILES: O=C(OCc1ccc(I)cc1)C([O-])(C(F)(F)F)C(F)(F)F ; c1ccc([S+](c2ccccc2)c2ccccc2)cc1 ; O=C(OCc1cccc(OC(F)(F)F)c1)C([O-])(C(F)(F)F)C(F)(F)F ; c1ccc([S+](c2ccccc2)c2ccccc2)cc1 ; O=C(OCc1cc(C(F)(F)F)cc(C(F)(F)F)c1)C([O-])(C(F)(F)F)C(F)(F)F ; c1ccc([S+](c2ccccc2)c2ccccc2)cc1]

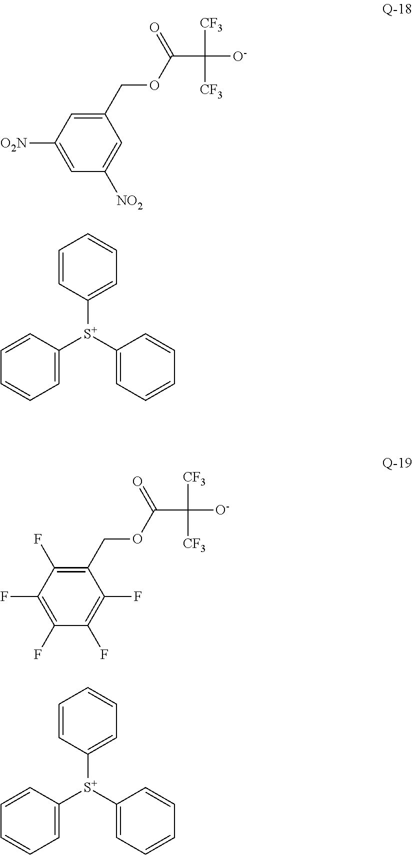 [SMILES: O=C(OCc1cc([N+](=O)[O-])cc([N+](=O)[O-])c1)C([O-])(C(F)(F)F)C(F)(F)F ; c1ccc([S+](c2ccccc2)c2ccccc2)cc1 ; O=C(OCc1c(F)c(F)c(F)c(F)c1F)C([O-])(C(F)(F)F)C(F)(F)F ; c1ccc([S+](c2ccccc2)c2ccccc2)cc1]

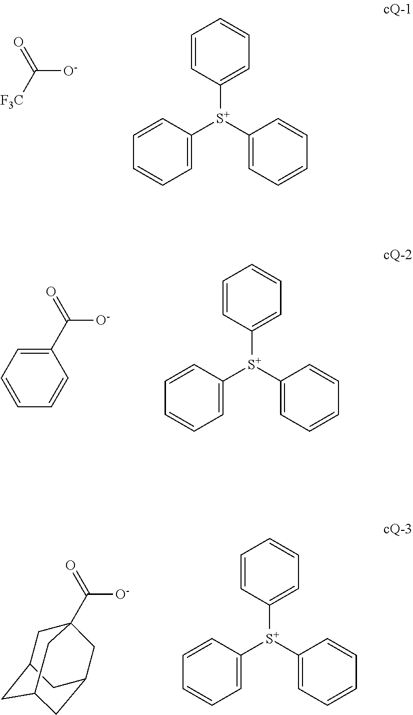 [SMILES: O=C([O-])C(F)(F)F ; c1ccc([S+](c2ccccc2)c2ccccc2)cc1 ; O=C([O-])c1ccccc1 ; c1ccc([S+](c2ccccc2)c2ccccc2)cc1 ; O=C([O-])C12CC3CC(CC(C3)C1)C2 ; c1ccc([S+](c2ccccc2)c2ccccc2)cc1]

### [Synthesis Examples 2-1 to 2-14, Comparative Synthesis Example 2-1] Synthesis of Base Polymers (Polymers 1 to 14, Comparative Polymer 1)

Various monomers were combined for copolymerization reaction in a solvent THF, and a crystal was precipitated in methanol, further washed with hexane repeatedly, then isolated, and dried. In this manner, base polymers (Polymers 1 to 14, Comparative polymer 1) having compositions shown below were obtained. The compositions of the obtained base polymers were identified by ¹H-NMR, and the Mw and Mw/Mn were identified by GPC (solvent: THF, standard: polystyrene).

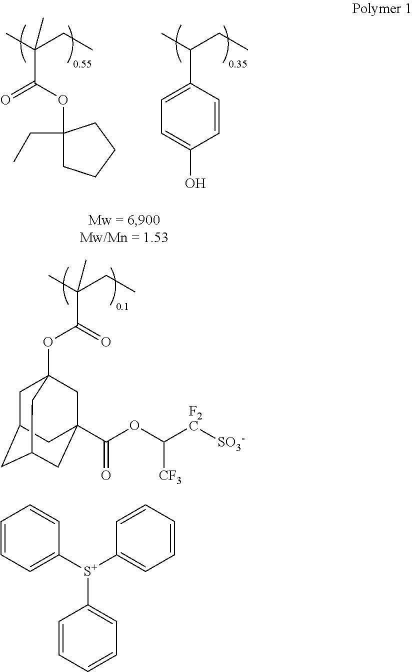

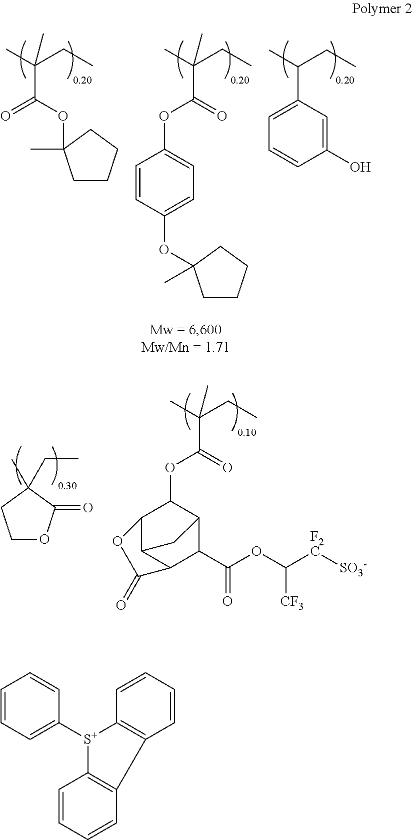

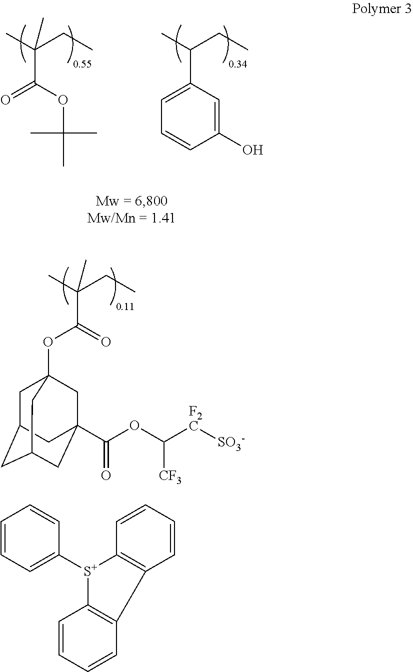

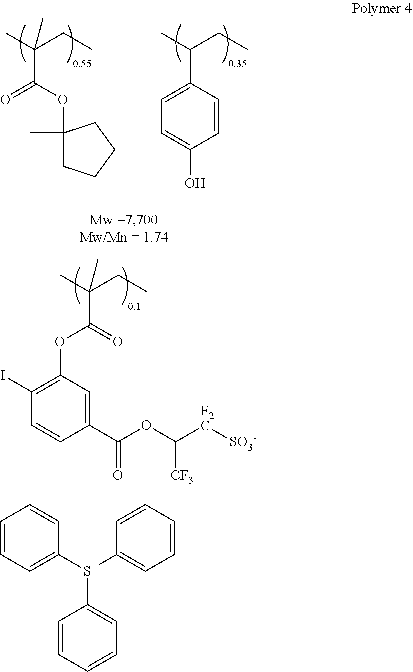

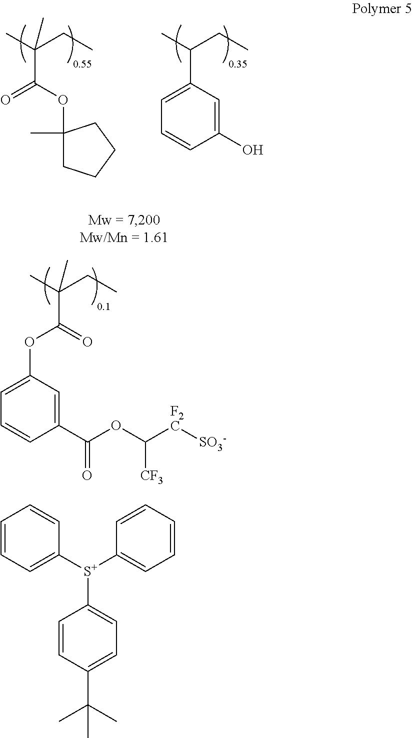

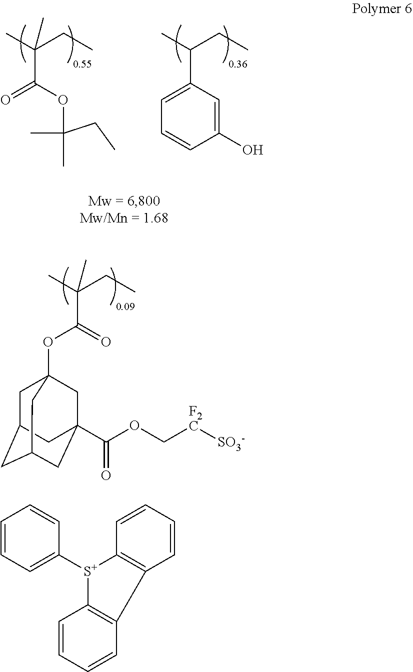

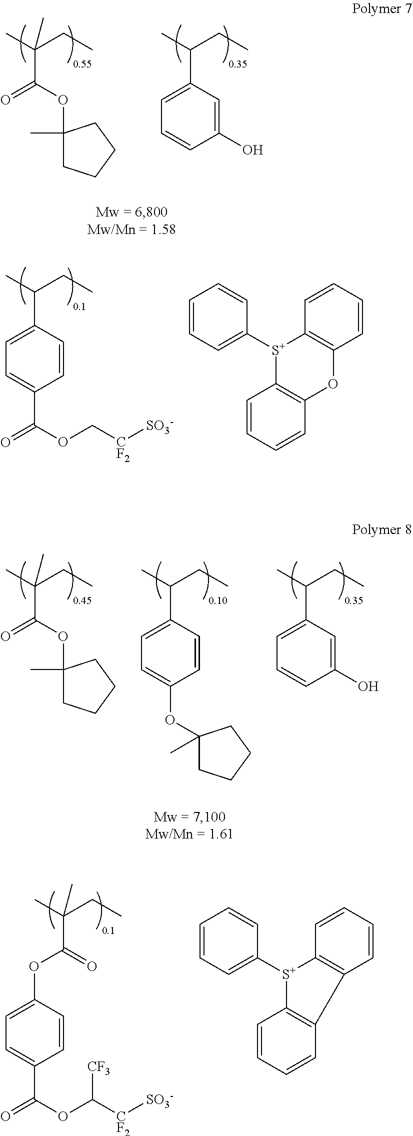

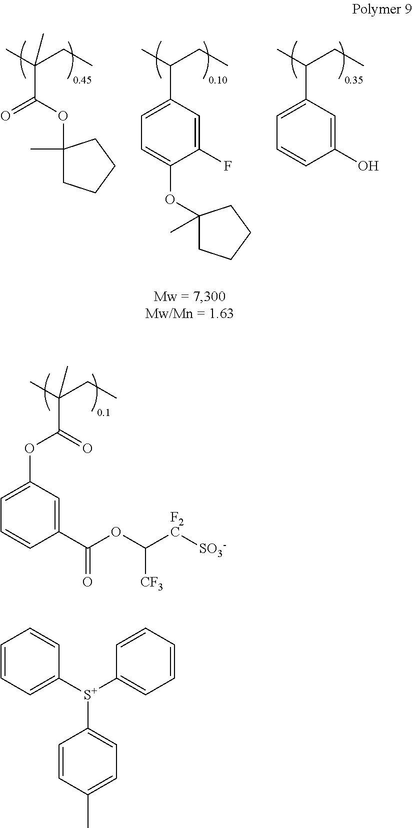

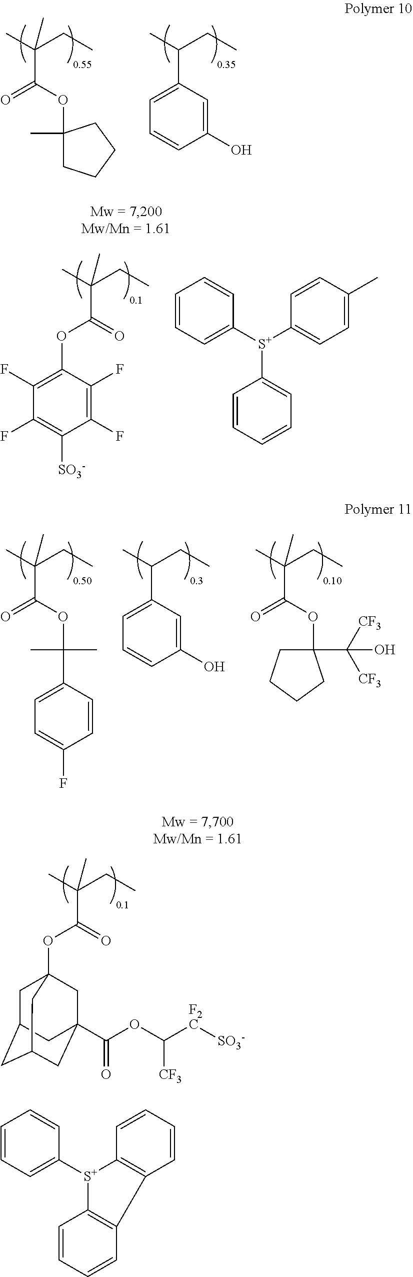

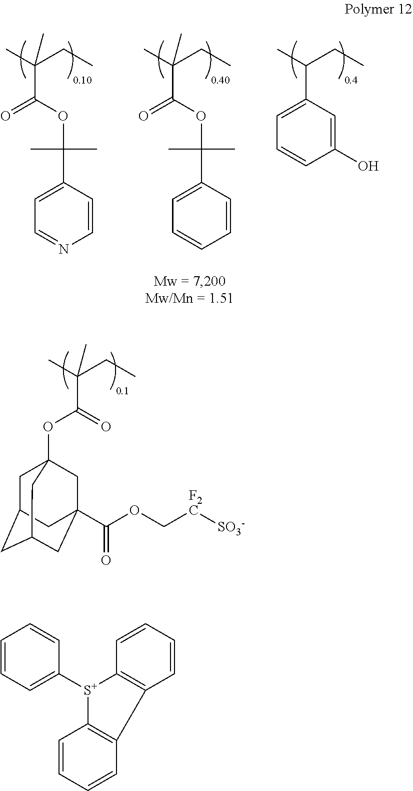

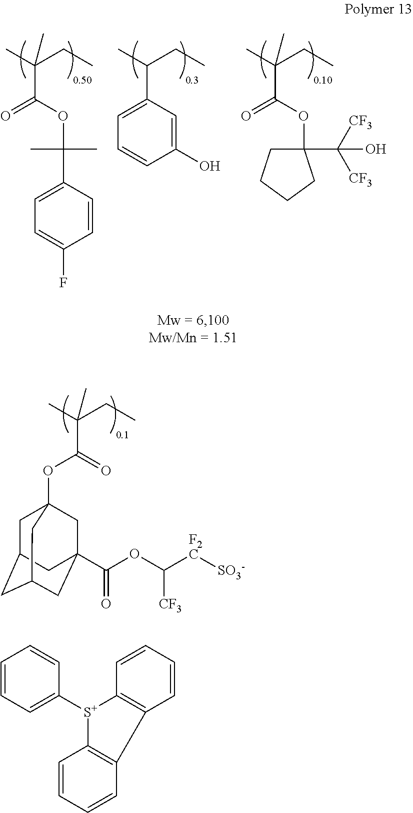

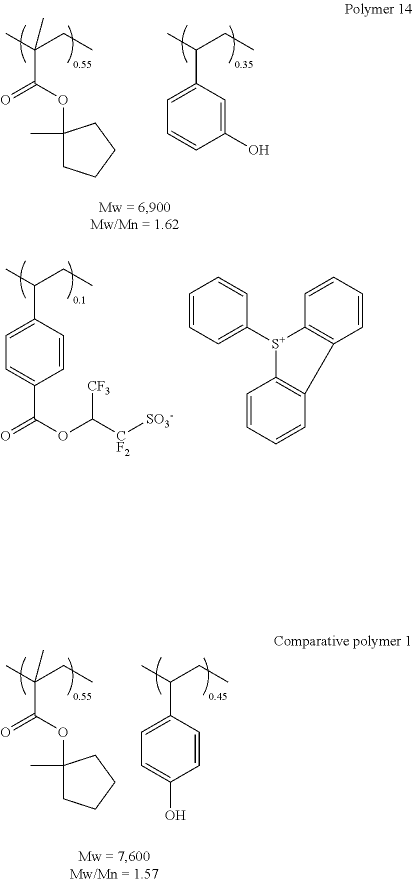

### Examples 1 to 32, Comparative Examples 1 to 5

### (1) Preparation of Positive Resist Materials

According to the compositions shown in Tables 1 and 2, components were dissolved in solvents in which 50 ppm of a surfactant Polyfox 636 manufactured by OMNOVA Solutions Inc. had been dissolved. The resulting solutions were each filtered through a filter having a pore size of 0.2 μm. In this manner, positive resist materials were prepared.

The components in Tables 1 and 2 are as follows.

Organic Solvents:

PGMEA (propylene glycol monomethyl ether acetate)

DAA (diacetone alcohol)

EL (ethyl lactate)

Acid Generator: PAG1 (See Structural Formula Below)

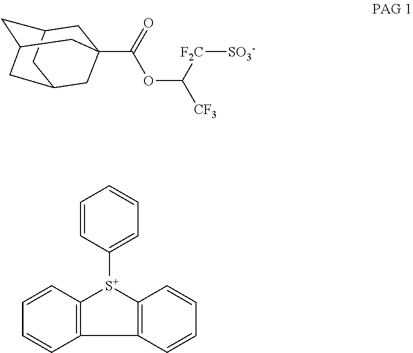

Water-Repellent Polymer 1 (See Structural Formula Below)

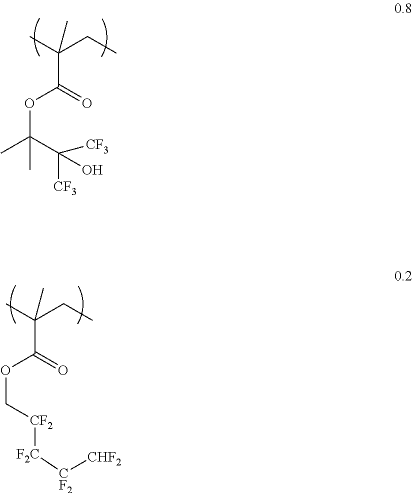

### Water-Repellent Polymer 1

Mw 11,200

Mw/Mn 1.65

### (2) EUV Lithography Evaluation

A silicon substrate with a silicon-containing spin-on hard mask SHB-A940 (silicon content: 43 mass %) manufactured by Shin-Etsu Chemical Co., Ltd. formed to have a film thickness of 20 nm was spin-coated with one of the resist materials shown in Tables 1 and 2. The resultant was prebaked using a hot plate at 105° C. for 60 seconds to prepare a resist film having a film thickness of 35 nm. The resist film was exposed using an EUV scanner NXE3400 (NA: 0.33, n: 0.9/0.6, 90° dipole illumination, with a mask having a line-and-space 1:1 pattern with a pitch of 32 nm (on-wafer size)) manufactured by ASML, followed by PEB on the hot plate at a temperature shown in Table 1 or 2 for 60 seconds, and development with a 2.38 mass % TMAH aqueous solution for 30 seconds to obtain a line-and-space pattern with a line dimension of 16 nm.

An exposure dose at which the line dimensions of 16 nm were formed was determined as “sensitivity”. Moreover, “edge roughness” was measured using a CD-SEM (CG6300) manufactured by Hitachi High-Technologies Corporation. From a line dimension which allowed the resolution of the space portion at an exposure dose smaller than the resist sensitivity, a dimension which caused resist pattern collapse and film reduction at an exposure dose larger than the resist sensitivity was subtracted to determine a “window”. The results are also shown in Tables 1 and 2.

TABLE 1

| | | | | | PEB | | | |
|---|---|---|---|---|---|---|---|---|
| | Polymer | Additive | Quencher | Organic solvent | temperature | Sensitivity | LWR | Window |
| | (parts by mass) | (parts by mass) | (parts by mass) | (parts by mass) | (° C.) | (mJ/cm²) | (nm) | (nm) |
| Example 1 | Polymer 1 | Water-repellent | Q-1 | PGMEA(4,000) | 80 | 56 | 2.20 | 4.0 |
| | (100) | polymer 1(3.0) | (12.45) | DAA(1,000) | | | | |
| Example 2 | Polymer 1 | Water-repellent | Q-2 | PGMEA(4,000) | 80 | 58 | 2.31 | 4.2 |
| | (100) | polymer 1(3.0) | (13.85) | DAA(1,000) | | | | |
| Example 3 | Polymer 1 | Water-repellent | Q-3 | PGMEA(4,000) | 80 | 54 | 2.16 | 4.2 |
| | (100) | polymer 1(3.0) | (12.40) | DAA(1,000) | | | | |
| Example 4 | Polymer 1 | Water-repellent | Q-4 | PGMEA(4,000) | 80 | 56 | 2.41 | 4.4 |
| | (100) | polymer 1(3.0) | (11.75) | DAA(1,000) | | | | |
| Example 5 | Polymer 1 | Water-repellent | Q-5 | PGMEA(4,000) | 80 | 57 | 2.44 | 4.7 |
| | (100) | polymer 1(3.0) | (12.65) | DAA(1,000) | | | | |
| Example 6 | Polymer 1 | Water-repellent | Q-6 | PGMEA(4,000) | 80 | 54 | 2.18 | 4.8 |
| | (100) | polymer 1(3.0) | (13.80) | DAA(1,000) | | | | |
| Example 7 | Polymer 1 | Water-repellent | Q-7 | PGMEA(4,000) | 80 | 56 | 2.28 | 4.1 |
| | (100) | polymer 1(3.0) | (12.90) | DAA(1,000) | | | | |
| Example 8 | Polymer 1 | Water-repellent | Q-8 | PGMEA(4,000) | 80 | 55 | 2.18 | 4.4 |
| | (100) | polymer 1(3.0) | (12.85) | DAA(1,000) | | | | |
| Example 9 | Polymer 1 | Water-repellent | Q-9 | PGMEA(4,000) | 80 | 57 | 2.34 | 4.5 |
| | (100) | polymer 1(3.0) | (14.15) | DAA(1,000) | | | | |
| Example 10 | Polymer 1 | Water-repellent | Q-10 | PGMEA(4,000) | 80 | 55 | 2.37 | 4.3 |
| | (100) | polymer 1(3.0) | (14.55) | DAA(1,000) | | | | |
| Example 11 | Polymer 1 | Water-repellent | Q-11 | PGMEA(4,000) | 80 | 56 | 2.39 | 4.1 |
| | (100) | polymer 1(3.0) | (17.05) | DAA(1,000) | | | | |
| Example 12 | Polymer 2 | Water-repellent | Q-1 | PGMEA(4,000) | 80 | 55 | 2.33 | 3.9 |
| | (100) | polymer 1(3.0) | (12.45) | DAA(1,000) | | | | |
| Example 13 | Polymer 3 | Water-repellent | Q-1 | PGMEA(4,000) | 90 | 61 | 2.09 | 3.6 |
| | (100) | polymer 1(3.0) | (12.45) | DAA(1,000) | | | | |
| Example 14 | Polymer 4 | Water-repellent | Q-1 | PGMEA(3,500) | 80 | 53 | 2.33 | 3.5 |
| | (100) | polymer 1(3.0) | (12.45) | DAA(500) | | | | |
| | | | | EL(1,000) | | | | |
| Example 15 | Polymer 5 | Water-repellent | Q-1 | EL(4,000) | 80 | 59 | 2.31 | 3.6 |
| | (100) | polymer 1(3.0) | (12.45) | DAA(1,000) | | | | |
| Example 16 | Polymer 6 | Water-repellent | Q-1 | EL(4,000) | 80 | 56 | 2.20 | 3.6 |
| | (100) | polymer 1(3.0) | (12.45) | DAA(1,000) | | | | |
| Example 17 | Polymer 7 | Water-repellent | Q-1 | EL(4,000) | 80 | 58 | 2.28 | 3.1 |
| | (100) | polymer 1(3.0) | (12.45) | DAA(1,000) | | | | |
| Example 18 | Polymer 8 | Water-repellent | Q-1 | EL(4,000) | 80 | 58 | 2.27 | 3.6 |
| | (100) | polymer 1(3.0) | (12.45) | DAA(1,000) | | | | |
| Example 19 | Polymer 9 | Water-repellent | Q-1 | EL(4,000) | 80 | 59 | 2.31 | 3.6 |
| | (100) | polymer 1(3.0) | (12.45) | DAA(1,000) | | | | |
| Example 20 | Polymer 10 | Water-repellent | Q-1 | EL(4,000) | 80 | 59 | 2.38 | 3.6 |
| | (100) | polymer 1(3.0) | (12.45) | DAA(1,000) | | | | |
| Example 21 | Polymer 11 | Water-repellent | Q-1 | EL(4,000) | 80 | 57 | 2.31 | 4.6 |
| | (100) | polymer 1(3.0) | (12.45) | DAA(1,000) | | | | |
| Example 22 | Polymer 12 | Water-repellent | Q-1 | EL(4,000) | 80 | 59 | 2.38 | 3.6 |
| | (100) | polymer 1(3.0) | (12.45) | DAA(1,000) | | | | |
| Example 23 | Polymer 13 | Water-repellent | Q-1 | EL(4,000) | 80 | 57 | 2.27 | 3.9 |
| | (100) | polymer 1(3.0) | (12.45) | DAA(1,000) | | | | |
| Example 24 | Polymer 14 | Water-repellent | Q-1 | EL(4,000) | 80 | 56 | 2.31 | 3.6 |
| | (100) | polymer 1(3.0) | (12.45) | DAA(1,000) | | | | |

TABLE 2

| | | | | | PEB | | | |
|---|---|---|---|---|---|---|---|---|
| | Polymer | Additive | Quencher | Organic solvent | temperature | Sensitivity | LWR | Window |
| | (parts by mass) | (parts by mass) | (parts by mass) | (parts by mass) | (° C.) | (mJ/cm²) | (nm) | (nm) |
| Example 25 | Polymer 1 | Water-repellent | Q-12 | PGMEA(4,000) | 80 | 65 | 3.5 | 1.5 |
| | (100) | polymer 1(3.0) | (13.90) | DAA(1,000) | | | | |
| Example 26 | Polymer 1 | Water-repellent | Q-13 | PGMEA(4,000) | 80 | 60 | 3.4 | 1.4 |
| | (100) | polymer 1(3.0) | (15.55) | DAA(1,000) | | | | |
| Example 27 | Polymer 1 | Water-repellent | Q-14 | PGMEA(4,000) | 80 | 65 | 3.2 | 1.3 |
| | (100) | polymer 1(3.0) | (14.65) | DAA(1,000) | | | | |
| Example 28 | Polymer 1 | Water-repellent | Q-15 | PGMEA(4,000) | 80 | 63 | 3.2 | 1.6 |
| | (100) | polymer 1(3.0) | (16.20) | DAA(1,000) | | | | |
| Example 29 | Polymer 1 | Water-repellent | Q-16 | PGMEA(4,000) | 80 | 60 | 3.1 | 1.2 |
| | (100) | polymer 1(3.0) | (17.25) | DAA(1,000) | | | | |
| Example 30 | Polymer 1 | Water-repellent | Q-17 | PGMEA(4,000) | 80 | 61 | 3.0 | 1.2 |
| | (100) | polymer 1(3.0) | (17.50) | DAA(1,000) | | | | |
| Example 31 | Polymer 1 | Water-repellent | Q-18 | PGMEA(4,000) | 80 | 69 | 3.0 | 1.6 |
| | (100) | polymer 1(3.0) | (13.08) | DAA(1,000) | | | | |
| Example 32 | Polymer 1 | Water-repellent | Q-19 | PGMEA(4,000) | 80 | 66 | 2.9 | 1.9 |
| | (100) | polymer 1(3.0) | (16.35) | DAA(1,000) | | | | |
| Comparative | Polymer 1 | Water-repellent | cQ-1 | PGMEA(4,000) | 80 | 61 | 3.1 | 0.8 |
| Example 1 | (100) | polymer 1(3.0) | (9.40) | DAA(1,000) | | | | |
| Comparative | Polymer 1 | Water-repellent | cQ-2 | PGMEA(4,000) | 80 | 64 | 4.0 | 1.8 |
| Example 2 | (100) | polymer 1(3.0) | (9.60) | DAA(1,000) | | | | |
| Comparative | Polymer 1 | Water-repellent | cQ-3 | PGMEA(4,000) | 80 | 62 | 4.1 | 1.1 |
| Example 3 | (100) | polymer 1(3.0) | (11.05) | DAA(1,000) | | | | |
| Comparative | Comparative | Water-repellent | Q-1 | PGMEA(4,000) | 80 | 68 | 4.5 | 3.9 |
| Example 4 | polymer 1 | polymer 1(3.0) | (12.45) | DAA(1,000) | | | | |
| | (100) | PAG-1 (20) | | | | | | |
| Comparative | Comparative | Water-repellent | cQ-1 | PGMEA(4,000) | 80 | 67 | 4.8 | 1.2 |
| Example 5 | polymer 1 | polymer 1(3.0) | (9.40) | DAA(1,000) | | | | |
| | (100) | PAG-1 (20) | | | | | | |

From the results shown in Tables 1 and 2, high sensitivity, favorable LWR, and wide window were achieved by the positive resist materials each containing: an acid generator being a sulfonium salt of a sulfonic acid bonded to a polymer main chain; and a quencher being a sulfonium salt of a fluoroalcohol with a particular structure.

In contrast, in Comparative Examples 1 to 3 and 5 containing no sulfonium salt of a fluoroalcohol with a particular structure, the LWR was large and the window was particularly narrow. Moreover, in Comparative Example 4 containing a sulfonium salt of a fluoroalcohol with a particular structure but not containing the acid generator being a sulfonium salt of a sulfonic acid bonded to a polymer main chain, the window was wide but the LWR was large.

It should be noted that the present invention is not limited to the above-described embodiments. The embodiments are just examples, and any embodiments that substantially have the same feature and demonstrate the same functions and effects as those in the technical concept disclosed in claims of the present invention are included in the technical scope of the present invention.

1. A positive resist material comprising:
an acid generator being a sulfonium salt of a sulfonate ion bonded to a polymer main chain; and
a quencher being a sulfonium salt shown by the following general formula (1). 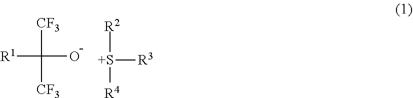
wherein R¹ represents a fluorine atom, a phenyl group, a phenyloxycarbonyl group, an alkyl group having 1 to 4 carbon atoms, an alkoxy group having 1 to 4 carbon atoms, an alkenyl group having 2 to 4 carbon atoms, an alkynyl group having 2 to 4 carbon atoms, or an alkoxycarbonyl group having 1 to 20 carbon atoms; the phenyl group and the phenyloxycarbonyl group have some or all of hydrogen atoms optionally substituted with one or more selected from a fluorine atom, a chlorine atom, a bromine atom, an iodine atom, a fluorinated alkyl group having 1 to 4 carbon atoms, a fluorinated alkyloxy group having 1 to 4 carbon atoms, a trifluoromethylthio group, a cyano group, a nitro group, and a hydroxy group; the alkyl group, the alkoxy group, the alkenyl group, the alkynyl group, and the alkoxycarbonyl group have some or all of hydrogen atoms optionally substituted with one or more selected from a fluorine atom, a chlorine atom, a bromine atom, an iodine atom, a trifluoromethyl group, a trifluoromethoxy group, a trifluoromethylthio group, a cyano group, a nitro group, a phenyl group, and a hydroxy group, or optionally having an ester group, an ether group, or a sulfonyl group; R² to R⁴ each independently represent a halogen atom, or a hydrocarbyl group having 1 to 25 carbon atoms and optionally having at least one selected from an oxygen atom, a sulfur atom, a nitrogen atom, and a halogen atom; and R² and R³, or R² and R⁴, are optionally bonded with each other to form a ring with a sulfur atom that is bonded thereto.

2. The positive resist material according to claim 1, wherein the acid generator bonded to the polymer main chain is contained in a base polymer comprising a repeating unit(s) shown by the following general formula(e) (a1) and/or (a2), 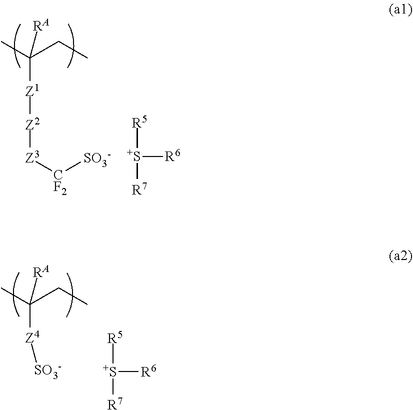
wherein each R^{A} independently represents a hydrogen atom or a methyl group; Z¹ represents a single bond, an ester bond, or a phenylene group; Z² represents a single bond, —Z²¹—C(═O)—O—, —Z²¹—O—, or —Z²¹—O—C(═O)—; Z²¹ represents a hydrocarbylene group having 1 to 12 carbon atoms, a phenylene group, or a group which is a combination thereof having 7 to 18 carbon atoms, the Z²¹ optionally containing a carbonyl group, an ester bond, an ether bond, a sulfur atom, an oxygen atom, a bromine atom, or an iodine atom; Z³ represents a methylene group, a 2,2,2-trifluoro-1,1-ethanediyl group, a hydrocarbon group having 2 to 4 carbon atoms optionally substituted with fluorine, or a carbonyl group; Z⁴ represents a fluorinated phenylene group, a phenylene group substituted with a trifluoromethyl group or an iodine atom, —Z⁴¹—, —O—Z⁴¹—, —C(═O)—O—Z⁴¹—, or —C(═O)—NH—Z⁴¹—; Z⁴¹ represents a fluorinated phenylene group, a phenylene group substituted with a trifluoromethyl group or an iodine atom, or a hydrocarbylene group having 1 to 15 carbon atoms substituted with a halogen atom and optionally containing an ester group and/or an aromatic hydrocarbon group therein; R⁵ to R⁷ each independently represent a hydrocarbyl group having 1 to 25 carbon atoms, and optionally have an oxygen atom, a sulfur atom, a nitrogen atom, or a halogen atom other than fluorine; and R⁵ and R⁶, or R⁵ and R⁷, are optionally bonded with each other to form a ring with a sulfur atom that is bonded thereto.

3. The positive resist material according to claim 2, wherein the base polymer comprises a repeating unit shown by the following general formula (b1) in which a hydrogen atom of a carboxy group is substituted with an acid labile group and/or a repeating unit shown by the following general formula (b2) in which a hydrogen atom of a phenolic hydroxy group is substituted with an acid labile group, 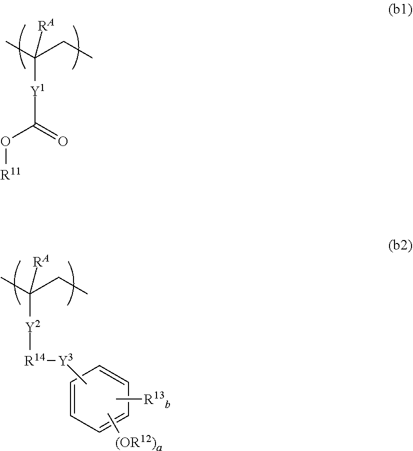
wherein each R^{A} independently represents a hydrogen atom or a methyl group; Y¹ represents a single bond, a phenylene group, a naphthylene group, or a linking group having 1 to 15 carbon atoms containing at least one selected from an ester bond, an ether bond, and a lactone ring; Y² represents a single bond, an ester bond, or an amide bond; Y³ represents a single bond, an ether bond, or an ester bond; R¹¹ and R¹² each represent an acid labile group; R¹³ represents a fluorine atom, a trifluoromethyl group, a cyano group, or a saturated hydrocarbyl group having 1 to 6 carbon atoms; R¹⁴ represents a single bond or an alkanediyl group having 1 to 6 carbon atoms, and some of the carbon atoms are optionally substituted with an ether bond or an ester bond; and “a” represents 1 or 2, and “b” represents an integer of 0 to 4, with 1≤a+b≤5.

4. The positive resist material according to claim 2, wherein the base polymer further comprises a repeating unit comprising an adhesive group selected from a hydroxy group, a carboxy group, a lactone ring, a carbonate group, a thiocarbonate group, a carbonyl group, a cyclic acetal group, an ether bond, an ester bond, a sulfonic acid ester group, a cyano group, an amide bond, —O—C(═O)—S—, and —O—C(═O)—NH—.

5. The positive resist material according to claim 3, wherein the base polymer further comprises a repeating unit comprising an adhesive group selected from a hydroxy group, a carboxy group, a lactone ring, a carbonate group, a thiocarbonate group, a carbonyl group, a cyclic acetal group, an ether bond, an ester bond, a sulfonic acid ester group, a cyano group, an amide bond, —O—C(═O)—S—, and —O—C(═O)—NH—.

6. The positive resist material according to claim 1, further comprising one or more of an acid generator other than the acid generator of the sulfonium salt, an organic solvent, a quencher other than the quencher of the sulfonium salt, and a surfactant.

7. The positive resist material according to claim 2, further comprising one or more of an acid generator other than the acid generator of the sulfonium salt, an organic solvent, a quencher other than the quencher of the sulfonium salt, and a surfactant.

8. The positive resist material according to claim 3, further comprising one or more of an acid generator other than the acid generator of the sulfonium salt, an organic solvent, a quencher other than the quencher of the sulfonium salt, and a surfactant.

9. The positive resist material according to claim 4, further comprising one or more of an acid generator other than the acid generator of the sulfonium salt, an organic solvent, a quencher other than the quencher of the sulfonium salt, and a surfactant.

10. The positive resist material according to claim 5, further comprising one or more of an acid generator other than the acid generator of the sulfonium salt, an organic solvent, a quencher other than the quencher of the sulfonium salt, and a surfactant.

11. A patterning process comprising steps of:
forming a resist film on a substrate by using the positive resist material according to claim 1;
exposing the resist film to a high-energy beam; and
developing the exposed resist film by using a developer.

12. A patterning process comprising steps of:
forming a resist film on a substrate by using the positive resist material according to claim 2;
exposing the resist film to a high-energy beam; and
developing the exposed resist film by using a developer.

13. A patterning process comprising steps of:
forming a resist film on a substrate by using the positive resist material according to claim 3;
exposing the resist film to a high-energy beam; and
developing the exposed resist film by using a developer.

14. A patterning process comprising steps of:
forming a resist film on a substrate by using the positive resist material according to claim 4;
exposing the resist film to a high-energy beam; and
developing the exposed resist film by using a developer.

15. A patterning process comprising steps of:
forming a resist film on a substrate by using the positive resist material according to claim 6;
exposing the resist film to a high-energy beam; and
developing the exposed resist film by using a developer.

16. The patterning process according to claim 11, wherein the high-energy beam is an i-line beam, a KrF excimer laser beam, an ArF excimer laser beam, an electron beam, or an extreme ultraviolet ray having a wavelength of 3 to 15 nm.

17. The patterning process according to claim 12, wherein the high-energy beam is an i-line beam, a KrF excimer laser beam, an ArF excimer laser beam, an electron beam, or an extreme ultraviolet ray having a wavelength of 3 to 15 nm.

18. The patterning process according to claim 13, wherein the high-energy beam is an i-line beam, a KrF excimer laser beam, an ArF excimer laser beam, an electron beam, or an extreme ultraviolet ray having a wavelength of 3 to 15 nm.

19. The patterning process according to claim 14, wherein the high-energy beam is an i-line beam, a KrF excimer laser beam, an ArF excimer laser beam, an electron beam, or an extreme ultraviolet ray having a wavelength of 3 to 15 nm.

20. The patterning process according to claim 15, wherein the high-energy beam is an i-line beam, a KrF excimer laser beam, an ArF excimer laser beam, an electron beam, or an extreme ultraviolet ray having a wavelength of 3 to 15 nm.
